(19) United States
(12) Patent Application Publication
(10) Pub. No.: US 2026/0164641 A1
(43) Pub. Date: Jun. 11, 2026

(54) MEMORY DEVICE AND METHOD FOR FABRICATING THE MEMORY DEVICE

(71) Applicant: Semiconductor Energy Laboratory Co., Ltd., Atsugi-shi (JP)

(72) Inventors: Takeya HIROSE, Atsugi (JP); Takanori MATSUZAKI, Atsugi (JP); Yasuhiro JINBO, Isehara (JP)

(21) Appl. No.: 19/398,386

(22) Filed: Nov. 24, 2025

(30) Foreign Application Priority Data
Dec. 5, 2024 (JP) 2024-212251

(51) Int. Cl. H10B 12/00

(52) U.S. Cl. CPC H10B 12/315; H10B 12/033; H10B 12/05

(57) ABSTRACT

A memory device that can be fabricated at low cost is provided. The memory device includes a vertical transistor and a vertical capacitor. The vertical capacitor is provided over the vertical transistor. The vertical transistor includes a pillar gate electrode and a gate insulating layer covering the top and side surfaces of the gate electrode. A lower electrode of the vertical transistor is provided over the gate insulating layer, and the level of the top surface of the lower electrode is lower than that of the top surface of the gate electrode. A semiconductor layer covers the gate electrode with the gate insulating layer therebetween and includes a region in contact with the top surface of the lower electrode. An interlayer insulating layer having an opening portion overlapping with the gate electrode is provided over the semiconductor layer. One conductive layer serves not only as an upper electrode of the vertical transistor but also as one of a pair of electrodes of the vertical capacitor, and the conductive layer is provided to include a region positioned in the opening portion. The conductive layer includes a region in contact with the top surface of the semiconductor layer in the opening portion.

### BACKGROUND OF THE INVENTION

### 1. Field of the Invention

One embodiment of the present invention relates to a transistor, a semiconductor device, a memory device, and an electronic device. Another embodiment of the present invention relates to a method for fabricating a memory device or a semiconductor device. Another embodiment of the present invention relates to a semiconductor wafer and a module.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like are sometimes regarded as including a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### 2. Description of the Related Art

A technique by which a transistor is formed using a semiconductor thin film formed over a substrate having an insulating surface has been attracting attention. The transistor is used in a wide range of electronic devices such as an integrated circuit (IC) and a display device. As semiconductor materials usable for the transistor, silicon-based semiconductor materials have been widely used, but oxide semiconductors have been attracting attention as alternative materials.

A transistor including an oxide semiconductor is known to have an extremely low leakage current in the off state. For example, Patent Document 1 discloses a low-power central processing unit (CPU) utilizing a characteristic of a low leakage current of the transistor including an oxide semiconductor. For another example, Patent Document 2 discloses a memory device that can retain stored data for a long time by utilizing a characteristic of a low leakage current of the transistor including an oxide semiconductor.

Examples of an oxide semiconductor that can be used for an active layer of a transistor include indium oxide and indium gallium zinc oxide. Non-Patent Document 1 reports the use of In₂O₃ for a thin film transistor. Non-Patent Document 2 discloses a thin film transistor in which hydrogenated polycrystal indium oxide formed by low-temperature solid phase crystallization is used for an active layer.

### REFERENCES

### Patent Documents

[Patent Document 1] Japanese Published Patent Application No. 2012-257187

[Patent Document 2] Japanese Published Patent Application No. 2011-151383

### Non-Patent Documents

[Non-Patent Document 1] Dhananjay and C. W. Chu, “Realization of In₂O₃ thin film transistors through reactive evaporation process”, Appl. Phys. Lett. 91, 1-4 (2007).

[Non-Patent Document 2] Y. Magari et al., “High-mobility hydrogenated polycrystalline In₂O₃ (In₂O₃:H) thin-film transistors”, Nature Communications, 13, 1078, (2022).

### SUMMARY OF THE INVENTION

An object of one embodiment of the present invention is to provide a memory device or a semiconductor device that can be fabricated at low cost. Another object of one embodiment of the present invention is to provide a memory device or a semiconductor device that operates at high speed. Another object of one embodiment of the present invention is to provide a memory device or a semiconductor device that consumes low power. Another object of one embodiment of the present invention is to provide a memory device or a semiconductor device that has high reliability. Another object of one embodiment of the present invention is to provide a memory device or a semiconductor device that can be scaled down or highly integrated. Another object of one embodiment of the present invention is to provide a memory device or a semiconductor device that occupies a small area. Another object of one embodiment of the present invention is to provide a novel memory device, a novel semiconductor device, or a novel transistor.

Another object of one embodiment of the present invention is to provide a method for fabricating a memory device with high productivity or a method for fabricating a semiconductor device with high productivity. Another object of one embodiment of the present invention is to provide a method for fabricating a memory device with a high fabrication yield or a method for fabricating a semiconductor device with a high fabrication yield. Another object of one embodiment of the present invention is to provide a method for fabricating a memory device that operates at high speed or a method for fabricating a semiconductor device that operates at high speed. Another object of one embodiment of the present invention is to provide a method for fabricating a memory device that consumes low power or a method for fabricating a semiconductor device that consumes low power. Another object of one embodiment of the present invention is to provide a method for fabricating a memory device that has high reliability or a method for fabricating a semiconductor device that has high reliability. Another object of one embodiment of the present invention is to provide a method for fabricating a memory device that can be scaled down or highly integrated or a method for fabricating a semiconductor device that can be scaled down or highly integrated. Another object of one embodiment of the present invention is to provide a method for fabricating a memory device that occupies a small area or a method for fabricating a semiconductor device that occupies a small area. Another object of one embodiment of the present invention is to provide a method for fabricating a novel memory device, a method for fabricating a novel semiconductor device, or a method for fabricating a novel transistor.

Note that the description of these objects does not preclude the existence of other objects. One embodiment of the present invention does not necessarily achieve all of these objects. Other objects can be derived from the description of the specification, the drawings, and the claims.

One embodiment of the present invention is a memory device including a transistor, a capacitor, a first insulating layer, and a second insulating layer. The transistor includes a first conductive layer, a second conductive layer, a third conductive layer, a third insulating layer, and a semiconductor layer. The capacitor includes the third conductive layer, a fourth conductive layer, and a fourth insulating layer. The first conductive layer is over the first insulating layer. The third insulating layer is provided over the first insulating layer to cover a top surface and a side surface of the first conductive layer. The second conductive layer is over the third insulating layer. A level of a top surface of the second conductive layer is lower than a level of the top surface of the first conductive layer. The semiconductor layer includes a region in contact with the top surface of the second conductive layer, a region in contact with a side surface of the third insulating layer, and a region in contact with a top surface of the third insulating layer that overlaps with the first conductive layer. The second insulating layer includes a region positioned over the semiconductor layer and a region in contact with a side surface of the semiconductor layer. A level of a bottom surface of the second insulating layer is lower than the level of the top surface of the second conductive layer. The second insulating layer has a first opening portion overlapping with the first conductive layer. The third conductive layer includes a region in contact with a top surface of the semiconductor layer in the first opening portion. The fourth insulating layer covers the third conductive layer and is provided to include a region positioned over the second insulating layer. The fourth conductive layer is over the fourth insulating layer and includes a region facing a side surface of the third conductive layer with the fourth insulating layer therebetween.

In the above embodiment, the second conductive layer may have a second opening portion. The first conductive layer and the third insulating layer may each include a region positioned in the second opening portion.

In the above embodiment, the memory device may further include a fifth conductive layer. The fifth conductive layer may include a region in contact with a bottom surface of the first conductive layer. An angle between the side surface of the first conductive layer and a top surface of the fifth conductive layer may be greater than or equal to 90°.

In the above embodiment, the angle may be greater than 110°.

In the above embodiment, the second conductive layer may extend in a first direction in a plan view. The fifth conductive layer may extend in a second direction in a plan view. The second direction may be perpendicular or substantially perpendicular to the first direction.

In the above embodiment, the fourth insulating layer and the fourth conductive layer may each include a region positioned in the first opening portion.

In the above embodiment, the semiconductor layer may be a crystalline oxide semiconductor containing indium and oxygen.

Another embodiment of the present invention is a method for fabricating a memory device. The method includes the steps of forming a first conductive layer over a first insulating layer; forming a second insulating layer to cover a top surface and a side surface of the first conductive layer; forming a second conductive layer over the second insulating layer; processing the second conductive layer to make a level of a top surface of the second conductive layer lower than a level of the top surface of the first conductive layer; forming a semiconductor layer over the second insulating layer to include a region in contact with the top surface of the second conductive layer; forming a third insulating layer to include a region in contact with a top surface of the semiconductor layer and a region in contact with a side surface of the semiconductor layer; forming, in the third insulating layer, a first opening portion overlapping with the first conductive layer and reaching the top surface of the semiconductor layer; forming a third conductive layer to include a region in contact with the top surface of the semiconductor layer in the first opening portion; forming a fourth insulating layer to cover the third conductive layer; and forming a fourth conductive layer over the fourth insulating layer to include a region facing a side surface of the third conductive layer with the fourth insulating layer therebetween.

In the above embodiment, the first conductive layer may be formed by the steps of forming a conductive film; forming a first resist mask over the conductive film; processing the conductive film into a band shape; removing the first resist mask; forming a second resist mask over the conductive film and the first insulating layer; and processing the conductive film into an island shape. The first resist mask may be formed to extend in a first direction in a plan view. The second resist mask may be formed to extend in a second direction in a plan view. The second direction may be perpendicular or substantially perpendicular to the first direction.

In the above embodiment, a fifth conductive layer may be formed over the first insulating layer before the first conductive layer is formed. A sacrificial layer may be formed over the fifth conductive layer. A second opening portion reaching a top surface of the fifth conductive layer may be formed in the sacrificial layer such that an angle between a side surface of the sacrificial layer in the second opening portion and a bottom portion of the second opening portion is greater than 90°. The first conductive layer may be formed to fill the second opening portion. The second insulating layer may be formed after the sacrificial layer is removed.

In the above embodiment, the second opening portion may be formed such that the angle is greater than 110°.

In the above embodiment, the second insulating layer and the semiconductor layer may be formed by an ALD method. The second conductive layer may be formed by a sputtering method or a CVD method.

According to one embodiment of the present invention, a memory device or a semiconductor device that can be fabricated at low cost can be provided. According to another embodiment of the present invention, a memory device or a semiconductor device that operates at high speed can be provided. According to another embodiment of the present invention, a memory device or a semiconductor device that consumes low power can be provided. According to another embodiment of the present invention, a memory device or a semiconductor device that has high reliability can be provided. According to another embodiment of the present invention, a memory device or a semiconductor device that can be scaled down or highly integrated can be provided. According to another embodiment of the present invention, a memory device or a semiconductor device that occupies a small area can be provided. According to another embodiment of the present invention, a novel memory device, a novel semiconductor device, or a novel transistor can be provided.

According to one embodiment of the present invention, a method for fabricating a memory device with high productivity or a method for fabricating a semiconductor device with high productivity can be provided. According to one embodiment of the present invention, a method for fabricating a memory device with a high fabrication yield or a method for fabricating a semiconductor device with a high fabrication yield can be provided. According to one embodiment of the present invention, a method for fabricating a memory device that operates at high speed or a method for fabricating a semiconductor device that operates at high speed can be provided. According to one embodiment of the present invention, a method for fabricating a memory device that consumes low power or a method for fabricating a semiconductor device that consumes low power can be provided. According to one embodiment of the present invention, a method for fabricating a memory device that has high reliability or a method for fabricating a semiconductor device that has high reliability can be provided. According to one embodiment of the present invention, a method for fabricating a memory device that can be scaled down or highly integrated or a method for fabricating a semiconductor device that can be scaled down or highly integrated can be provided. According to one embodiment of the present invention, a method for fabricating a memory device that occupies a small area or a method for fabricating a semiconductor device that occupies a small area can be provided. According to one embodiment of the present invention, a method for fabricating a novel memory device, a method for fabricating a novel semiconductor device, or a method for fabricating a novel transistor can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A and 1B are perspective views illustrating a structure example of a memory device, and FIG. 1C is a circuit diagram illustrating a structure example of a memory cell.

FIGS. 2A and 2B are plan views illustrating a structure example of a memory device.

FIGS. 3A to 3C are cross-sectional views illustrating a structure example of a memory device.

FIGS. 4A and 4B are cross-sectional views illustrating a structure example of a memory device.

FIG. 5 is a plan view illustrating a structure example of a memory device.

FIGS. 6A and 6B are cross-sectional views illustrating a structure example of a memory device.

FIGS. 7A and 7B are a plan view and a cross-sectional view illustrating a structure example of a memory device.

FIG. 8 is a cross-sectional view illustrating a structure example of a memory device.

FIGS. 9A to 9D are plan views and cross-sectional views illustrating a structure example of a memory device.

FIGS. 10A and 10B are cross-sectional views illustrating a structure example of a memory device.

FIGS. 11A and 11B are cross-sectional views illustrating a structure example of a memory device.

FIGS. 12A to 12D are plan views and cross-sectional views illustrating a structure example of a memory device.

FIGS. 13A and 13B are cross-sectional views illustrating a structure example of a memory device.

FIGS. 14A and 14B are a plan view and a cross-sectional view illustrating a structure example of a memory device.

FIGS. 15A to 15C are cross-sectional views illustrating a structure example of a memory device.

FIGS. 16A and 16B are cross-sectional views illustrating structure examples of a memory device.

FIGS. 17A and 17B are cross-sectional views illustrating a structure example of a memory device.

FIG. 18 is a cross-sectional view illustrating a structure example of a memory device.

FIGS. 19A to 19C are a plan view and cross-sectional views illustrating an example of a method for fabricating a memory device.

FIGS. 20A to 20C are a plan view and cross-sectional views illustrating an example of a method for fabricating a memory device.

FIGS. 21A to 21C are a plan view and cross-sectional views illustrating an example of a method for fabricating a memory device.

FIGS. 22A to 22C are a plan view and cross-sectional views illustrating an example of a method for fabricating a memory device.

FIGS. 23A to 23C are a plan view and cross-sectional views illustrating an example of a method for fabricating a memory device.

FIGS. 24A to 24C are a plan view and cross-sectional views illustrating an example of a method for fabricating a memory device.

FIGS. 25A to 25C are a plan view and cross-sectional views illustrating an example of a method for fabricating a memory device.

FIGS. 26A to 26C are a plan view and cross-sectional views illustrating an example of a method for fabricating a memory device.

FIGS. 27A to 27C are a plan view and cross-sectional views illustrating an example of a method for fabricating a memory device.

FIGS. 28A to 28C are a plan view and cross-sectional views illustrating an example of a method for fabricating a memory device.

FIGS. 29A to 29C are a plan view and cross-sectional views illustrating an example of a method for fabricating a memory device.

FIGS. 30A to 30C are a plan view and cross-sectional views illustrating an example of a method for fabricating a memory device.

FIGS. 31A to 31C are a plan view and cross-sectional views illustrating an example of a method for fabricating a memory device.

FIGS. 32A to 32C are a plan view and cross-sectional views illustrating an example of a method for fabricating a memory device.

FIGS. 33A to 33C are a plan view and cross-sectional views illustrating an example of a method for fabricating a memory device.

FIG. 34 is a block diagram illustrating a structure example of a memory device.

FIG. 35 is a block diagram illustrating a structure example of a CPU.

FIGS. 36A and 36B are perspective views illustrating structure examples of a memory device.

FIGS. 37A and 37B are perspective views illustrating structure examples of memory devices.

FIG. 38 illustrates an example of an electronic component.

FIGS. 39A to 39C illustrate an example of a large computer, FIG. 39D illustrates an example of space equipment, and FIG. 39E illustrates an example of a storage system that can be used in a data center.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

For easy understanding, the position, size, range, and the like of each component illustrated in drawings do not represent the actual position, size, range, and the like in some cases. Therefore, the disclosed invention is not necessarily limited to the position, size, range, or the like disclosed in the drawings.

Ordinal numbers such as “first” and “second” in this specification and the like are used in order to avoid confusion among components and do not denote the priority or the order such as the order of steps, the stacking order, or the order of placement. A term without an ordinal number in this specification and the like may be described with an ordinal number in a claim in order to avoid confusion among components. A term with an ordinal number in this specification and the like might be provided with a different ordinal number in a claim. An ordinal number provided for a term in this specification and the like might be omitted in a claim or the like.

A transistor is a kind of semiconductor elements and enables amplification of current or voltage, switching operation for controlling conduction or non-conduction, and the like. A transistor in this specification includes, in its category, an insulated-gate field-effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an oxide semiconductor (OS) transistor. A transistor including silicon in its channel formation region is sometimes referred to as a Si transistor.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

In this specification and the like, an oxynitride refers to a material containing oxygen and nitrogen, and the nitrogen content and the oxygen content in its composition are not limited. That is, an oxynitride includes, in its category, a material containing more oxygen than nitrogen in its composition and a material containing more nitrogen than oxygen in its composition.

In this specification and the like, the terms “film” and “layer” can be used interchangeably depending on the case or the circumstances. For example, the term “conductive layer” can be replaced with the term “conductive film”. For another example, the term “insulating film” can be replaced with the term “insulating layer”.

In this specification and the like, the term “parallel” indicates that the angle subtended between two straight lines is greater than or equal to −10° and less than or equal to 10°. Thus, the case where the angle is greater than or equal to −5° and less than or equal to 5° is also included. The term “substantially parallel” indicates that the angle subtended between two straight lines is greater than or equal to −20° and less than or equal to 20°. The term “perpendicular” indicates that the angle subtended between two straight lines is greater than or equal to 80° and less than or equal to 100°. Thus, the case where the angle is greater than or equal to 85° and less than or equal to 95° is also included. The term “substantially perpendicular” indicates that the angle subtended between two straight lines is greater than or equal to 70° and less than or equal to 110°.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element such as a transistor or a switch (note that a wiring is not a circuit element) therebetween. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation period of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film or the like of a transistor is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

In this specification and the like, a tapered shape refers to a shape such that at least part of a side surface of a component is inclined with respect to a substrate surface or a formation surface of the component. For example, a tapered shape preferably includes a region where the angle subtended between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially planar with a slight curvature or slight unevenness.

In this specification and the like, the expression “level with” indicates components having the same level from a reference surface (e.g., a flat surface such as a substrate surface) in a cross-sectional view. For example, the expression “level with” also includes the case where two layers (here, a layer A and a layer B) have different levels with respect to a reference surface and the difference in the top-surface level between the layer A and the layer B is less than or equal to 10 nm.

In this specification and the like, the expression “side end portions are aligned with each other” indicates that at least outlines of stacked layers partly overlap with each other in a plan view. For example, the expression “side end portions are aligned with each other” includes the case where two layers (here, a layer A and a layer B) are stacked and the shortest distance between a side end portion of the layer A and a side end portion of the layer B is less than or equal to 10 nm in a plan view.

In general, it is sometimes difficult to clearly differentiate “completely aligned” from “substantially aligned”. Thus, in this specification and the like, the expression “aligned” sometimes includes both “completely aligned” and “substantially aligned”.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions perpendicular or substantially perpendicular to each other.

In this specification and the like, a crystal structure of a cubic crystal system is sometimes referred to as a cubic crystal, a cubic crystal structure, or the like. The same applies to the other crystal systems (e.g., a hexagonal crystal system, a trigonal crystal system, a tetragonal crystal system, an orthorhombic crystal system, a monoclinic crystal system, and a triclinic crystal system).

In this specification and the like, a high power supply potential V_{DD} (hereinafter, also simply referred to as “V_{DD}”) refers to a power supply potential higher than a low power supply potential V_{SS} (hereinafter, also simply referred to as “V_{SS}”). The low power supply potential V_{SS} is a power supply potential lower than the high power supply potential V_{DD}.

A potential H is a potential with which an n-channel field-effect transistor (also referred to as an “n-type transistor”) is turned on and also a potential with which a p-channel field-effect transistor (also referred to as a “p-type transistor”) is turned off. A potential L is a potential with which an n-type transistor is turned off and a p-type transistor is turned on. Thus, the potential H is higher than the potential L. The potential H may be equal to V_{DD}, and the potential L may be equal to V_{SS}.

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing “−” (a minus sign) in front of the number instead of placing a bar over the number. Furthermore, an individual direction that shows an orientation in crystal is expressed with “[ ]”, a set direction that shows all of the equivalent orientations is expressed with “< >”, an individual plane that shows a crystal plane is expressed with “( )”, and a set plane having equivalent symmetry is expressed with “{ }”.

In this specification and the like, the content of a certain metal element in a metal oxide refers to the proportion of the number of atoms of the metal element to the total number of metal element atoms contained in the metal oxide. For example, in the case where a metal oxide contains a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio between the metal element X, the metal element Y, and the metal element Z contained in the metal oxide is represented by B_{X}:B_{Y}:B_{Z}, the content of the metal element X can be represented by B_{X}/(B_{X}+B_{Y}+B_{Z}).

In this specification and the like, the term “island shape” refers to a state where two or more layers formed using the same material in the same step are physically separated from each other. A band shape refers to a shape including a region extending in a certain direction (e.g., the X direction, the Y direction, or the Z direction).

### Embodiment 1

In this embodiment, a memory device of one embodiment of the present invention will be described. The memory device of one embodiment of the present invention includes a memory cell. The memory cell includes a vertical transistor and a vertical capacitor. A word line and a bit line are connected to the memory cell. One embodiment of the present invention relates to a memory device in which a vertical capacitor is provided over a vertical transistor.

In this specification and the like, a vertical transistor refers to a transistor in which a source electrode and a drain electrode are positioned at different levels. For example, a transistor in which the bottom surface of a source electrode and the bottom surface of a drain electrode are positioned at different levels can be referred to as a vertical transistor. Here, of the source electrode and the drain electrode, an electrode at a lower level from a reference surface is referred to as a lower electrode, and an electrode at a higher level from the reference surface is referred to as an upper electrode. The reference surface can be the top surface of a substrate, the top surface of a base insulating layer, the top surface of an interlayer insulating layer, or the like.

The channel length direction of a vertical transistor has a height-direction (vertical-direction) component. Note that a vertical transistor is also referred to as a vertical field-effect transistor (VFET), a vertical-channel transistor, a vertical-channel-type transistor, or the like.

In this specification and the like, a vertical capacitor refers to a capacitor including a region where the side surfaces of a pair of electrodes face each other with a dielectric therebetween. The capacitance per unit area of a vertical capacitor can be higher than that of a planar (also referred to as parallel-plate) capacitor, for example. Thus, a memory cell including a vertical capacitor can occupy a smaller area and contribute to a more stable data reading operation than a memory cell including a planar capacitor, for example. Examples of a vertical capacitor include a cylindrical capacitor and a pillar capacitor. Note that a vertical capacitor is also referred to as a VC.

A gate electrode of a vertical transistor is provided in a pillar shape to include a region in contact with a conductive layer functioning as a word line. A gate insulating layer of the vertical transistor covers the top and side surfaces of the pillar gate electrode. A lower electrode of the vertical transistor is provided over the gate insulating layer so as not to overlap with the top surface of the gate electrode. The level of the top surface of the lower electrode of the vertical transistor is lower than that of the top surface of the gate electrode. The lower electrode of the vertical transistor can cover part of the side surface of the gate electrode and part of the side surface of the gate insulating layer. The lower electrode of the vertical transistor includes a region functioning as a bit line.

A semiconductor layer of the vertical transistor covers the top and side surfaces of the pillar gate electrode with the gate insulating layer therebetween. The semiconductor layer of the vertical transistor includes a region in contact with the top surface of the lower electrode, a region in contact with the side surface of the gate insulating layer, and a region in contact with the top surface of the gate insulating layer that overlaps with the gate electrode.

An interlayer insulating layer is provided over the semiconductor layer of the vertical transistor. The interlayer insulating layer can include a region in contact with the side surface of the semiconductor layer. The level of the bottom surface of the interlayer insulating layer is lower than that of the top surface of the lower electrode of the vertical transistor, and is the same as that of the bottom surface of the lower electrode, for example. The interlayer insulating layer has an opening portion overlapping with the gate electrode of the vertical transistor. The opening portion reaches the top surface of the semiconductor layer of the vertical transistor.

A conductive layer is provided to include a region positioned in the opening portion. The conductive layer is in contact with the top surface of the semiconductor layer of the vertical transistor, specifically the top surface of the semiconductor layer that overlaps with the gate electrode, in the opening portion. The conductive layer functions as an upper electrode of the vertical transistor and one of a pair of electrodes of a vertical capacitor.

A dielectric of the vertical capacitor is provided to cover the conductive layer and include a region positioned over the interlayer insulating layer. The other of the pair of electrodes of the vertical capacitor is positioned over the dielectric.

As described above, in the memory cell included in the memory device of one embodiment of the present invention, the vertical transistor is provided below the vertical capacitor. When a driver circuit for supplying a signal to the word line (a word line driver circuit) and a driver circuit for supplying a signal to a bit line (a bit line driver circuit) are provided below the memory cell, for example, the wiring distance between the driver circuits and the vertical transistor can be shorter in the case where the vertical transistor is provided below the vertical capacitor than in the case where the vertical transistor is provided above the vertical capacitor. Specifically, the wiring distance between the conductive layer functioning as the word line and a transistor included in the word line driver circuit can be shortened. Moreover, the wiring distance between a conductive layer functioning as the bit line (the lower electrode of the vertical transistor) and a transistor included in the bit line driver circuit can be shortened. Accordingly, the memory device can operate at high speed. In addition, the memory device can have low power consumption.

As the length of one of the pair of electrodes of the vertical capacitor in the height direction is longer (the difference between the level of the top surface or the upper end portion from the reference surface and the level of the bottom surface from the reference surface is larger), the capacitance of the vertical capacitor becomes higher without an increase in the area occupied by the vertical capacitor. However, in the case where the vertical transistor is provided above the vertical capacitor, the wiring distance between the driver circuits and the vertical transistor becomes longer as the length of one of the pair of electrodes of the vertical capacitor in the height direction is longer. Specifically, the length of a plug for connecting the vertical transistor and the driver circuits becomes longer. By contrast, in the memory device of one embodiment of the present invention, the length of the plug for connecting the vertical transistor and the driver circuits does not depend on the length of one of the pair of electrodes of the vertical capacitor in the height direction.

Accordingly, in the memory device of one embodiment of the present invention, the wiring distance between the driver circuits and the vertical transistor can be shortened while the capacitance of the vertical capacitor is increased. Thus, the memory device can have high reliability and operate at high speed. Since the length of the plug for connecting the vertical transistor and the driver circuits in the height direction can be shortened, the aspect ratio of the plug can be reduced. This can increase the fabrication yield of the memory device. Note that the plug is also referred to as a connection electrode.

In the memory device of one embodiment of the present invention, one conductive layer can serve not only as the upper electrode of the vertical transistor but also as one of the pair of electrodes of the vertical capacitor. This enables the number of fabrication steps of the memory device to be smaller than that in the case where different conductive layers serve as these electrodes. Thus, the memory device can be fabricated at low cost.

### Structure Example 1 of Memory Device

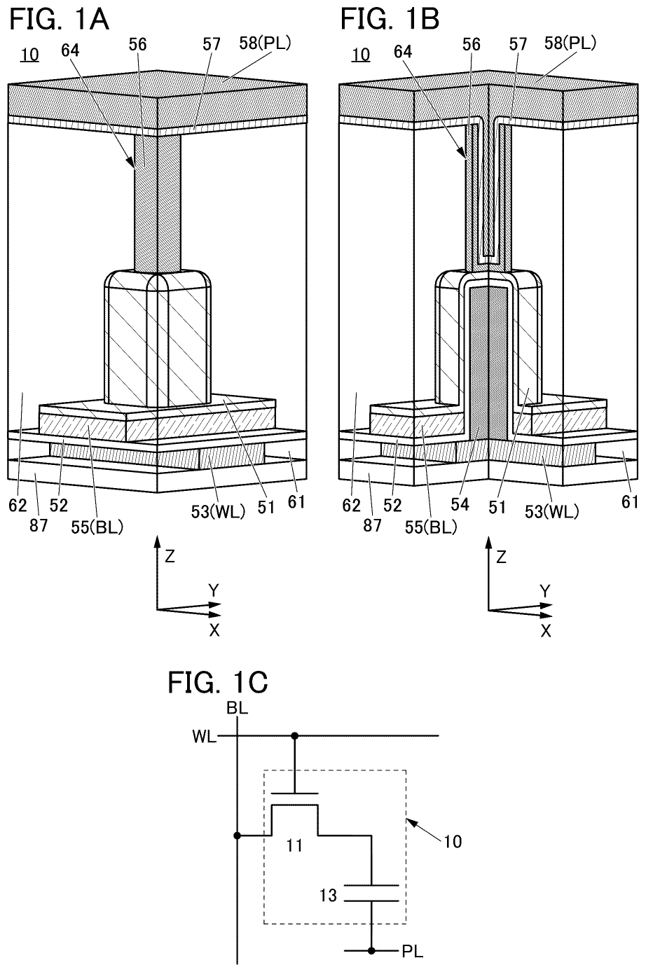

FIG. 1A is a perspective view illustrating a structure example of the memory device of one embodiment of the present invention, specifically, a perspective view illustrating a structure example of a memory cell 10 included in the memory device of one embodiment of the present invention. FIG. 1B is a perspective view obtained by cutting part of FIG. 1A. FIG. 1C is a circuit diagram illustrating the structure example of the memory cell 10. As illustrated in FIG. 1C, the memory cell 10 includes a transistor 11 and a capacitor 13.

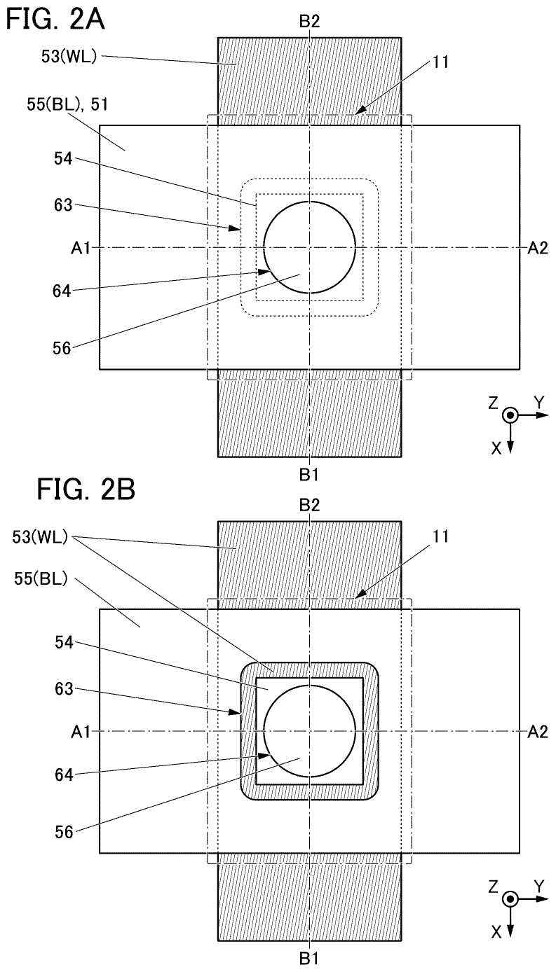

FIG. 2A is a plan view illustrating a structure example of the transistor 11. For clarity of the drawing, some components are omitted in FIG. 2A. Some components may be omitted also in the following plan views. FIG. 2B is a plan view omitting some components from FIG. 2A.

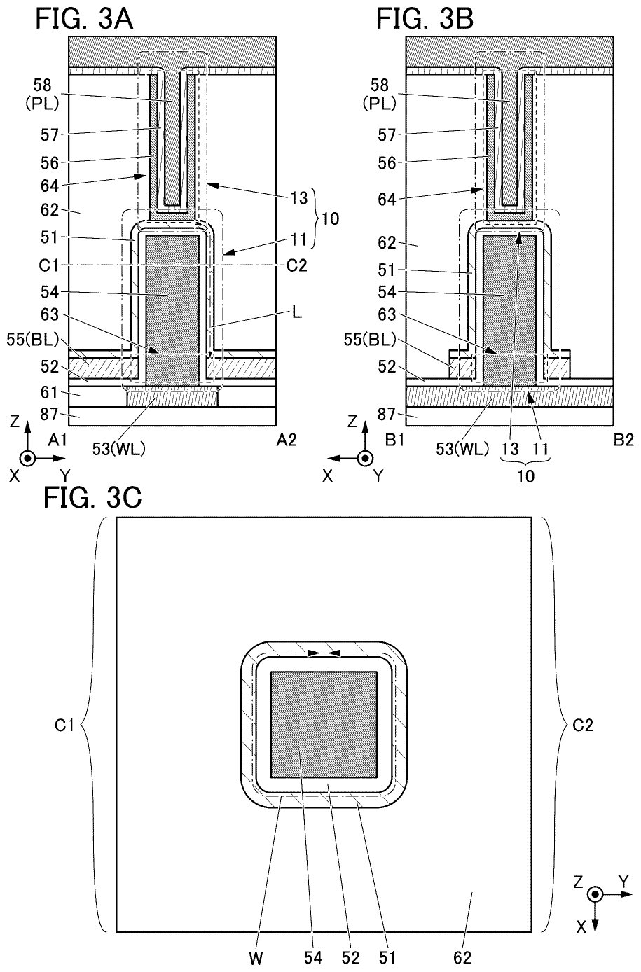

FIG. 3A is a cross-sectional view taken along the dashed-dotted line A1-A2 in FIGS. 2A and 2B. FIG. 3B is a cross-sectional view taken along the dashed-dotted line B1-B2 in FIGS. 2A and 2B. FIGS. 3A and 3B illustrate a structure example of the capacitor 13 in addition to the transistor 11. FIGS. 3A and 3B can be regarded as cross-sectional views illustrating the structure example of the memory cell 10.

FIG. 3C is a cross-sectional view taken along the dashed-dotted line C1-C2 in FIG. 3A. FIG. 3C is also referred to as a plan view.

As illustrated in FIG. 1C, one of a source and a drain of the transistor 11 is connected to a wiring BL. The other of the source and the drain of the transistor 11 is connected to one of a pair of electrodes of the capacitor 13. A gate of the transistor 11 is connected to a wiring WL. The other of the pair of electrodes of the capacitor 13 is connected to a wiring PL.

The wiring BL functions as a bit line. The wiring WL functions as a word line. The wiring PL functions as a power supply line for applying a predetermined potential to the other of the pair of electrodes of the capacitor 13. In the case where the transistor 11 is an n-channel transistor, the transistor 11 is turned on by application of a potential H to the wiring WL. Accordingly, data is written to the memory cell 10 or data retained in the memory cell 10 is read. Note that a potential L is preferably applied to the wiring PL at the time of data writing and data reading.

The memory device illustrated in FIGS. 1A to 1C, FIGS. 2A and 2B, and FIGS. 3A to 3C includes an insulating layer 87 over a substrate (not illustrated), a conductive layer 53 and an insulating layer 61 over the insulating layer 87, the transistor 11 over the conductive layer 53 and the insulating layer 61, and the capacitor 13 and an insulating layer 62 over the transistor 11.

The insulating layer 87 functions as a base insulating layer or an interlayer insulating layer. The insulating layers 61 and 62 function as interlayer insulating layers.

The transistor 11 includes a conductive layer 54 over the conductive layer 53, an insulating layer 52 over the conductive layer 53, the conductive layer 54, and the insulating layer 61, a conductive layer 55 over the insulating layer 52, a semiconductor layer 51 over the insulating layer 52 and the conductive layer 55, and a conductive layer 56 over the semiconductor layer 51. The capacitor 13 includes the conductive layer 56, an insulating layer 57 over the conductive layer 56 and the insulating layer 62, and a conductive layer 58 over the insulating layer 57. Here, the semiconductor layer 51 illustrated in FIG. 2A is omitted in FIG. 2B.

In the transistor 11, the conductive layer 54 functions as a gate electrode. The insulating layer 52 functions as a gate insulating layer. The conductive layer 55 functions as one of a source electrode and a drain electrode. The conductive layer 56 functions as the other of the source electrode and the drain electrode.

In the capacitor 13, the conductive layer 56 functions as one of the pair of electrodes. That is, the conductive layer 56 functions as both the other of the source electrode and the drain electrode of the transistor 11 and one of the pair of electrodes of the capacitor 13. The insulating layer 57 functions as a dielectric. The conductive layer 58 functions as the other of the pair of electrodes. That is, the capacitor 13 is a metal-insulator-metal (MIM) capacitor. Note that the conductive layer 56 is also referred to as a lower electrode of the capacitor 13. The conductive layer 58 is also referred to as an upper electrode of the capacitor 13.

### Transistor 11

The structure example of the transistor 11 will be described in detail below.

The conductive layer 53 includes a region functioning as the wiring WL illustrated in FIG. 1C. The conductive layer 55 includes a region functioning as the wiring BL. The conductive layer 58 includes a region functioning as the wiring PL. FIGS. 1A and 1B, FIGS. 2A and 2B, and FIGS. 3A and 3B illustrate an example in which the conductive layer 53 extends in the X direction and the conductive layer 55 extends in the Y direction. That is, the conductive layer 53 and the conductive layer 55 are each provided in a band shape. The conductive layer 55 intersects perpendicularly or substantially perpendicularly with the conductive layer 53 in a plan view, for example.

The conductive layer 53 is provided to fill an opening portion of the insulating layer 61, for example. The top surface of the conductive layer 53 can be level with the top surface of the insulating layer 61, for example.

The bottom surface of the conductive layer 54 is in contact with the top surface of the conductive layer 53. Thus, the gate electrode of the transistor 11 is connected to the wiring WL. Specifically, the conductive layer 54 functioning as the gate electrode of the transistor 11 is connected to the conductive layer 53 including the region functioning as the wiring WL. Note that the bottom surface of the conductive layer 54 may include a region in contact with the top surface of the insulating layer 61.

The conductive layer 54 includes a pillar region (also referred to as a region serving as a pillar or a region having a pillar shape), for example. The conductive layer 54 can be a pillar with an axis along the Z direction, for example. Here, the axis along the Z direction of the pillar passes through the center of gravity of the planar shape of the pillar, for example. Note that the axis of the pillar may have a curve or the like as long as the axis is substantially along the Z direction. FIG. 1B, FIGS. 2A and 2B, and FIGS. 3A to 3C illustrate an example in which the conductive layer 54 is a quadrangular prism. Note that the conductive layer 54 can be regarded as being provided in an island shape.

The conductive layer 53 and the conductive layer 54 can be formed using any of conductive materials described later in [Conductive layer]. The conductive layer 53 and the conductive layer 54 are preferably formed using a conductive material containing tungsten, copper, or aluminum as its main component, for example. One or both of the conductive layer 53 and the conductive layer 54 may have a stacked-layer structure. For example, a stacked-layer structure of a titanium nitride film and a tungsten film over the titanium nitride film can be employed.

The insulating layer 52 covers the top and side surfaces of the conductive layer 54. The insulating layer 52 can include a region in contact with the top surface of the conductive layer 54, a region in contact with the side surface of the conductive layer 54, a region in contact with the top surface of the conductive layer 53, and a region in contact with the top surface of the insulating layer 61. The insulating layer 52 has a projection along the top and side surfaces of the conductive layer 54.

In this specification and the like, a surface of the insulating layer 52 that is along the side surface of the conductive layer 54 is referred to as a side surface of the insulating layer 52. A surface of the semiconductor layer 51 that is along the side surface of the insulating layer 52 is referred to as a side surface of the semiconductor layer 51.

The insulating layer 52 can be formed using any of insulating materials described later in [Insulating layer].

The conductive layer 55 is provided over the insulating layer 52 so as not to overlap with the top surface of the conductive layer 54. The level of the top surface of the conductive layer 55 is lower than that of the top surface of the conductive layer 54. Specifically, the level of the top surface of the conductive layer 55 from the reference surface is lower than that of the top surface of the conductive layer 54 from the reference surface. The conductive layer 55 can be regarded as being provided in the vicinity of the projection of the insulating layer 52.

In the above example, the reference surface can be the top surface of the substrate, the top surface of the insulating layer 87, the top surface of the insulating layer 61, or the top surface of the conductive layer 53, for example. Also in the following description, the reference surface can sometimes be the top surface of the substrate, the top surface of the insulating layer 87, the top surface of the insulating layer 61, or the top surface of the conductive layer 53, for example.

The conductive layer 55 has an opening portion 63. The shape of the opening portion 63 in a plan view can be of the same type as the shape of the conductive layer 54 in a plan view. The shape of the opening portion 63 in a plan view can be of the same type as the shape of the conductive layer 54 in a plan view and can have rounded corners. FIGS. 2A and 2B illustrate an example in which the shape of the conductive layer 54 in a plan view is a quadrangle and the shape of the opening portion 63 in a plan view is a quadrangle with rounded corners. Although FIGS. 2A and 2B illustrate an example in which the shape of the conductive layer 54 in a plan view is a square, the shape may be either a rectangle or a rhombus, for example.

Part of the conductive layer 54 and part of the insulating layer 52 are provided in the opening portion 63. Specifically, part of a region of the conductive layer 54 at a lower level than the top surface of the conductive layer 54 from the reference surface and part of a region of the insulating layer 52 at a lower level than the top surface of the insulating layer 52 that overlaps with the conductive layer 54 (the top of the projection of the insulating layer 52) from the reference surface are provided in the opening portion 63. It can be said that the bottom surface of the conductive layer 54 is not provided but a region in the vicinity of the bottom surface of the conductive layer 54 is provided in the opening portion 63. It can be said that the bottom surface of the insulating layer 52 is not provided but a region in the vicinity of the bottom surface of the insulating layer 52 in a region along the side surface of the conductive layer 54 is provided in the opening portion 63.

The side surface of the conductive layer 55 in the opening portion 63 covers part of the insulating layer 52. The side surface of the conductive layer 55 in the opening portion 63 also covers part of the conductive layer 54 with the insulating layer 52 therebetween.

The semiconductor layer 51 covers the top and side surfaces of the conductive layer 54 with the insulating layer 52 therebetween. Specifically, the semiconductor layer 51 covers the top surface of the conductive layer 54 and the side surface of the conductive layer 54 in a region at a level higher than or equal to the level of the top surface of the conductive layer 55 from the reference surface, with the insulating layer 52 therebetween. The semiconductor layer 51 includes a region in contact with the top surface of the conductive layer 55, a region in contact with the side surface of the insulating layer 52, and a region in contact with the top surface of the insulating layer 52 that overlaps with the conductive layer 54. The semiconductor layer 51 is provided along the projection of the insulating layer 52. The semiconductor layer 51 has a projection along the side surface of the insulating layer 52 and the top surface of the insulating layer 52 that overlaps with the conductive layer 54.

The top of the projection of the semiconductor layer 51 includes a region overlapping with the top surface of the conductive layer 54. The side surface of the projection of the semiconductor layer 51 includes a region facing the side surface of the conductive layer 54 with the insulating layer 52 therebetween.

The thickness of the semiconductor layer 51 can be greater than or equal to 1 nm and less than or equal to 50 nm, preferably greater than or equal to 2 nm and less than or equal to 30 nm, further preferably greater than or equal to 2 nm and less than or equal to 20 nm, still further preferably greater than or equal to 2 nm and less than or equal to 10 nm. It is preferable that the semiconductor layer 51 at least partly include a region with the above-described thickness.

The insulating layer 62 is provided over the semiconductor layer 51 and the insulating layer 52. The insulating layer 62 can include a region in contact with the side surface of the semiconductor layer 51. The insulating layer 62 can also include a region in contact with the top surface of the semiconductor layer 51.

The level of the bottom surface of the insulating layer 62 is lower than that of the top surface of the conductive layer 55, and is the same as that of the bottom surface of the conductive layer 55, for example. Specifically, the level of the bottom surface of the insulating layer 62 from the reference surface is lower than that of the top surface of the conductive layer 55 from the reference surface, and is the same as that of the bottom surface of the conductive layer 55 from the reference surface, for example. As illustrated in FIGS. 1A and 1B and FIG. 3B, another insulating layer, e.g., an interlayer insulating layer, is absent between the insulating layer 52 and the insulating layer 62 in a region not overlapping with the conductive layer 55. This enables the number of fabrication steps of the memory device to be smaller than that in the case where another insulating layer, e.g., an interlayer insulating layer, is provided between the insulating layer 52 and the insulating layer 62. Thus, the memory device can be fabricated at low cost.

The insulating layer 62 has an opening portion 64 overlapping with the conductive layer 54. The opening portion 64 reaches the top surface of the semiconductor layer 51. FIGS. 2A and 2B illustrate an example in which the opening portion 64 is circular in a plan view. When the opening portion 64 is circular in a plan view, the processing accuracy at the time of forming the opening portion 64 can be increased. Thus, the size of the opening portion 64 can be reduced.

A low-dielectric-constant material is preferably used for the insulating layer 62, and silicon oxide or silicon oxynitride is preferably used, for example. Thus, formation of parasitic capacitance between the conductive layer 53 and the conductive layer 58 and between the conductive layer 55 and the conductive layer 58 can be inhibited, for example, thereby allowing the memory device to operate at high speed.

In the case where a metal oxide is used for the semiconductor layer 51, the insulating layer 62 preferably includes a region containing oxygen to be released by heating (also referred to as excess oxygen). Thus, oxygen is supplied to a channel formation region of the semiconductor layer 51, which can reduce the amount of oxygen vacancies (V_{O}) and the number of defects in which hydrogen enters the oxygen vacancies (also referred to as V_{O}H) in the channel formation region. Note that silicon oxide, silicon oxynitride, and the like are each an insulator that easily forms a region containing excess oxygen and thus can be suitably used for the insulating layer 62.

In the case where a metal oxide is used for the semiconductor layer 51 and oxygen vacancies and impurities exist in the channel formation region of the semiconductor layer 51, the electrical characteristics of the transistor 11 are likely to vary and the reliability thereof is degraded in some cases. Furthermore, V_{O}H generates an electron serving as a carrier in some cases. Thus, when the transistor 11 is an n-channel transistor, oxygen vacancies and impurities in the channel formation region of the semiconductor layer 51 easily make the transistor 11 have normally-on characteristics. Accordingly, the amounts of oxygen vacancies and impurities are preferably reduced as much as possible in the channel formation region of the semiconductor layer 51. In other words, the semiconductor layer 51 preferably includes an i-type (intrinsic) or substantially i-type channel formation region with a low carrier concentration.

As described above, the transistor 11 can have excellent electrical characteristics when the insulating layer 62 includes a region containing excess oxygen. In addition, the memory device can have high reliability.

The conductive layer 56 includes a region positioned in the opening portion 64. The conductive layer 56 is in contact with the top surface of the semiconductor layer 51, specifically the top surface of the semiconductor layer 51 that overlaps with the conductive layer 54, in the opening portion 64. The conductive layer 56 can also be in contact with the side surface of the insulating layer 62 in the opening portion 64. The conductive layer 56 can have a depression along the side surface of the insulating layer 62 in the opening portion 64 and the top surface of the semiconductor layer 51.

FIG. 1B and FIGS. 3A and 3B illustrate an example in which the upper end portion of the conductive layer 56 is level with the top surface of the insulating layer 62. Note that the level of the upper end portion of the conductive layer 56 from the reference surface may be lower than that of the top surface of the insulating layer 62 from the reference surface. The level of the end portion of the conductive layer 56 from the reference surface may be higher than that of the top surface of the insulating layer 62 from the reference surface. In that case, the end portion of the conductive layer 56 is positioned outside the opening portion 64. In addition, the end portion of the conductive layer 56 is positioned on the top surface of the insulating layer 62.

As described above, the side surface of the projection of the semiconductor layer 51 includes the region facing the side surface of the conductive layer 54 with the insulating layer 52 therebetween. At least part of the region functions as the channel formation region of the transistor 11. The region of the semiconductor layer 51 that is in contact with the conductive layer 55 and a region in its vicinity function as one of a source region and a drain region. A region of the semiconductor layer 51 that is in contact with the conductive layer 56 and a region in its vicinity function as the other of the source region and the drain region. Accordingly, the channel formation region is sandwiched between the source region and the drain region.

The semiconductor layer 51 includes a region along the side surface of the insulating layer 52. The conductive layer 55 is positioned under the semiconductor layer 51, and the conductive layer 56 is positioned over the semiconductor layer 51. Accordingly, the transistor 11 has a structure in which current flows in the vertical direction. Thus, the transistor 11 can occupy a smaller area than a planar transistor in which a channel formation region, a source region, and a drain region are provided separately on the XY plane. This enables the memory device to be highly integrated. Hence, the memory capacity per unit area can be increased. Note that the channel length direction of the transistor 11 can be regarded as having a height-direction (vertical-direction) component.

From the above, the transistor 11 is a vertical transistor. The conductive layer 55 serves as a lower electrode of the transistor 11. The conductive layer 56 serves as an upper electrode of the transistor 11. As described above, the conductive layer 56 also serves as the lower electrode of the capacitor 13. Accordingly, the conductive layer 56 serves as both the upper electrode of the transistor 11 and the lower electrode of the capacitor 13.

The channel length of the transistor 11 depends on the distance between the source region and the drain region. The channel length of the transistor 11 corresponds to, for example, the length of the channel formation region of the semiconductor layer 51. In FIG. 3A, a channel length L of the transistor 11 is indicated by a dashed-dotted double-headed arrow. The channel length L can be, for example, the length of the semiconductor layer 51 along the side surface of the insulating layer 52 in a region where the semiconductor layer 51 faces the conductive layer 54 with the insulating layer 52 therebetween.

In the example illustrated in FIG. 3C, the entire perimeter of the semiconductor layer 51 serves as the channel formation region. In that case, the channel width of the transistor 11 is determined by the length of the outer periphery of the semiconductor layer 51, the length of the inner periphery thereof, or an intermediate length between the outer periphery and the inner periphery. In FIG. 3C, a channel width W of the transistor 11 is indicated by a dashed-dotted double-headed arrow.

FIGS. 1A and 1B, FIGS. 2A and 2B, and FIGS. 3A and 3B illustrate an example in which the side end portion of the semiconductor layer 51 is aligned with the side end portion of the conductive layer 55. The conductive layer 55 and the semiconductor layer 51 that have such a structure can be formed in the following manner: the conductive layer 55 and the semiconductor layer 51 are formed and then processed using the same mask. This enables the number of masks required for fabricating the memory device to be smaller than that in the case where the conductive layer 55 and the semiconductor layer 51 are processed using different masks. Here, in the case where the conductive layer 55 and the semiconductor layer 51 have the structure illustrated in FIGS. 1A and 1B, FIGS. 2A and 2B, and FIGS. 3A and 3B, the side surface of the conductive layer 55 can be in contact with the insulating layer 62.

A metal oxide functioning as a semiconductor (hereinafter, also referred to as an oxide semiconductor) can be used for the semiconductor layer 51. In that case, the transistor 11 can be regarded as an OS transistor.

For the semiconductor layer 51, for example, an oxide containing indium is preferably used, and indium oxide is particularly preferably used. The band gap of an oxide containing indium is greater than or equal to 2.0 eV or greater than or equal to 2.5 eV. The use of a metal oxide having a wide band gap for the semiconductor layer 51 can reduce the off-state current of the transistor. An OS transistor having a low off-state current allows the memory device to have sufficiently low power consumption. Furthermore, the OS transistor has excellent frequency characteristics, which enables the memory device to operate at high speed. In the case where indium oxide is used for the semiconductor layer 51, the transistor 11 can be referred to as an IO transistor.

The description in Embodiment 2 can be referred to for indium oxide that can be used for the semiconductor layer 51. Here, the detailed description thereof is omitted. The semiconductor layer 51 can be formed using any of semiconductor materials described later in [Semiconductor layer].

The conductive layer 55 and the conductive layer 56 can be formed using any of the conductive materials described later in [Conductive layer]. Particularly in the case where a metal oxide is used for the semiconductor layer 51, the conductive layer 55 and the conductive layer 56 each including the region in contact with the semiconductor layer 51 are preferably formed using a conductive material that is less likely to be oxidized, a conductive material that maintains its conductivity even after absorbing oxygen, or a conductive material having a function of inhibiting diffusion of oxygen. Examples of the conductive materials include a conductive material containing nitrogen and a conductive material containing oxygen (also referred to as an oxide conductor). Accordingly, even in the case where a metal oxide is used for the semiconductor layer 51, a decrease in the conductivity of the conductive layer 55 and the conductive layer 56 can be inhibited.

Examples of the conductive material containing nitrogen include titanium nitride and tantalum nitride. Examples of the oxide conductor include indium tin oxide (In—Sn oxide, also referred to as ITO), ITO containing silicon (In—Sn—Si oxide, also referred to as ITSO), indium zinc oxide (In—Zn oxide), and indium titanium oxide (In—Ti oxide).

### Capacitor 13

The structure example of the capacitor 13 will be described in detail below. As described above, the capacitor 13 includes the conductive layer 56, the insulating layer 57 over the conductive layer 56, and the conductive layer 58 over the insulating layer 57. In the capacitor 13, the conductive layer 56 functions as the lower electrode, the conductive layer 58 functions as the upper electrode, and the insulating layer 57 functions as the dielectric.

As described above, the conductive layer 56 includes the region positioned in the opening portion 64. Similarly, the insulating layer 57 and the conductive layer 58 each include a region positioned in the opening portion 64. The insulating layer 57 covers the conductive layer 56 and includes a region positioned over the insulating layer 62. The conductive layer 58 is positioned over the insulating layer 57. The conductive layer 58 can be provided to fill the opening portion 64.

The capacitor 13 has a structure in which the upper electrode faces the lower electrode with the dielectric therebetween, along the side surface of the opening portion 64 as well as the bottom surface thereof. Thus, the capacitor 13 is a vertical capacitor. Hence, the capacitor 13 can have higher capacitance per unit area than a planar capacitor, for example. Accordingly, the operation of reading data from the memory cell 10 can be stabilized while an increase in the area occupied by the memory cell 10 is inhibited. FIGS. 1A and 1B and FIGS. 3A and 3B illustrate an example in which the capacitor 13 is a cylindrical capacitor.

As the opening portion 64 is deeper, the length of the conductive layer 56 in the Z direction (also referred to as the height direction) becomes longer. Thus, the area of a region where the conductive layer 56 faces the conductive layer 58 with the insulating layer 57 therebetween becomes larger. This can increase the capacitance of the capacitor 13 without an increase in the area occupied by the capacitor 13.

The insulating layer 57 is preferably formed using a high-dielectric-constant (high-k) material. Using the high-k material for the insulating layer 57 allows the insulating layer 57 to be thick enough to inhibit leakage current and a sufficiently high capacitance of the capacitor 13 to be ensured. The details of the high-k material will be described later.

The insulating layer 57 preferably has a stacked-layer structure including an insulating layer that contains a high-k material. A stacked-layer structure containing a high-k material and a material with higher dielectric strength than the high-k material is preferably used. For example, as the insulating layer 57, an insulating film in which zirconium oxide, aluminum oxide, and zirconium oxide are stacked in this order can be used. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulating layer with relatively high dielectric strength, such as aluminum oxide, can increase the dielectric strength and inhibit electrostatic breakdown of the capacitor 13.

Alternatively, a material that can have ferroelectricity may be used for the insulating layer 57. The details of the material that can have ferroelectricity will be described later.

The conductive layer 58 can be formed using any of the conductive materials described later in [Conductive layer]. For example, the conductive layer 58 is preferably formed using a conductive material containing tungsten, copper, or aluminum as its main component.

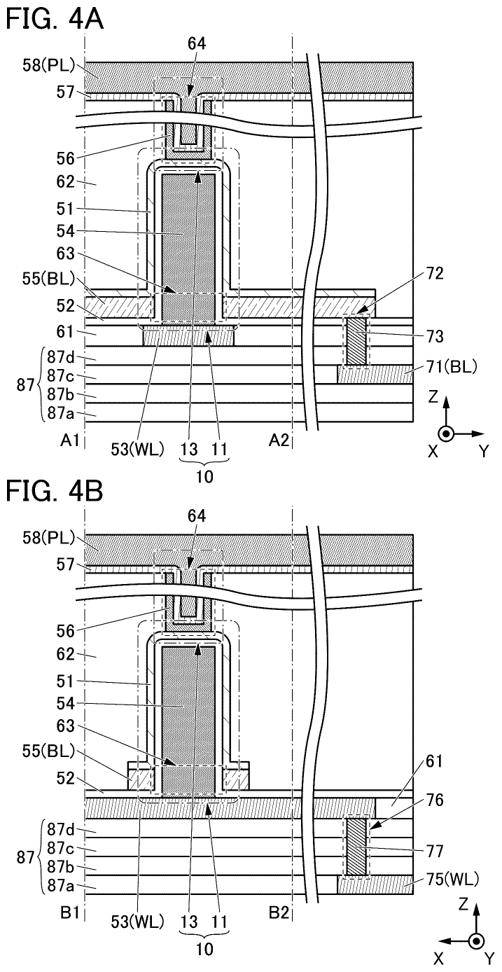

FIG. 4A illustrates an example in which the insulating layer 87 illustrated in FIG. 3A has a stacked-layer structure of an insulating layer 87a, an insulating layer 87b over the insulating layer 87a, an insulating layer 87c over the insulating layer 87b, and an insulating layer 87d over the insulating layer 87c. FIG. 4B illustrates an example in which the insulating layer 87 illustrated in FIG. 3B has the above stacked-layer structure. FIG. 4A illustrates a structure example along the dashed-dotted line A1-A2 in FIGS. 2A and 2B. FIG. 4B illustrates a structure example along the dashed-dotted line B1-B2 in FIGS. 2A and 2B.

In the example illustrated in FIG. 4A, a conductive layer 71 is provided to fill an opening portion of the insulating layer 87c. The insulating layer 87d, the insulating layer 61, and the insulating layer 52 have an opening portion 72 reaching the conductive layer 71. A conductive layer 73 is embedded in the opening portion 72. The conductive layer 55 includes a region positioned over the conductive layer 73. Any of the materials that can be used for the conductive layer 53 can be used for the conductive layer 71 and the conductive layer 73, for example.

The conductive layer 73 can include a region in contact with the top surface of the conductive layer 71 and a region in contact with the bottom surface of the conductive layer 55. Thus, the conductive layer 55 can be connected to the conductive layer 71 through the conductive layer 73. The conductive layer 73 functions as a plug for connecting the conductive layer 55 to the conductive layer 71. Like the conductive layer 55, the conductive layer 71 includes a region functioning as the wiring BL. Note that the conductive layer 73 may be included in the wiring BL.

In the example illustrated in FIG. 4B, a conductive layer 75 is provided to fill an opening portion of the insulating layer 87a. The insulating layer 87b, the insulating layer 87c, and the insulating layer 87d have an opening portion 76 reaching the conductive layer 75. A conductive layer 77 is embedded in the opening portion 76. The conductive layer 53 includes a region positioned over the conductive layer 77. Any of the materials that can be used for the conductive layer 53 can be used for the conductive layer 75 and the conductive layer 77, for example.

The conductive layer 77 can include a region in contact with the top surface of the conductive layer 75 and a region in contact with the bottom surface of the conductive layer 53. Thus, the conductive layer 53 can be connected to the conductive layer 75 through the conductive layer 77. The conductive layer 77 functions as a plug for connecting the conductive layer 53 to the conductive layer 75. Like the conductive layer 53, the conductive layer 75 includes a region functioning as the wiring WL. Note that the conductive layer 77 may be included in the wiring WL.

Although not illustrated in FIG. 4A, FIG. 4B, or the like, for example, a circuit for driving the memory cell 10 (a driver circuit) is provided below the memory cell 10, specifically below the insulating layer 61 and the conductive layer 53. For example, a driver circuit for supplying a signal to the wiring WL (a word line driver circuit) and a driver circuit for supplying a signal to the wiring BL (a bit line driver circuit) can be provided below the memory cell 10. For example, transistors, specifically Si transistors, included in the driver circuits can be provided below the memory cell 10. This enables the memory device to occupy a smaller area than a memory device in which the driver circuits are provided not to overlap with the memory cell 10, for example. Here, the conductive layer 71 illustrated in FIG. 4A is connected to the bit line driver circuit, e.g., a sense amplifier included in the bit line driver circuit. The conductive layer 75 illustrated in FIG. 4B is connected to the word line driver circuit.

In this manner, the capacitor 13 can be provided to include a region overlapping with the transistor 11. Specifically, in the example illustrated in FIGS. 1A and 1B, FIGS. 2A and 2B, FIGS. 3A and 3B, and FIGS. 4A and 4B, the opening portion 64 is provided in the insulating layer 62 to overlap with the conductive layer 54 functioning as the gate electrode of the transistor 11. Then, the capacitor 13 is provided to include a region positioned in the opening portion 64. This enables the area occupied by the memory cell 10 to be smaller than that in the case where the capacitor 13 does not overlap with the transistor 11. Thus, the memory device can be scaled down or highly integrated.

In the memory cell 10, the transistor 11 is provided under the capacitor 13. This enables the wiring distance between the driver circuits and the transistor 11 to be shorter than that in the case where the transistor 11 is provided over the capacitor 13. Specifically, the opening portion 72 illustrated in FIG. 4A does not need to be provided in the insulating layer 62; thus, the length of the conductive layer 73 in the Z direction can be shortened by at least the thickness of the insulating layer 62. Hence, the wiring distance between one of the source electrode and the drain electrode of the transistor 11 and the bit line driver circuit can be shortened by at least the thickness of the insulating layer 62. Similarly, the opening portion 76 illustrated in FIG. 4B does not need to be provided in the insulating layer 62; thus, the length of the conductive layer 77 in the Z direction can be shortened by at least the thickness of the insulating layer 62. Accordingly, the wiring distance between the conductive layer 54 and the word line driver circuit can be shortened by at least the thickness of the insulating layer 62.

Thus, the memory device can operate at high speed. In addition, the memory device can have low power consumption. Since the lengths of the conductive layers 73 and 77 in the Z direction can be shortened, the aspect ratios of the conductive layers 73 and 77 can be reduced. This can increase the fabrication yield of the memory device, so that the memory device can be fabricated at low cost.

As the opening portion 64 is deeper, the capacitance of the capacitor 13 can be increased without an increase in the area occupied by the capacitor 13, as described above. Making the opening portion 64 deeper requires an increase in the thickness of the insulating layer 62. Here, in the case where the transistor 11 is provided over the capacitor 13, the wiring distance between the driver circuits and the transistor 11 becomes longer as the thickness of the insulating layer 62 becomes larger. By contrast, in the memory device of one embodiment of the present invention, the length of a plug such as the conductive layer 73 or the conductive layer 77 does not depend on the thickness of the insulating layer 62. Accordingly, in the memory device of one embodiment of the present invention, the wiring distance between the driver circuits and the transistor 11 can be shortened while the capacitance of the capacitor 13 is increased. This allows the memory device to have high reliability and operate at high speed.

In the memory device of one embodiment of the present invention, the conductive layer 56 can serve not only as the other of the source electrode and the drain electrode of the transistor 11 but also as one of the pair of electrodes of the capacitor 13. This enables the number of fabrication steps of the memory device to be smaller than that in the case where different conductive layers serve as these electrodes. Thus, the memory device can be fabricated at low cost.

### Structure Example 2 of Memory Device

A structure example of a memory device including a plurality of the memory cells 10 will be described below. Specifically, a structure example of a memory array in which the plurality of memory cells 10 are arranged in a matrix will be described.

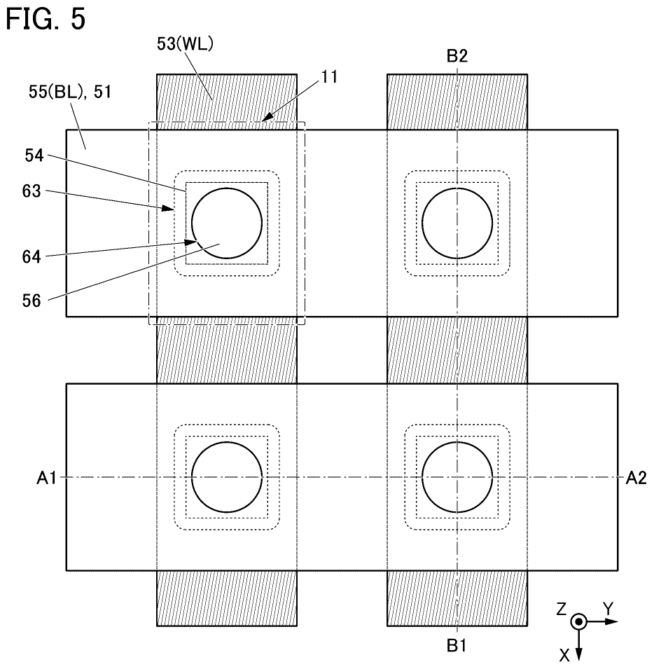

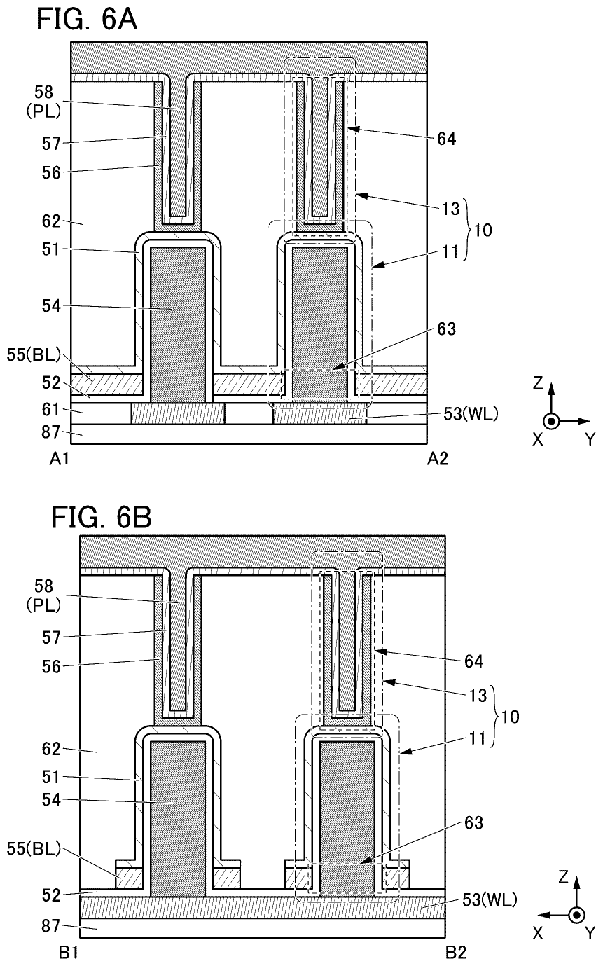

FIG. 5 is a plan view illustrating a structure example of a memory device in which 2×2 memory cells are arranged in the X direction and the Y direction. Specifically, FIG. 5 is a plan view illustrating a structure example of the transistor 11 included in each of the 2×2 memory cells 10. FIG. 6A is a cross-sectional view taken along the dashed-dotted line A1-A2 in FIG. 5. FIG. 6B is a cross-sectional view taken along the dashed-dotted line B1-B2 in FIG. 5.

As illustrated in FIG. 5 and FIGS. 6A and 6B, the conductive layer 53 including the region functioning as the wiring WL is shared by the plurality of memory cells 10 arranged in the X direction. The semiconductor layer 51 and the conductive layer 55 including the region functioning as the wiring BL are shared by the plurality of memory cells 10 arranged in the Y direction. The conductive layer 58 including the region functioning as the wiring PL can be shared by all the memory cells 10, for example.

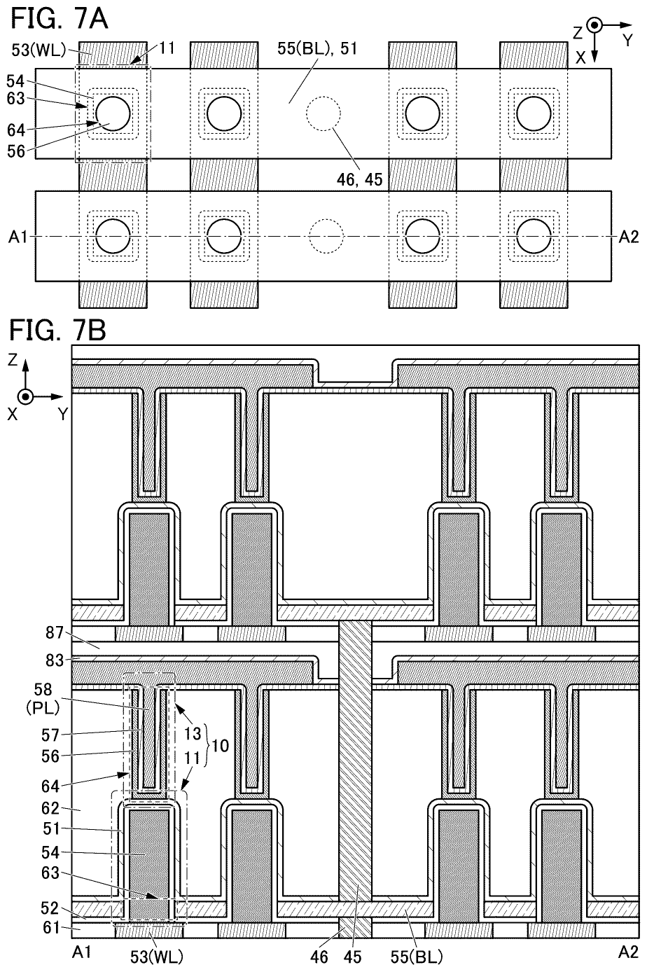

FIG. 7A is a plan view illustrating a structure example of a memory device in which 4×2×2 memory cells are arranged in the X direction, the Y direction, and the Z direction. Specifically, FIG. 7A is a plan view illustrating a structure example of the transistor 11 included in each of the 4×2×2 memory cells 10. FIG. 7B is a cross-sectional view taken along the dashed-dotted line A1-A2 in FIG. 7A.

As illustrated in FIGS. 7A and 7B, the conductive layer 53 is shared by the plurality of memory cells 10 arranged in the X direction. The conductive layer 55 and the semiconductor layer 51 are shared by the plurality of memory cells 10 arranged in the Y direction. The conductive layer 58 can be shared by the plurality of memory cells 10 adjacent in the X direction or the Y direction, for example.

In the example illustrated in FIG. 7B, an insulating layer 83 is provided over the conductive layer 58 and the insulating layer 57, and the insulating layer 87 is provided over the insulating layer 83. The insulating layer 83 preferably has a barrier property against oxygen. Thus, diffusion of oxygen contained in the channel formation region of the semiconductor layer 51 into the insulating layer 87 and the like and formation of oxygen vacancies in the channel formation region can be inhibited. The insulating layer 83 preferably also has a barrier property against hydrogen. Hence, diffusion of hydrogen into the semiconductor layer 51 and formation of V_{O}H in the channel formation region can be inhibited, for example. As the insulating layer 83, a single layer or stacked layers of an insulating material having a barrier property against oxygen, an insulating material having a barrier property against hydrogen, or the like described later in [Insulating layer] can be used as appropriate.

In this specification and the like, a barrier property refers to a property that does not easily allow diffusion of a target substance (also referred to as a property that does not easily allow passage of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer of a transistor, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

A plurality of the wirings BL, specifically the conductive layers 55, arranged in the Z direction are connected to each other by a conductive layer 45 functioning as a plug. Note that the conductive layer 45 may be included in the wiring BL. The conductive layer 45 is provided in an opening portion formed in the semiconductor layer 51, the insulating layer 62, the insulating layer 57, the insulating layer 83, the insulating layer 87, the insulating layer 61, and the insulating layer 52. The conductive layer 45 can be formed using any of the materials that can be used for the conductive layer 53, for example.

A conductive layer 46 functions as a plug for connecting the conductive layer 55 and the driver circuits (not illustrated) provided below the memory cell 10, for example. The conductive layer 46 is connected to the bit line driver circuit, specifically the sense amplifier included in the bit line driver circuit, for example. The conductive layer 46 is connected to a transistor, specifically a Si transistor, included in the bit line driver circuit, for example. Note that the conductive layer 46 may be included in the wiring BL. The conductive layer 46 can be formed using any of the materials that can be used for the conductive layer 53, for example.

When the plurality of memory cells 10 are stacked as illustrated in FIGS. 7A and 7B, the memory cells 10 can be provided in an integrated manner without increasing the area occupied by the memory array. That is, a 3D memory array can be formed. Although FIG. 7B illustrates an example in which two layers of the memory cells 10 are stacked in the memory device, only one layer of the memory cells 10 may be provided or three or more layers of the memory cells 10 may be stacked.

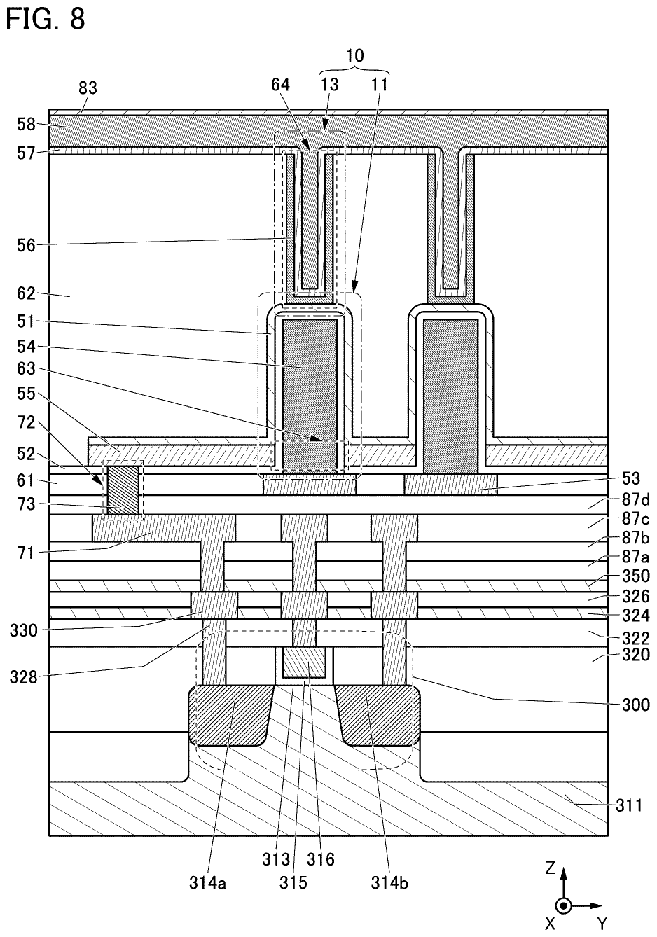

FIG. 8 is a cross-sectional view illustrating a structure example of the memory device of one embodiment of the present invention. FIG. 8 illustrates an example in which a transistor 300 included in the driver circuit is provided below the memory cell 10.

The transistor 300 is provided over a substrate 311. The substrate 311 is provided with a semiconductor region 313, a low-resistance region 314a, and a low-resistance region 314b. The transistor 300 includes the semiconductor region 313, the low-resistance region 314a, the low-resistance region 314b, an insulating layer 315, and a conductive layer 316.

The low-resistance region 314a functions as one of a source region and a drain region of the transistor 300. The low-resistance region 314b functions as the other of the source region and the drain region of the transistor 300. The insulating layer 315 functions as a gate insulating layer of the transistor 300. The conductive layer 316 functions as a gate electrode of the transistor 300.

The transistor 300 may be either a p-channel transistor or an n-channel transistor. The substrate 311 preferably contains a silicon-based semiconductor, specifically, single crystal silicon. In the case where the substrate 311 contains a silicon-based semiconductor, the transistor 300 is a Si transistor.

As the substrate 311, a structure body in which a single crystal oxide semiconductor film (typically, indium oxide film) is provided over a stabilized zirconia substrate can also be used. An indium oxide film formed over a stabilized zirconia substrate includes a single crystal. With the use of part of the indium oxide film as the semiconductor region 313, the field-effect mobility and reliability of the transistor 300 can be increased.

In the transistor 300 illustrated in FIG. 8, the semiconductor region 313 (part of the substrate 311) in which a channel is formed has a projecting shape. Furthermore, the conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projection of the semiconductor substrate is utilized. Note that an insulating layer serving as a mask for forming the projection may be provided in contact with the top of the projection. Although the case where the projection is formed by processing part of the semiconductor substrate is described here, a semiconductor film having a projecting shape may be formed by processing a silicon on insulator (SOI) substrate.

A wiring layer including an interlayer insulating layer, a wiring, a plug, and the like can be provided between components. A plurality of wiring layers can be provided in accordance with the design. Here, a plurality of conductive layers functioning as plugs or wirings are collectively denoted by the same reference numeral in some cases. In this specification and the like, a wiring and a plug connected to the wiring may be a single component. That is, part of a conductive layer functions as a wiring in some cases and part of a conductive layer functions as a plug in other cases.

For example, an insulating layer 320, an insulating layer 322, an insulating layer 324, and an insulating layer 326 are stacked over the transistor 300 in this order as interlayer insulating layers. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer insulating layer may function as a planarization film that covers a roughness thereunder. For example, the top surface of the insulating layer 322 may be planarized by planarization treatment using a chemical mechanical polishing (CMP) method or the like to improve the planarity.

A wiring layer can be provided over the insulating layer 326 and the conductive layer 330. In the example illustrated in FIG. 8, an insulating layer 350, the insulating layer 87a, the insulating layer 87b, and the insulating layer 87c are stacked in this order. The conductive layer 71 is embedded in the insulating layer 350, the insulating layer 87a, the insulating layer 87b, and the insulating layer 87c.

The conductive layers functioning as plugs or wirings, such as the conductive layers 328, 330, and 71 can be formed using any of the conductive materials that can be used for the conductive layer 53. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The insulating layer 87d is provided over the conductive layer 71 and the insulating layer 87c as described above. The conductive layer 53 and the insulating layer 61 are provided over the insulating layer 87d, and the insulating layer 52 is provided over the conductive layer 53 and the insulating layer 61. The insulating layer 87d, the insulating layer 61, and the insulating layer 52 have the opening portion 72 reaching the conductive layer 71. The conductive layer 73 is embedded in the opening portion 72. The conductive layer 55 includes the region positioned over the conductive layer 73. The conductive layer 55 included in the transistor 11 is connected to the low-resistance region 314a included in the transistor 300 through the conductive layer 73, the conductive layer 71, the conductive layer 330, and the conductive layer 328.

The transistor 300 illustrated in FIG. 8 can be the transistor included in the bit line driver circuit, specifically a transistor provided in the sense amplifier included in the bit line driver circuit. In the case where the transistor 300 is provided to include a region overlapping with the memory cell 10, the area occupied by the memory device can be smaller than that in the case where the transistor 300 does not overlap with the memory cell 10.

As illustrated in FIG. 8, the transistor 11 is provided under the capacitor 13. This enables the wiring distance between the transistor 300 and the transistor 11 to be shorter than that in the case where the transistor 11 is provided over the capacitor 13. Specifically, the opening portion 72 does not need to be provided in the insulating layer 62 as described above; thus, the length of the conductive layer 73 in the Z direction can be shortened by at least the thickness of the insulating layer 62. Accordingly, the wiring distance between one of the source electrode and the drain electrode of the transistor 11 and one of the source region and the drain region of the transistor 300 can be shortened by at least the thickness of the insulating layer 62.

Thus, the memory device can operate at high speed. In addition, the memory device can have low power consumption. Since the length of the conductive layer 73 in the Z direction can be shortened, the aspect ratio of the conductive layer 73 can be reduced. This can increase the fabrication yield of the memory device, so that the memory device can be fabricated at low cost.

As the thickness of the insulating layer 62, specifically the thickness of the insulating layer 62 in a region overlapping with the conductive layer 54, is larger, the capacitance of the capacitor 13 can be increased without an increase in the area occupied by the capacitor 13, as described above. Here, in the case where the transistor 11 is provided over the capacitor 13, the wiring distance between the transistor 300 and the transistor 11 becomes longer as the thickness of the insulating layer 62 becomes larger. By contrast, in the memory device illustrated in FIG. 8, the length of the conductive layer 73 in the Z direction does not depend on the thickness of the insulating layer 62. Accordingly, in the memory device illustrated in FIG. 8, the wiring distance between the transistor 300 and the transistor 11 can be shortened while the capacitance of the capacitor 13 is increased. This allows the memory device to have high reliability and operate at high speed.

In the example illustrated in FIG. 8, the insulating layer 83 is provided over the conductive layer 58. As described above, the insulating layer 83 preferably has a barrier property against oxygen. The insulating layer 83 preferably also has a barrier property against hydrogen.

### Structure Example 3 of Memory Device

A structure example of the memory device of one embodiment of the present invention, which is different from the structure example in FIGS. 1A to 1C, FIGS. 2A and 2B, FIGS. 3A to 3C, and FIGS. 4A and 4B, will be described below. Note that description of the portions already described is omitted and only different portions are described in detail. Even when positions or shapes of components are different from those in the above example, the same reference numerals are used as long as the components have the same functions as those in the above example, and description thereof is omitted in some cases.

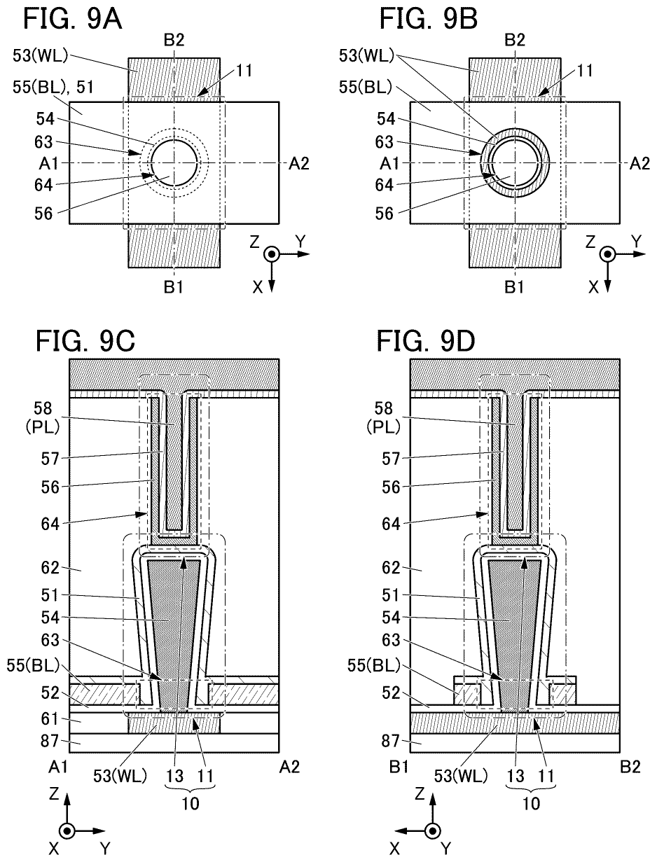

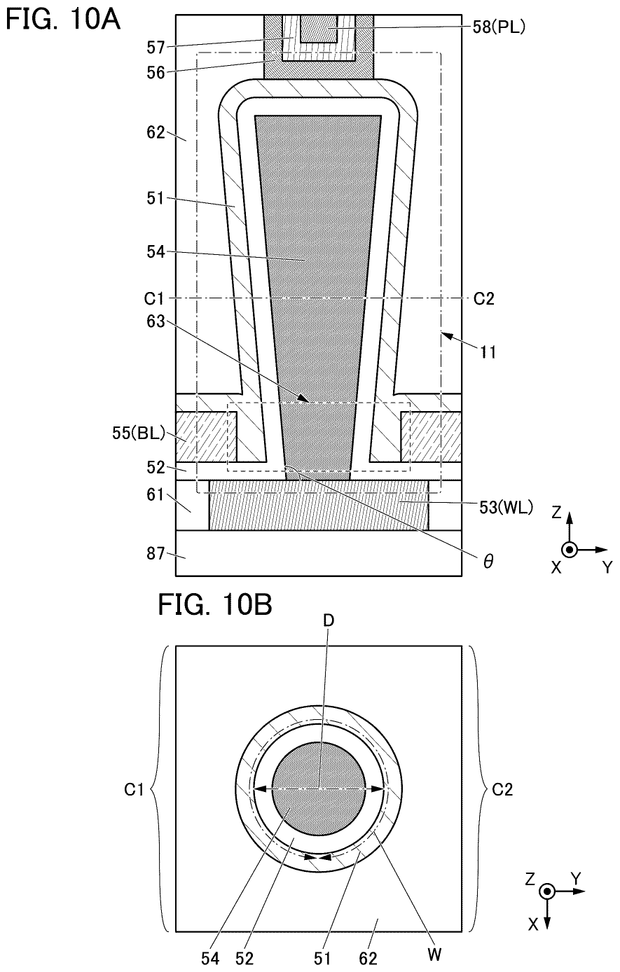

FIG. 9A is a plan view illustrating an example in which the shape of the conductive layer 54 illustrated in FIG. 2A in a plan view is a circle. FIG. 9B is a plan view omitting the semiconductor layer 51 from FIG. 9A. FIG. 9C is a cross-sectional view taken along the dashed-dotted line A1-A2 in FIGS. 9A and 9B. FIG. 9D is a cross-sectional view taken along the dashed-dotted line B1-B2 in FIGS. 9A and 9B. FIG. 10A is an enlarged view of the transistor 11 in FIG. 9C. FIG. 10B is a cross-sectional view taken along the dashed-dotted line C1-C2 in FIG. 10A. Note that FIG. 10B is also referred to as a plan view.

Depending on the formation process of the conductive layer 54, the shape of the conductive layer 54 in a plan view is a quadrangle in some cases and is a circle in other cases. The shape of the conductive layer 54 in a plan view is not limited to a quadrangle or a circle, and can be a substantially circular shape such as an ellipse, a polygonal shape such as a triangle, a pentagon, or a star polygon, or a polygonal shape with rounded corners, for example. Note that a circle is not limited to a perfect circle. A polygonal shape may be a concave polygonal shape (a polygonal shape at least one of the interior angles of which is greater than 180°) or a convex polygonal shape (a polygonal shape all the interior angles of which are less than or equal to 180°). As described above, the shape of the opening portion 63 in a plan view can be of the same type as the shape of the conductive layer 54 in a plan view. FIGS. 9A and 9B illustrate an example in which the shape of the opening portion 63 in a plan view is a circle like the shape of the conductive layer 54 in a plan view.

In the case where the shape of the conductive layer 54 in a plan view is a circle, the conductive layer 54, the insulating layer 52, and the semiconductor layer 51 can be provided concentrically. In that case, the channel width of the transistor 11 can be a value obtained by adding the width (diameter) of the conductive layer 54 and the double of the thickness of the insulating layer 52, i.e., a value obtained by multiplying the width of the inner diameter of the semiconductor layer 51 by the circular constant π, for example. In FIG. 10B, a width D of the inner diameter of the semiconductor layer 51 and the channel width W of the transistor 11 are each indicated by a dashed-dotted double-headed arrow.

In FIG. 10A, an angle between the side surface of the conductive layer 54 and the top surface of the conductive layer 53 is denoted by an angle θ. The angle θ can be an angle between the side surface of the conductive layer 54 and the above-described reference surface. For example, the angle may be an angle between the side surface of the conductive layer 54 and the top surface of the insulating layer 87. Alternatively, the angle θ may be an angle between the side surface of the conductive layer 54 and the top surface of the substrate.

FIG. 10A illustrates an example in which the angle θ is greater than 90°. In that case, the side surface of the conductive layer 54 has an inverse tapered shape. Note that FIGS. 1A to 1C, FIGS. 2A and 2B, FIGS. 3A to 3C, and FIGS. 4A and 4B illustrate an example in which the angle θ is 90°.

When the side surface of the conductive layer 54 has an inverse tapered shape, attachment of the conductive layer 55 to the side surface of the insulating layer 52 due to the formation process of the conductive layer 55 can be inhibited. Specifically, the conductive layer 55 can be inhibited from being in contact with the side surface of the insulating layer 52 at the time of forming the conductive layer 55. This enables the memory device to have high reliability.

The angle θ is preferably greater than or equal to 90°, further preferably greater than or equal to 100°, still further preferably greater than or equal to 110°. In particular, when the angle θ is greater than 110°, it becomes easy to prevent the conductive layer 55 from being in contact with the side surface of the insulating layer 52. On the other hand, when the angle θ is too large, the area occupied by the top surface of the conductive layer 54 increases. In addition, the conductive layer 55 sometimes falls down. The angle θ is preferably set in consideration of the above. For example, the angle θ is preferably less than or equal to 135°. Note that the angle θ may be less than 90°. For example, the angle θ may be greater than or equal to 80° and less than 90°, preferably greater than or equal to 85° and less than 90°, further preferably greater than or equal to 87° and less than 90°.

In the case where the angle θ is not 90°, the width D depends on the height (the position in the Z direction) of the conductive layer 54. Specifically, in the case where the angle θ is greater than 90°, the width D becomes larger as the height of the conductive layer 54 becomes larger. Thus, a value between the maximum value of the width D and the minimum value of the width D in the channel formation region, e.g., the average value, can be used as the width D in the calculation of the channel width W. Note that the maximum value of the width D or the minimum value of the width D in the channel formation region may be used as the width D in the calculation of the channel width W.

FIG. 10A illustrates an example in which the semiconductor layer 51 is provided between the side surface of the conductive layer 54 and the side surface of the conductive layer 55 in the opening portion 63. In that case, the semiconductor layer 51 can include a region in contact with the side surface of the conductive layer 55 in the opening portion 63. In the case where the angle θ is greater than 90°, the side surface of the conductive layer 55 in the opening portion 63 sometimes overlaps with the side surface of the conductive layer 54.

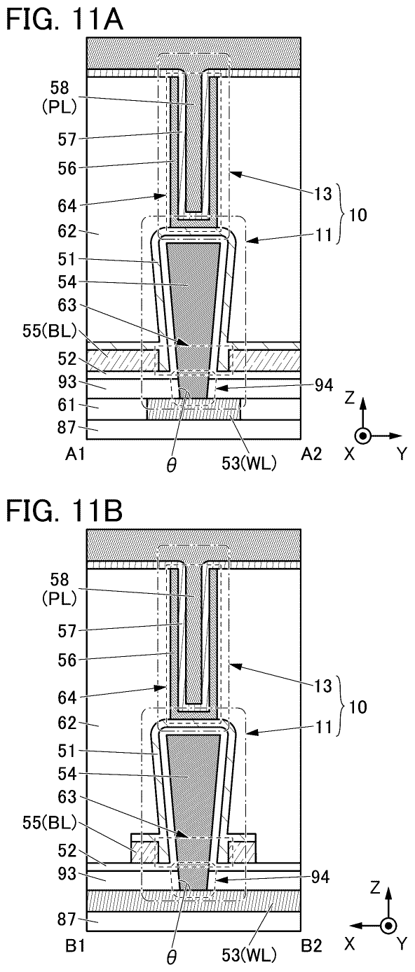

FIGS. 11A and 11B illustrate modification examples of the memory device illustrated in FIGS. 9C and 9D, respectively, and illustrate an example in which a layer 93 is provided between the insulating layer 52 and each of the conductive layer 53 and the insulating layer 61. Note that FIGS. 9A and 9B can be referred to for a plan view.

The layer 93 has an opening portion 94 reaching the conductive layer 53. The conductive layer 54 can include a region in contact with the top surface of the conductive layer 53 in the opening portion 94. The conductive layer 54 can be provided to fill the opening portion 94. The conductive layer 54 provided to include a region positioned in the opening portion 94 can be easily prevented from falling down even when the angle θ is made larger.

The layer 93 can be formed using any of the insulating materials described later in [Insulating layer], for example. As the layer 93, an inorganic insulating film, specifically an oxide insulating film, a nitride insulating film, or an oxynitride insulating film, can be used, for example. The layer 93 can be formed using silicon oxide, silicon nitride, silicon oxynitride, aluminum oxide, aluminum nitride, or aluminum oxynitride, for example. Note that the layer 93 may have a stacked-layer structure of two or more layers.

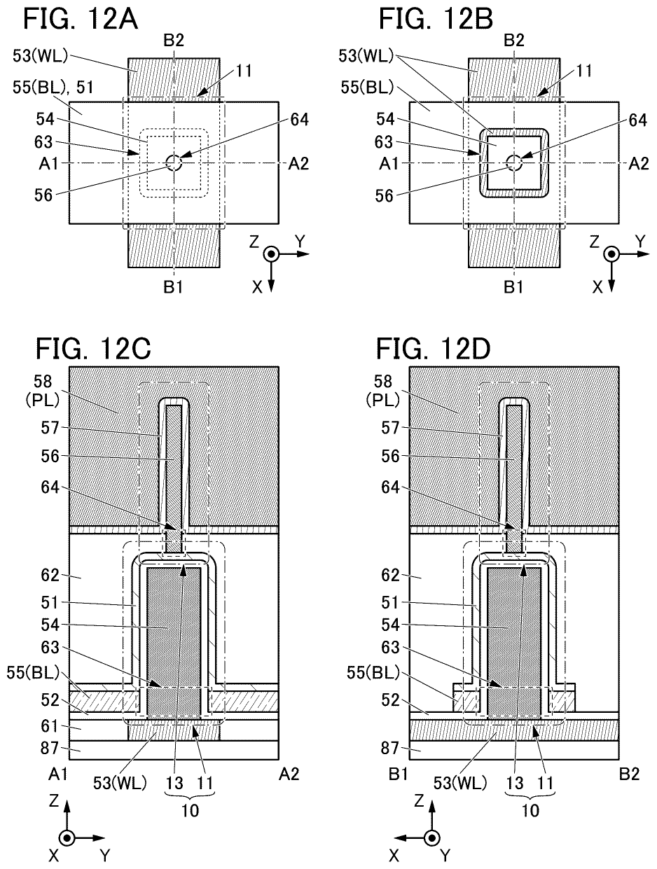

FIG. 12A is a plan view illustrating a structure example of the memory device of one embodiment of the present invention. FIG. 12B is a plan view omitting the semiconductor layer 51 from FIG. 12A. FIG. 12C is a cross-sectional view taken along the dashed-dotted line A1-A2 in FIGS. 12A and 12B. FIG. 12D is a cross-sectional view taken along the dashed-dotted line B1-B2 in FIGS. 12A and 12B. FIGS. 12A to 12D illustrate an example in which the structure of the capacitor 13 is different from that of the capacitor 13 illustrated in FIGS. 2A and 2B, FIGS. 3A and 3B, and the like.

In the example illustrated in FIGS. 12A to 12D, the conductive layer 56 is provided to fill the opening portion 64. The level of the top surface of the conductive layer 56 is higher than that of the top surface of the insulating layer 62. Specifically, the level of the top surface of the conductive layer 56 from the reference surface is higher than that of the top surface of the insulating layer 62 from the reference surface. FIGS. 12C and 12D illustrate an example in which the conductive layer 56 is a cylinder. Note that the conductive layer 56 may be a quadrangular prism. The conductive layer 56 may be an elliptical cylinder, a triangular prism, or a polygonal prism whose bottom surface has a polygonal shape with five or more corners. The conductive layer 56 may include a region having a cone shape, an elliptical cone shape, or a pyramid shape such as a polygonal pyramid. Furthermore, the conductive layer 56 may have a pillar shape or a pyramid shape whose bottom surface has a polygonal shape, such as a quadrangle, with rounded corners. Note that the capacitor 13 illustrated in FIGS. 12C and 12D is also referred to as a pillar capacitor.

In the case where the conductive layer 56 includes a pillar region, it is preferable that the side surface of the conductive layer 56 be perpendicular or substantially perpendicular to the reference surface. For example, it is preferable that the side surface of the conductive layer 56 be perpendicular or substantially perpendicular to the top surface of the semiconductor layer 51 or the top surface of the conductive layer 54. Thus, the area occupied by the conductive layer 56 can be reduced, and the memory cells 10 can be highly integrated. In the case where the conductive layer 56 includes the pillar region, an angle between the side surface of the conductive layer 56 and the top surface of the semiconductor layer 51 or the top surface of the conductive layer 54 is preferably greater than or equal to 60°, further preferably greater than or equal to 70°, still further preferably greater than or equal to 80°, and less than or equal to 90°.

In the case where the conductive layer 56 includes a conical or pyramidal region, the side surface of the conductive layer 56 has a tapered shape, for example. The tapered side surface of the conductive layer 56 can increase the coverage of the conductive layer 56 with the insulating layer 57 and the coverage of the insulating layer 57 with the conductive layer 58, for example.

As the height of the conductive layer 56 is larger, i.e., as the length of the conductive layer 56 in the Z direction is longer, the capacitance of the capacitor 13 can be increased without an increase in the area occupied by the capacitor 13. Increasing the capacitance per unit area of the capacitor 13 in this manner can stabilize the operation of reading data from the memory cell 10 while an increase in the area occupied by the memory cell 10 is inhibited.

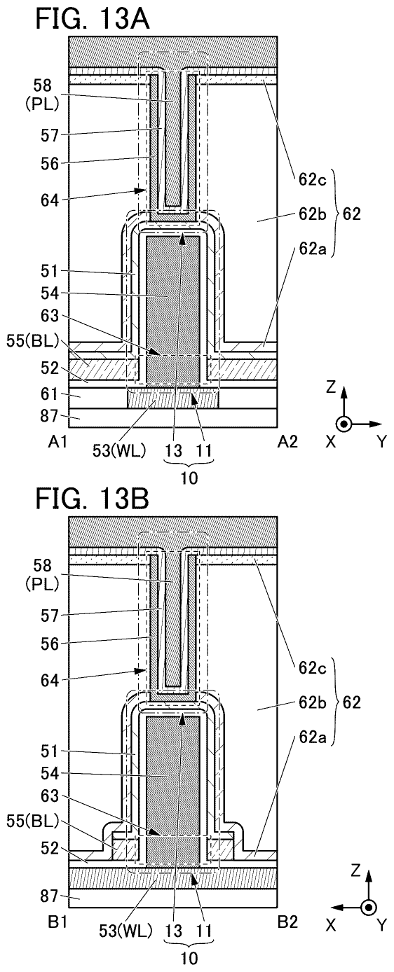

FIGS. 13A and 13B respectively illustrate the insulating layer 62 illustrated in FIG. 3A and the insulating layer 62 illustrated in FIG. 3B, each of which has a three-layer structure of an insulating layer 62a, an insulating layer 62b over the insulating layer 62a, and an insulating layer 62c over the insulating layer 62b, for example.

The insulating layer 62a preferably has a barrier property against hydrogen. Thus, diffusion of hydrogen into the semiconductor layer 51 can be inhibited. For example, diffusion of hydrogen into the channel formation region of the semiconductor layer 51 and entry of hydrogen into oxygen vacancies in the channel formation region can be inhibited. That is, formation of V_{O}H in the channel formation region of the semiconductor layer 51 can be inhibited. The insulating layer 62a can be formed using an insulating material having a barrier property against hydrogen, which is described later in [Insulating layer], such as silicon nitride.

Alternatively, the insulating layer 62a preferably has a function of capturing or fixing (also referred to as gettering) hydrogen. In that case, hydrogen contained in the semiconductor layer 51 can be captured or fixed. This can reduce the amount of hydrogen contained in the semiconductor layer 51. Thus, formation of V_{O}H in the semiconductor layer 51, specifically in the channel formation region, can be inhibited. The insulating layer 62a can be formed using an insulating material having a function of capturing or fixing hydrogen, which is described later in [Insulating layer]. It is particularly preferable to use hafnium oxide that can transmit oxygen for the insulating layer 62a, in which case oxygen, specifically excess oxygen, contained in the insulating layer 62b can be supplied to the semiconductor layer 51.

The insulating layer 62b can be formed using any of the materials that can be used for the insulating layer 62. For example, the insulating layer 62b can be formed using silicon oxide or silicon oxynitride. The insulating layer 62b can include a region containing excess oxygen.

The insulating layer 62c preferably has a barrier property against oxygen. Thus, outward diffusion of excess oxygen contained in the insulating layer 62b can be inhibited. Specifically, outward diffusion of excess oxygen contained in the insulating layer 62b during the fabrication process of the memory device can be inhibited. This facilitates supply of excess oxygen contained in the insulating layer 62b to the semiconductor layer 51.

The insulating layer 62c preferably has a property of transmitting hydrogen. Thus, impurities such as water and hydrogen in the insulating layer 62 can diffuse outwardly during the fabrication process of the memory device. This enables the concentration of impurities such as water and hydrogen in the insulating layer 62 to be lower than that in the case where the insulating layer 62c has a barrier property against hydrogen.

Accordingly, the memory device can have high reliability. The insulating layer 62c can be formed using aluminum oxide, for example. Note that the insulating layer 62 does not necessarily include one or two of the insulating layer 62a, the insulating layer 62b, and the insulating layer 62c. For example, the insulating layer 62 does not necessarily include the insulating layer 62c. In the case where planarization treatment is performed by a CMP method or the like on the top surface of the insulating layer 62 after the insulating layer 62c is formed, for example, the insulating layer 62c is sometimes removed. The insulating layer 62 does not necessarily include the insulating layer 62a, or does not necessarily include the insulating layer 62b. In the case where the insulating layer 62 includes not the insulating layer 62b but the insulating layer 62c, the insulating layer 62a can have a larger thickness than the insulating layer 62c. In the case where the insulating layer 62 does not include the insulating layer 62b, the top surface of the insulating layer 62a can be planarized.

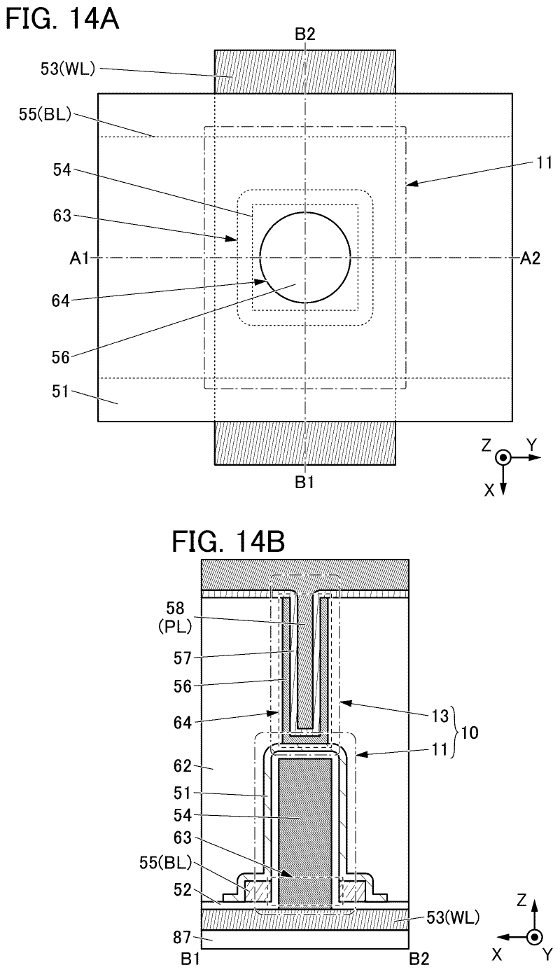

FIG. 14A is a plan view illustrating an example in which the side end portion of the semiconductor layer 51 illustrated in FIG. 2A is positioned outward from the side end portion of the conductive layer 55 (extends to the side opposite to the conductive layer 54). FIG. 14B is a cross-sectional view taken along the dashed-dotted line B1-B2 in FIG. 14A. FIG. 3A can be referred to for a cross-sectional view taken along the dashed-dotted line A1-A2 in FIG. 14A.

When the transistor 11 has a structure illustrated in FIGS. 14A and 14B, the semiconductor layer 51 includes not only the region in contact with the top surface of the conductive layer 55 but also the region in contact with the side surface of the conductive layer 55. This can increase the contact area between the semiconductor layer 51 and the conductive layer 55. Thus, the contact resistance between the semiconductor layer 51 and the conductive layer 55 can be reduced.

In the memory device illustrated in FIGS. 14A and 14B, the insulating layer 62 can have a structure without a region in contact with the side surface of the conductive layer 55. Although FIGS. 14A and 14B illustrate an example in which the semiconductor layer 51 is provided in a band shape extending in the Y direction, the semiconductor layer 51 may be provided in an island shape. In that case, the insulating layer 62 can include a region in contact with the top surface of the conductive layer 55 and a region in contact with the side surface of the conductive layer 55.

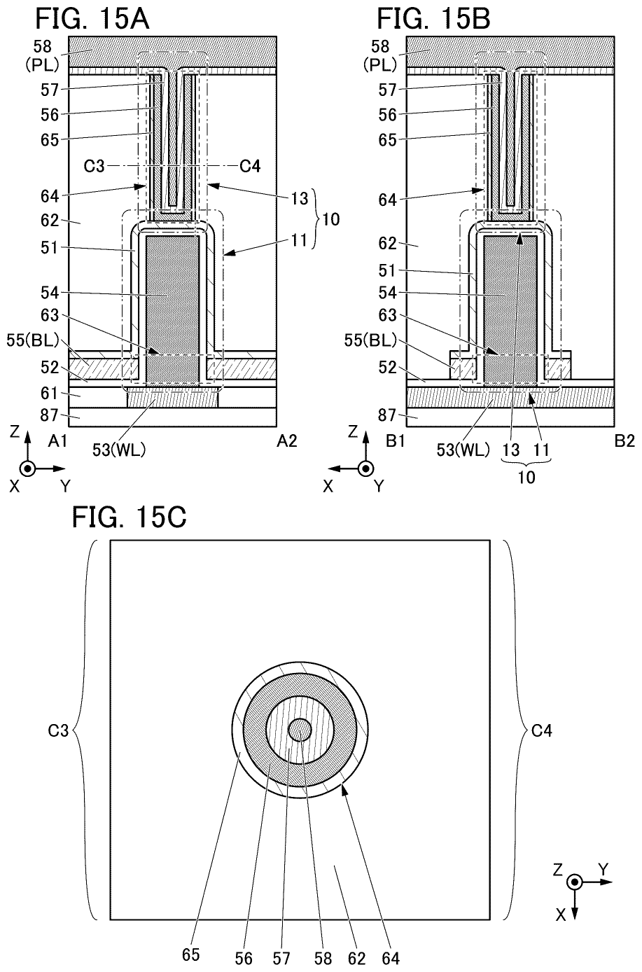

FIGS. 15A and 15B illustrate an example in which an insulating layer 65 is provided in the opening portion 64 illustrated in FIGS. 3A and 3B. FIG. 15C is a cross-sectional view taken along the dashed-dotted line C3-C4 in FIG. 15A. Note that FIG. 15C is also referred to as a plan view.

The insulating layer 65 is provided along the side surface of the insulating layer 62 in the opening portion 64. FIG. 15C illustrates an example in which the opening portion 64 has a circular shape in a plan view and the insulating layer 65 has a ring shape in a plan view. In the example illustrated in FIGS. 15A to 15C, the conductive layer 56, the insulating layer 57, and the conductive layer 58 are positioned in this order inward from the insulating layer 65.

The insulating layer 65 preferably has a barrier property against oxygen. Thus, oxidation of the conductive layer 56 due to oxygen, specifically excess oxygen, contained in the insulating layer 62 can be inhibited, thereby inhibiting an increase in the electrical resistance of the conductive layer 56, for example. Accordingly, the memory device can operate at high speed. The insulating layer 65 can be formed using an insulating material having a barrier property against oxygen, which is described later in [Insulating layer], such as silicon nitride.

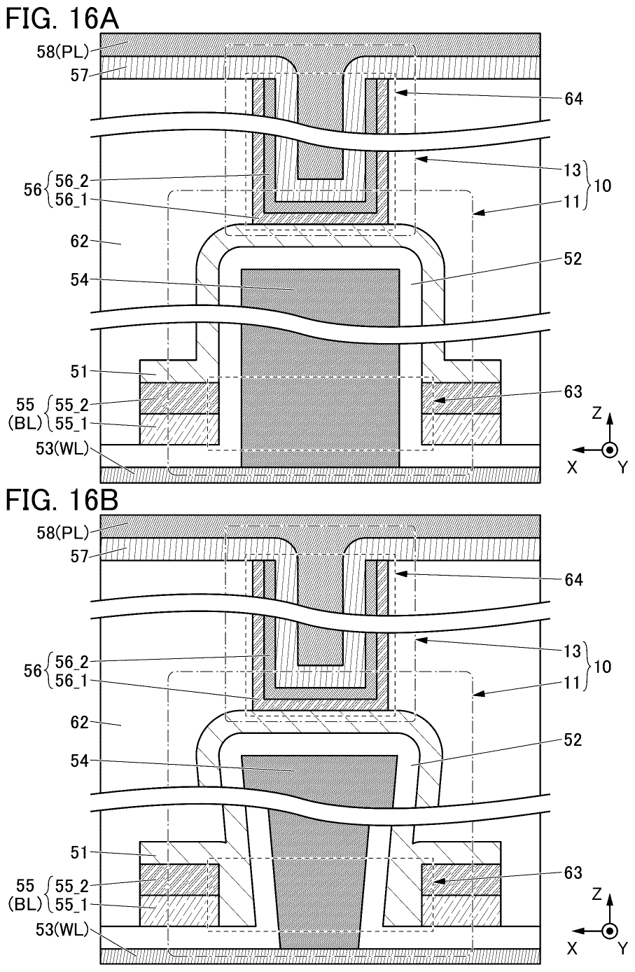

FIG. 16A is an enlarged view of the memory cell 10 illustrated in FIG. 3B. FIG. 16B is an enlarged view of the memory cell 10 illustrated in FIG. 9D. FIGS. 16A and 16B illustrate an example in which the conductive layer 55 has a two-layer structure of a conductive layer 55_1 and a conductive layer 55_2 over the conductive layer 55_1. FIGS. 16A and 16B also illustrate an example in which the conductive layer 56 has a two-layer structure of a conductive layer 56_1 and a conductive layer 56_2 over the conductive layer 56_1.

The conductive layer 55_2 and the conductive layer 56_1 each including a region in contact with the semiconductor layer 51 are preferably formed using a conductive material that is less likely to be oxidized, a conductive material that maintains its conductivity even after absorbing oxygen, or a conductive material having a function of inhibiting diffusion of oxygen. That is, the conductive layer 55_2 and the conductive layer 56_1 are preferably formed using a conductive material containing nitrogen, a conductive material containing oxygen, or the like. Thus, a decrease in the conductivity of the conductive layer 55_2 and the conductive layer 56_1 can be inhibited even when a metal oxide is used for the semiconductor layer 51. For example, ITO, ITSO, In—Zn oxide, In—Ti oxide, or the like can be used for the conductive layer 55_2. Titanium nitride, tantalum nitride, or the like can be used for the conductive layer 56_1.

The conductive layer 55_1 that is not in contact with the semiconductor layer 51 preferably contains a material having higher conductivity than the material for the conductive layer 55_2. Thus, the conductive layer 55_1 can have higher conductivity than the conductive layer 55_2. This enables the conductivity of the conductive layer 55 to be higher than that in the case where the conductive layer 55 does not include the conductive layer 55_1. Similarly, the conductive layer 56_2 that is not in contact with the semiconductor layer 51 preferably contains a material having higher conductivity than the material for the conductive layer 56_1, in which case the conductivity of the conductive layer 56 can be high. The conductive layer 55_1 and the conductive layer 56_2 can each contain at least one of tungsten, copper, and aluminum, for example.

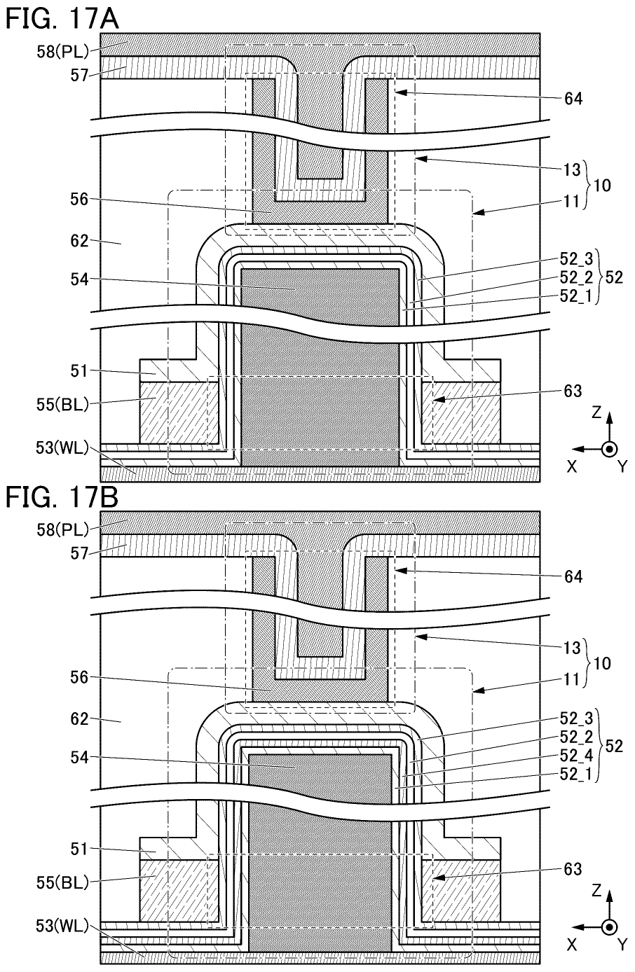

FIGS. 17A and 17B are enlarged views of the memory cell 10 illustrated in FIG. 3B. FIG. 17A illustrates an example in which the insulating layer 52 has a three-layer structure of an insulating layer 52_1, an insulating layer 52_2 over the insulating layer 52_1, and an insulating layer 52_3 over the insulating layer 52_2.

The insulating layer 52_1 preferably has a barrier property against hydrogen. Such a structure can inhibit diffusion of hydrogen into the semiconductor layer 51. The insulating layer 52_1 preferably also has a barrier property against oxygen. The insulating layer 52_1 is provided between the channel formation region in the semiconductor layer 51 and the conductive layer 54. Such a structure can inhibit oxygen contained in the channel formation region in the semiconductor layer 51 from diffusing into the conductive layer 54 and the like and thus can inhibit formation of oxygen vacancies in the channel formation region. Oxygen contained in the semiconductor layer 51 can be inhibited from diffusing into the conductive layer 54 and the like and oxidizing the conductive layer 54 and the like. The insulating layer 52_1 preferably has a lower oxygen-transmitting property than at least the insulating layer 52_2. The insulating layer 52_1 preferably has a function of inhibiting diffusion of hydrogen. Thus, diffusion of impurities such as hydrogen contained in the conductive layer 54 and the like into the semiconductor layer 51 can be prevented. For example, silicon nitride is preferably used for the insulating layer 52_1.

The insulating layer 52_2 is preferably formed using a low-dielectric-constant material. For example, silicon oxide or silicon oxynitride is preferably used for the insulating layer 52_2.

The insulating layer 52_3 including a region in contact with the semiconductor layer 51 preferably has a barrier property against oxygen. Thus, diffusion of oxygen contained in the semiconductor layer 51 into the conductive layer 54 and the like can be inhibited, thereby inhibiting oxidation of the conductive layer 54 and the like.

As the insulating layer 52_3, an insulating film containing gallium and oxygen can be used, for example. An insulating film containing aluminum and oxygen can also be used as the insulating layer 52_3. For example, gallium oxide or aluminum oxide can be used for the insulating layer 52_3.

It is particularly preferable to use gallium oxide for the insulating layer 52_3. The ion radius of gallium is closer to that of indium than the ion radius of aluminum is. In other words, the difference between the ion radii of indium and gallium is smaller than the difference between the ion radii of indium and aluminum. Thus, in the case where indium oxide is used for the semiconductor layer 51, the use of gallium oxide for the insulating layer 52_3 increases the frequency of formation of a bond between an indium atom in the semiconductor layer 51 and a gallium atom in the insulating layer 52_3 through an oxygen atom. This can inhibit generation of oxygen vacancies, oxygen having a dangling bond, or the like at the interface between the semiconductor layer 51 and the insulating layer 52_3.

A high-k material is preferably used for the insulating layer 52_3. When a high-k material is used for the insulating layer 52_3, a potential applied to the conductive layer 53 during the operation of the transistor 11 can be lowered while the physical thickness of the insulating layer 52 functioning as the gate insulating layer of the transistor 11 is maintained. Furthermore, the equivalent oxide thickness (EOT) of the insulating layer 52 can be reduced. Gallium oxide and aluminum oxide described above are high-k materials and thus can be suitably used for the insulating layer 52_3. Examples of the high-k material that can be used for the insulating layer 52_3 include, in addition to gallium oxide and aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

FIG. 17B illustrates an example in which an insulating layer 52_4 is provided between the insulating layer 52_1 and the insulating layer 52_2 illustrated in FIG. 17A. As the insulating layer 52_4, an insulating film having a function of capturing or fixing hydrogen is used. In that case, hydrogen contained in the semiconductor layer 51 can be captured or fixed. This can reduce the amount of hydrogen contained in the semiconductor layer 51. Thus, formation of V_{O}H in the semiconductor layer 51, specifically in the channel formation region, can be inhibited. Accordingly, the transistor 11 can be prevented from being normally on. Consequently, the transistor can have excellent electrical characteristics and high reliability. In addition, the memory device can have high reliability.

As the insulating layer 52_4, an insulating film containing hafnium and oxygen can be used, for example. Specifically, hafnium oxide, hafnium zirconium oxide, an oxide containing hafnium and silicon, or the like can be used for the insulating layer 52_4.

Here, gallium oxide and aluminum oxide are each an insulating material having a lower barrier property against hydrogen than silicon nitride, for example. Thus, the insulating layer 52_3 formed using gallium oxide or aluminum oxide transmits hydrogen in the semiconductor layer 51. Accordingly, even in the case where the insulating layer 52_3 is provided to include a region in contact with the semiconductor layer 51, hydrogen in the semiconductor layer 51 can be captured or fixed by the insulating layer 52_4.

Specifically, the insulating layer 52 preferably has a four-layer structure in which a gallium oxide film, a silicon oxide film, a hafnium oxide film, and a silicon nitride film are stacked in this order from the semiconductor layer 51 side. With such a structure, hydrogen in the semiconductor layer 51 can diffuse into the insulating layer 52_4, and the hydrogen can be captured or fixed. Thus, the hydrogen concentration in the semiconductor layer 51 can be reduced.

The insulating layer 52 is preferably thin. For example, when the thickness of the insulating layer 52 is greater than or equal to 1 nm and less than or equal to 20 nm, preferably greater than or equal to 3 nm and less than or equal to 10 nm, the subthreshold swing value (also referred to as an S value) can be reduced. Note that the S value means the amount of change in gate voltage in a subthreshold region when drain voltage is constant and drain current is changed by one order of magnitude.

The thickness of each layer included in the insulating layer 52 is preferably greater than or equal to 0.1 nm and less than or equal to 20 nm, preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that each layer included in the insulating layer 52 at least partly preferably includes a region with the above-described thickness.

The insulating layer 52_1 in the insulating layer 52 having the four-layer structure is not necessarily provided. For example, an insulating layer containing a low-dielectric-constant material can be used as the insulating layer 52_2, an insulating layer having a function of capturing or fixing oxygen can be used as the insulating layer 52_3, and an insulating layer having a function of capturing or fixing hydrogen can be used as the insulating layer 52_4. Specifically, the insulating layer 52 can have a three-layer structure in which a gallium oxide film, a silicon oxide film, and a hafnium oxide film are stacked in this order from the semiconductor layer 51 side.

In order that the insulating layers 52_1 to 52_4 can have small thicknesses as described above, an atomic layer deposition (ALD) method is preferably employed. In order that the insulating layers 52_1 to 52_4 can be formed to cover the conductive layer 54 with good coverage, an ALD method is preferably employed.

Note that in formation of the insulating layer 52 having a stacked-layer structure of a plurality of insulating films, an ALD process is preferably performed twice or more. For example, two or more kinds of the insulating films in the insulating layer 52 are preferably formed through an ALD process. When at least two kinds of insulating films are formed through an ALD process, the coverage with the insulating layer 52 and the thickness uniformity of the insulating layer 52 can be improved. When two or more kinds of insulating films are successively formed through an ALD process, for example, the productivity can be increased.

Although the insulating layer 52 has the three-layer structure or the four-layer structure in the above description, the present invention is not limited thereto. The insulating layer 52 can have a structure including at least one of the insulating layers 52_1 to 52_4. When the insulating layer 52 is formed of one, two, or three of the insulating layers 52_1 to 52_4, the fabrication process of the memory device can be simplified and the productivity can be improved.

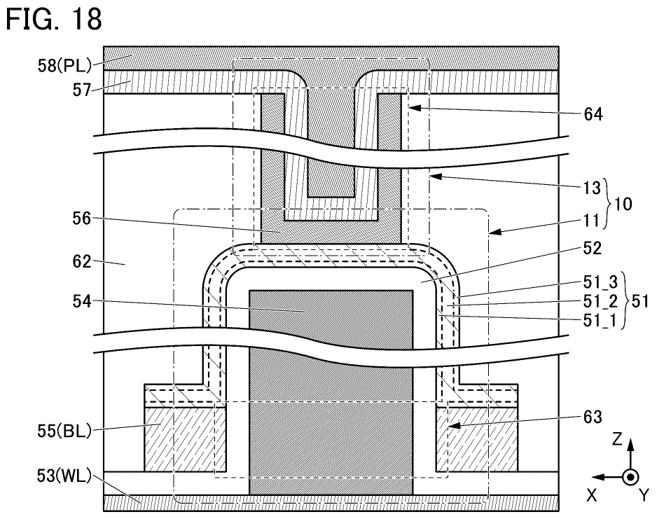

FIG. 18 is an enlarged view of the memory cell 10 illustrated in FIG. 3B. FIG. 18 illustrates an example in which the semiconductor layer 51 has a three-layer structure of a semiconductor layer 51_1, a semiconductor layer 51_2 over the semiconductor layer 51_1, and a semiconductor layer 51_3 over the semiconductor layer 51_2. Here, the semiconductor layer 51_1 includes a region in contact with the conductive layer 55 and a region in contact with the insulating layer 52. The semiconductor layer 51_3 includes a region in contact with the conductive layer 56 and a region in contact with the insulating layer 62. Note that a boundary (also referred to as an interface) between the semiconductor layer 51_1 and the semiconductor layer 51_2 and a boundary (an interface) between the semiconductor layer 51_2 and the semiconductor layer 51_3 cannot be clearly observed in some cases. Thus, the interfaces are denoted by dashed lines in FIG. 18.

It is preferable that indium oxide containing a first element whose bonding strength with oxygen is higher than that of indium with oxygen be used for the semiconductor layer 51_1 in contact with the insulating layer 52, and indium oxide be used for the semiconductor layer 51_2 not in contact with the insulating layer 52. Such a structure can inhibit formation of oxygen vacancies and V_{O}H in the vicinity of the interface between the semiconductor layer 51_1 and the insulating layer 52. Thus, scattering in the vicinity of the surface of the semiconductor layer 51 on the insulating layer 52 side is suppressed. Accordingly, the transistor 11 can have a high on-state current.

As the first element contained in the semiconductor layer 51_1, one or more selected from gallium, aluminum, yttrium, scandium, titanium, tungsten, molybdenum, tin, zirconium, hafnium, and tantalum can be used, for example. The first element is preferably one or more selected from gallium, aluminum, scandium, and yttrium, further preferably gallium or aluminum, still further preferably gallium.

Gallium is suitable because the bonding strength with oxygen is high and the bond length between gallium and oxygen is close to that between indium and oxygen.

Scandium oxide and yttrium oxide can each have a bixbyite structure like indium oxide; thus, scandium and yttrium are suitable in terms of facilitating maintenance of the crystal structure even when the content of scandium or yttrium is increased.

Gallium, aluminum, yttrium, and scandium mainly exist as trivalent cations like an indium atom. Thus, the use of gallium, aluminum, yttrium, or scandium as the first element allows the carrier concentration of the semiconductor layer 51_1 to be kept low.

The bonding strength of titanium or tungsten with oxygen is higher than that of molybdenum or tin with oxygen. Thus, formation of oxygen vacancies and V_{O}H in the semiconductor layer 51 can be inhibited more in the case where titanium or tungsten is used as the first element contained in the semiconductor layer 51_1 than in the case where molybdenum or tin is used as the first element. On the other hand, the bond length between oxygen and molybdenum or the bond length between oxygen and tin is closer to that between indium and oxygen than the bond length between oxygen and titanium or the bond length between oxygen and tungsten is. Thus, the crystal structure of the semiconductor layer 51 can be maintained more easily in the case where molybdenum or tin is used as the first element than in the case where titanium or tungsten is used as the first element even when the content of the first element in the semiconductor layer 51_1 increases.

The semiconductor layer 51_3 preferably contains indium, oxygen, and the first element whose bonding strength with oxygen is higher than that of indium with oxygen. For specific examples of the first element, the above description can be referred to. When the semiconductor layer 51_3 contains the first element, formation of oxygen vacancies and V_{O}H in the semiconductor layer 51_3 and in the vicinity of the interface between the semiconductor layer 51_3 and the insulating layer 62 can be inhibited. Thus, scattering in the vicinity of the surface of the semiconductor layer 51 on the insulating layer 62 side can be inhibited. Note that the semiconductor layer 51 does not necessarily include the semiconductor layer 51_3.

The proportion of the number of atoms of the first element to the total number of atoms of indium and the first element in each of the semiconductor layer 51_1 and the semiconductor layer 51_3 is preferably higher than that in the semiconductor layer 51_2.

An oxide containing the first element has a wider band gap than indium oxide. Thus, indium oxide containing the first element sometimes has a wider band gap than indium oxide. In addition, indium oxide containing the first element sometimes has a lower electron affinity than indium oxide. When the electron affinity of each of the semiconductor layer 51_1 and the semiconductor layer 51_3 is lower than that of the semiconductor layer 51_2, a carrier flow path can be kept away from the interface between the insulating layer 52 and the semiconductor layer 51, so that the influence of surface scattering can be reduced in some cases. Consequently, the on-state current, reliability, or the like can be increased in some cases. With such a structure, the transistor 11 can have a buried channel structure.

The semiconductor layer 51_2 preferably includes a crystal part or a crystal region. The crystal structure of indium oxide is a bixbyite structure. That is, the crystal structure of the crystal part included in the semiconductor layer 51_2 is a bixbyite structure. Note that a layer including a crystal part or a crystal region can be rephrased as a layer having crystallinity.

Single crystal indium oxide is particularly preferably used for the semiconductor layer 51_2; alternatively, polycrystal or microcrystal indium oxide can be used. The use of single crystal indium oxide can inhibit carrier scattering or the like at the crystal grain boundary, thereby allowing the transistor to have high field-effect mobility. In addition, the transistor can have high reliability.

In the case of using polycrystal indium oxide, the crystal grain boundary is preferably not observed at least in the channel formation region (a region facing the conductive layer 54 with the insulating layer 52 therebetween). In other words, the region of the semiconductor layer 51_2 that faces the conductive layer 54 with the insulating layer 52 therebetween is preferably included in the crystal part of the semiconductor layer 51_2. In that case, even in the case of using polycrystal indium oxide, an effect similar to the effect obtained when single crystal indium oxide is used can be obtained.

The semiconductor layer 51_1 preferably includes a crystal part or a crystal region. The crystal structure of the crystal part included in the semiconductor layer 51_1 is preferably a bixbyite structure. Thus, indium oxide can be epitaxially grown on the semiconductor layer 51_1, so that the crystallinity of the semiconductor layer 51_2 can be increased.

When the semiconductor layer 51_2 includes a crystal part or a crystal region, indium oxide containing the first element can be epitaxially grown on the semiconductor layer 51_2, so that the semiconductor layer 51_3 can include a crystal part or a crystal region. In that case, the crystal orientation of the crystal part of the semiconductor layer 51_3 is aligned with that of the crystal part of the semiconductor layer 51_2.

### Example of Method for Fabricating Memory Device

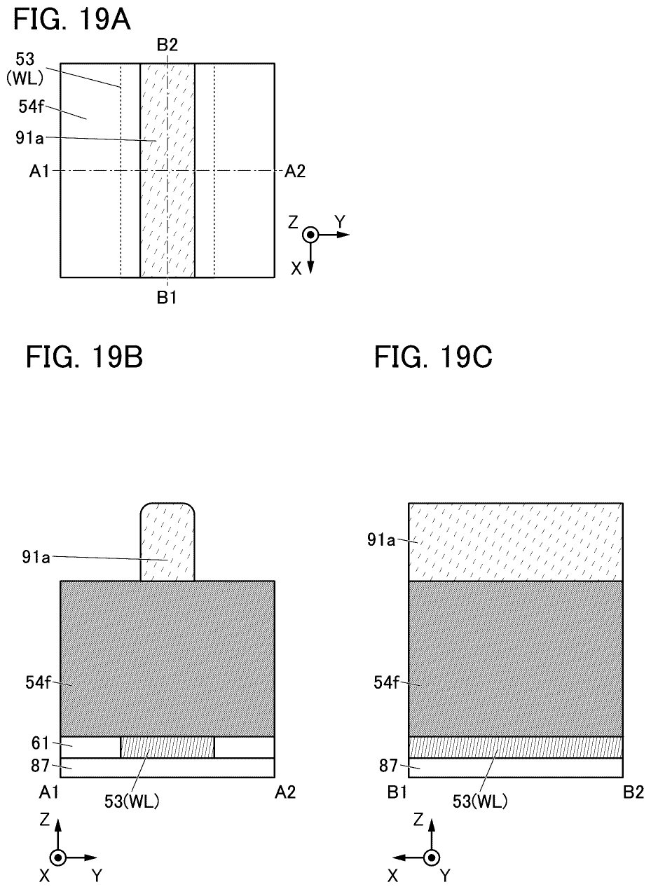

An example of a method for fabricating the memory device of one embodiment of the present invention will be described with reference to FIGS. 19A to 19C to FIGS. 33A to 33C. As for a material and a formation method of each component, portions similar to those described above are not described in some cases.

Thin films included in the memory device (e.g., insulating films, semiconductor films, and conductive films) can be formed by any of a sputtering method, a chemical vapor deposition (CVD) method, a vacuum evaporation method, a pulsed laser deposition (PLD) method, an ALD method, a molecular beam epitaxy (MBE) method, and the like. Examples of a CVD method include a plasma-enhanced CVD (PECVD) method, a thermal CVD method, and a photo CVD method. Examples of a thermal CVD method include a metal organic CVD (MOCVD) method and a metal CVD method.

The thin films included in the memory device (e.g., the insulating films, the semiconductor films, and the conductive films) can be formed by a method such as spin coating, dipping, spray coating, ink-jetting, dispensing, screen printing, offset printing, slit coating, roll coating, or curtain coating.

The thin films included in the memory device can be processed using a photolithography method or the like. Besides, a nanoimprinting method, a lift-off method, or the like may be used to process the thin films. Alternatively, island-shaped thin films may be directly formed by a film formation method using a shielding mask such as a metal mask.

As etching, dry etching, wet etching, or the like can be used.

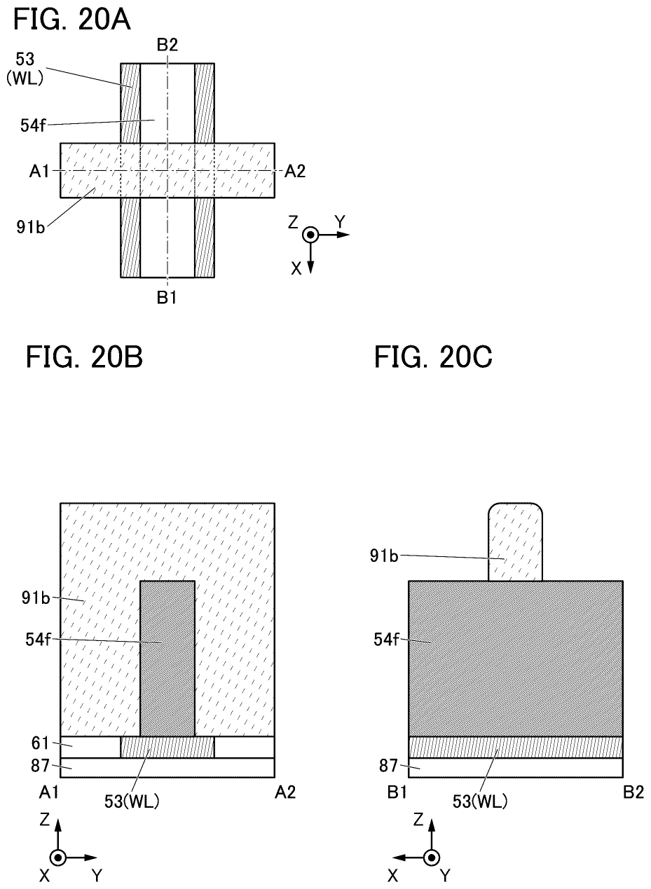

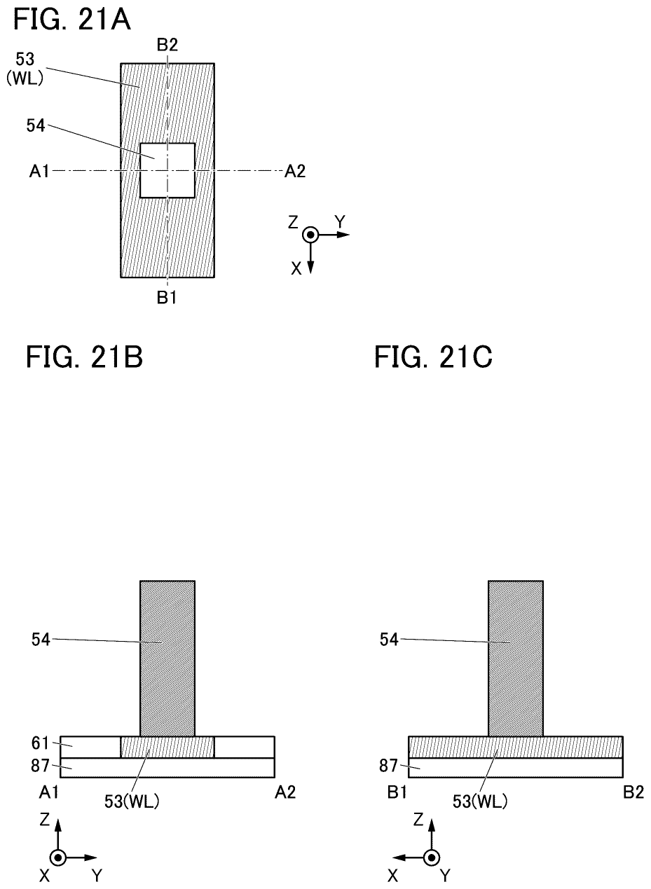

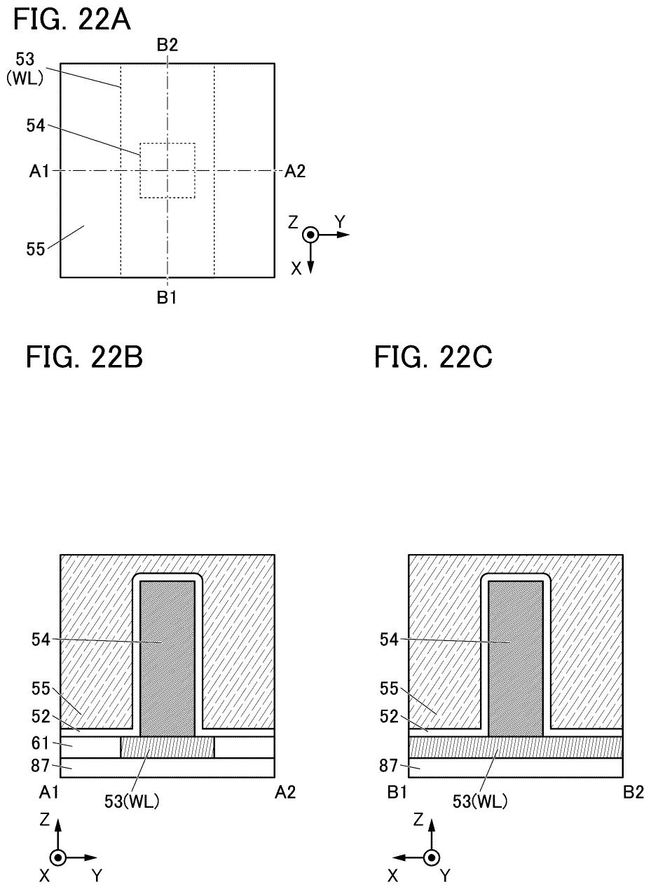

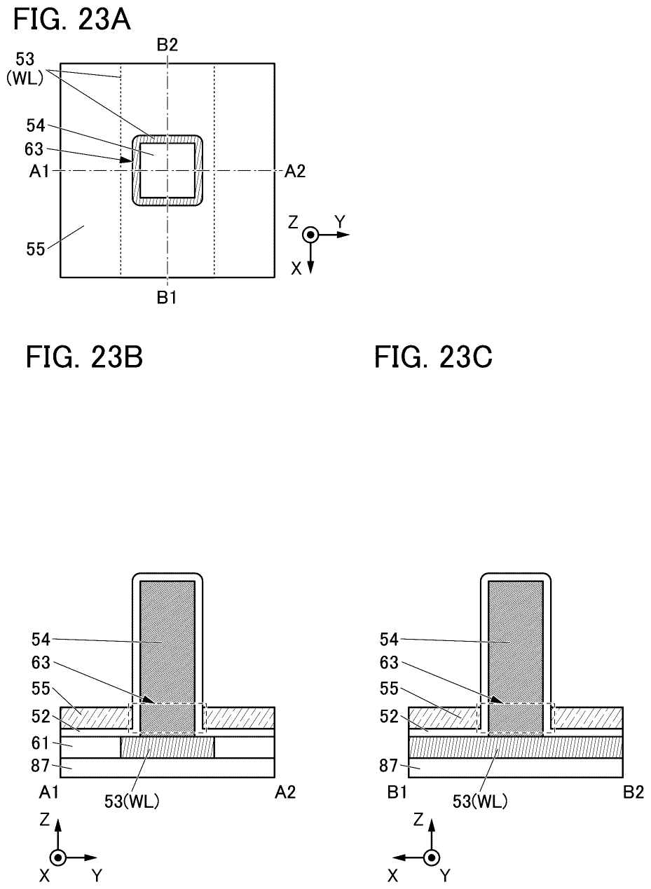

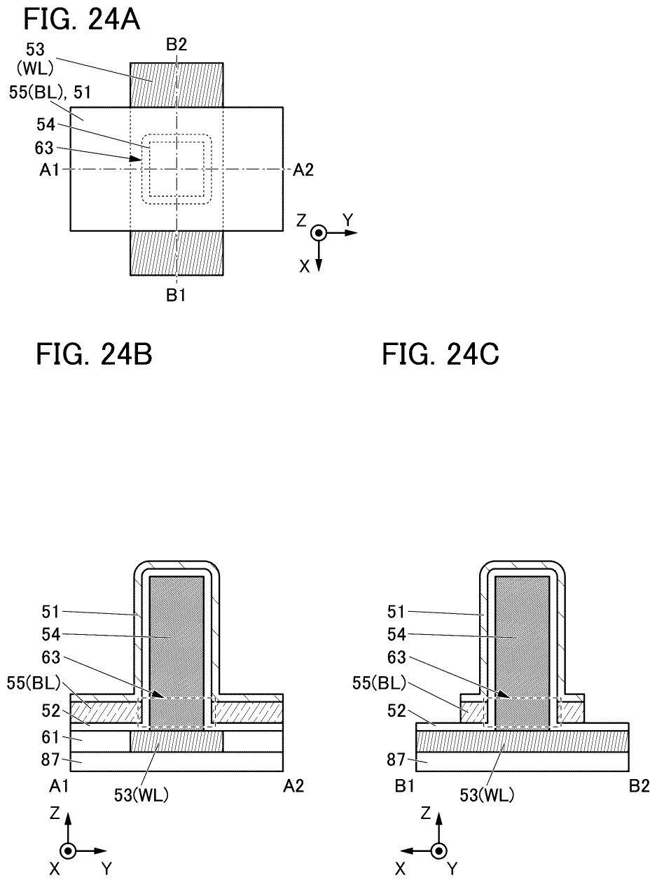

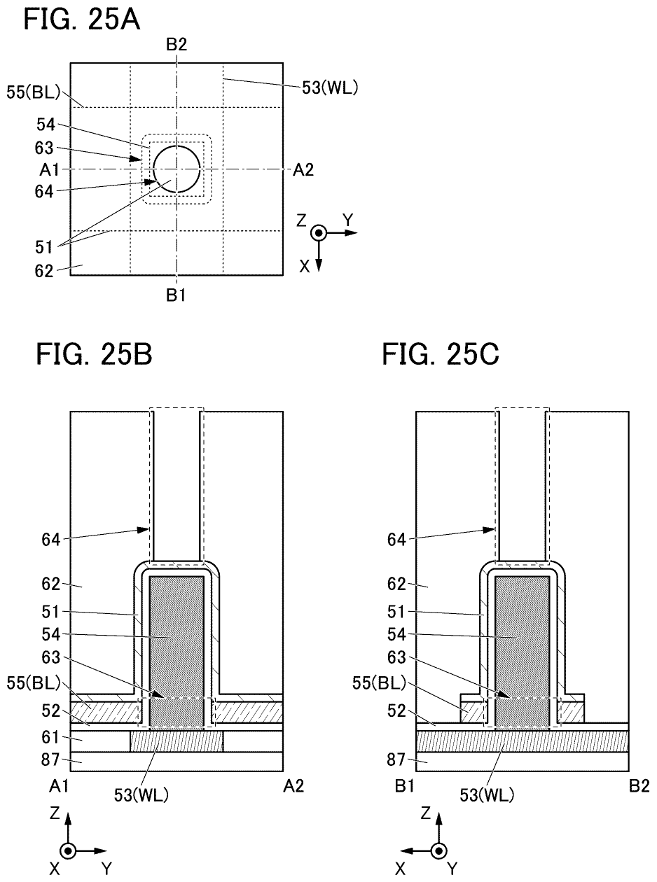

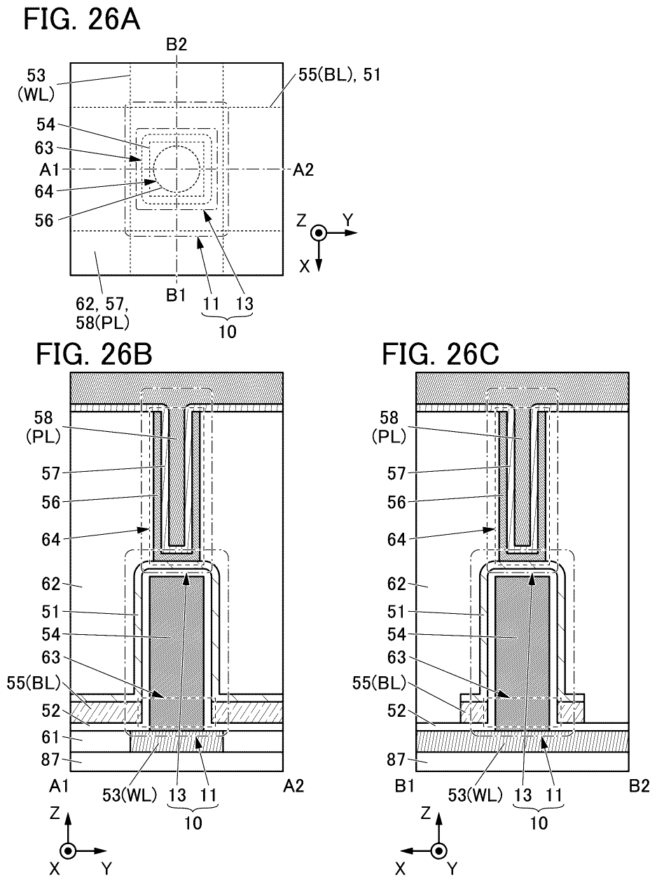

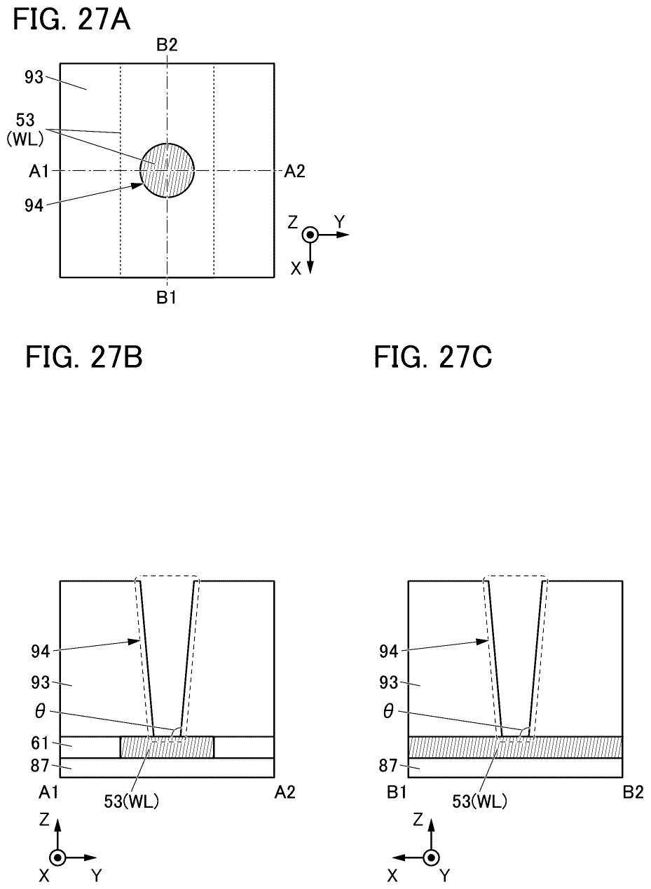

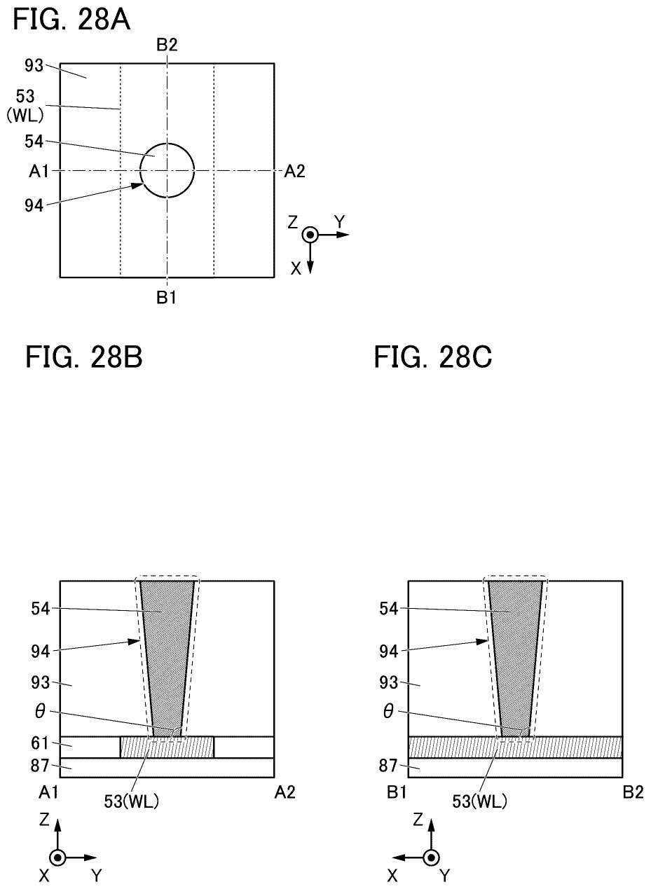

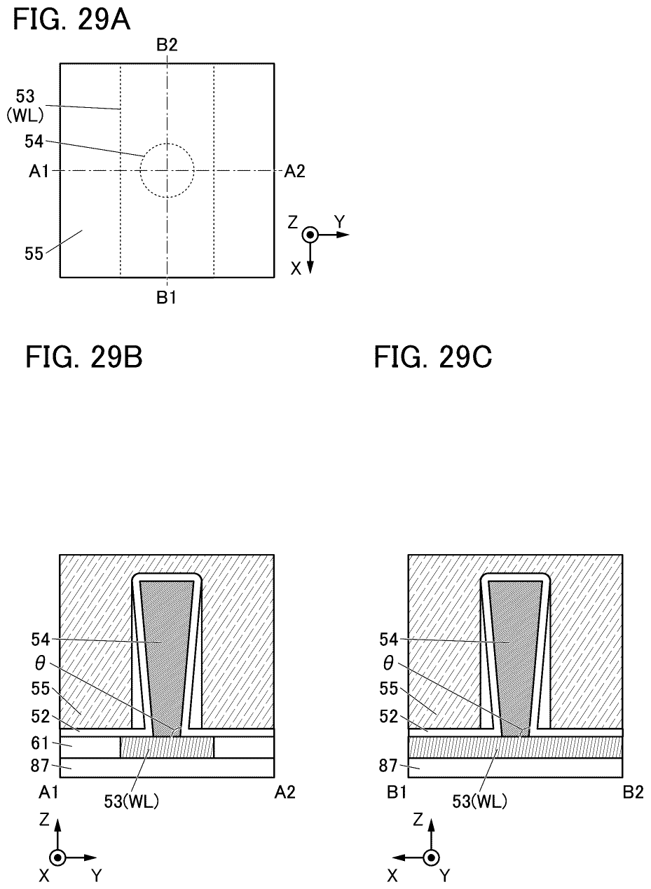

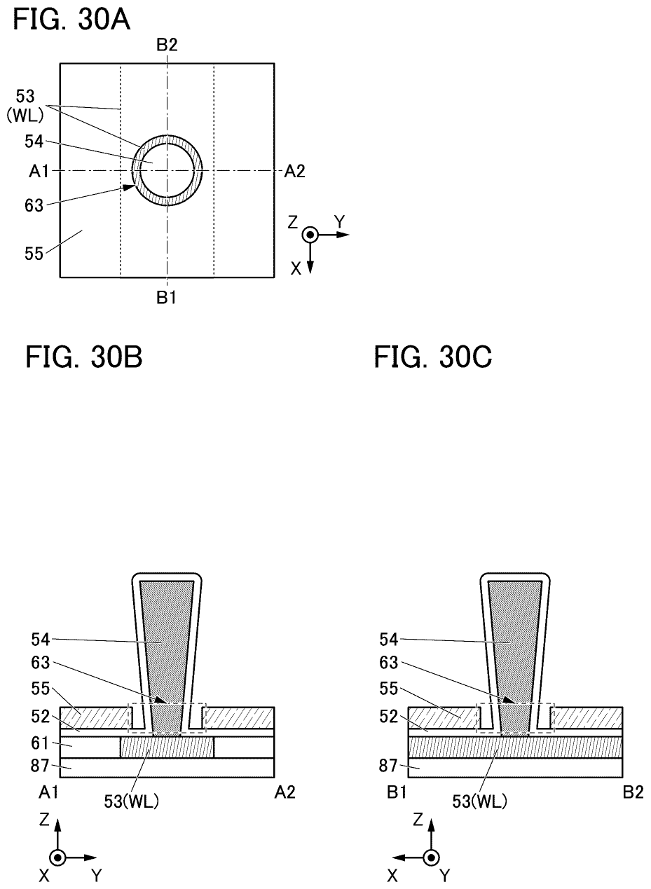

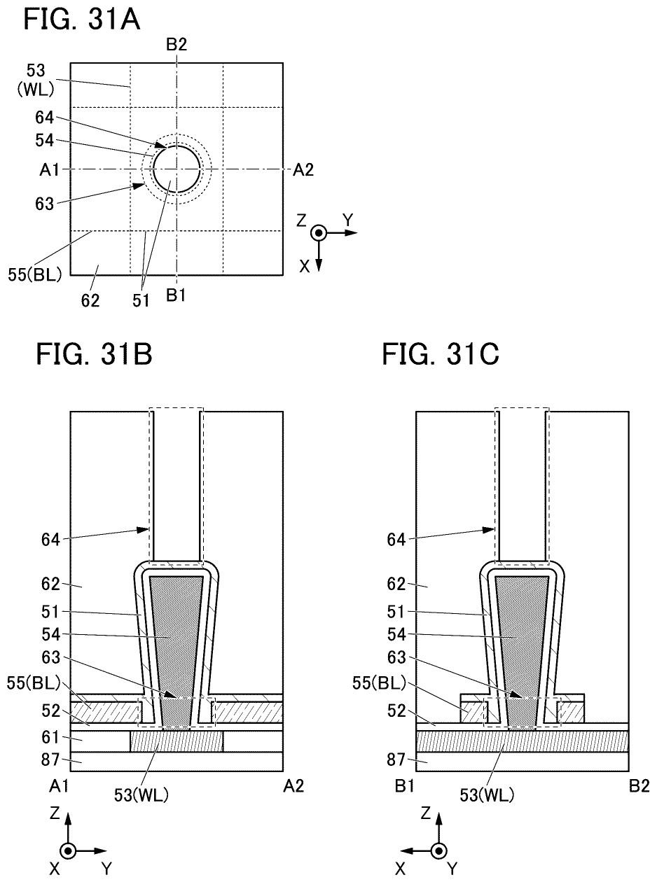

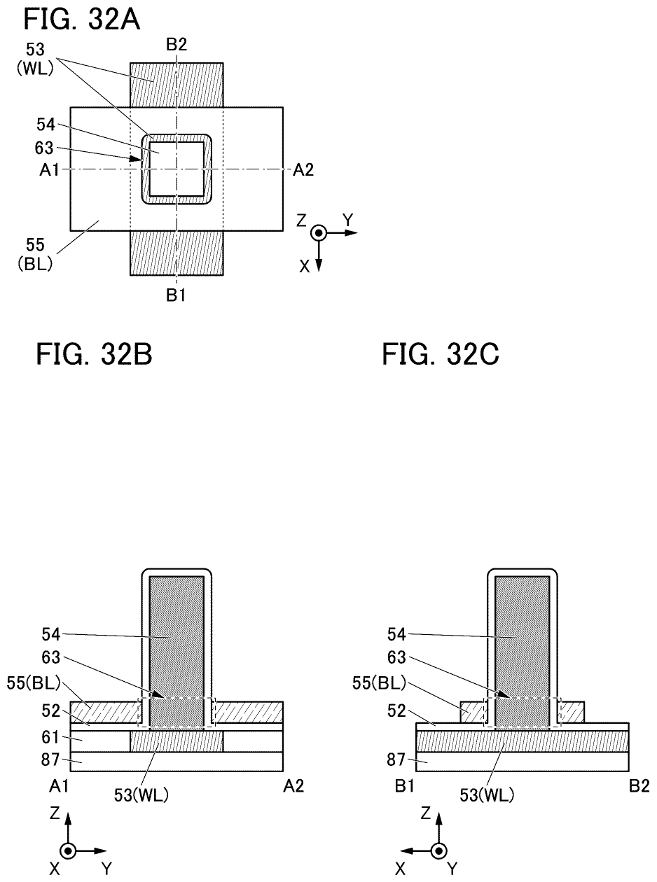

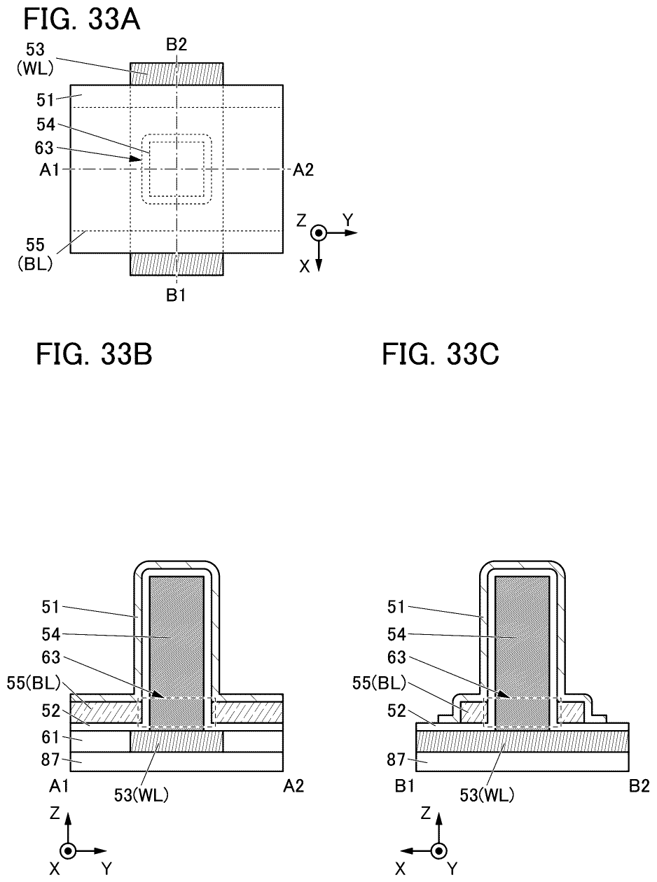

Unless otherwise specified, FIG. 19A, FIG. 20A, FIG. 21A, FIG. 22A, FIG. 23A, FIG. 24A, FIG. 25A, FIG. 26A, FIG. 27A, FIG. 28A, FIG. 29A, FIG. 30A, FIG. 31A, FIG. 32A, and FIG. 33A are plan views. FIG. 19B, FIG. 20B, FIG. 21B, FIG. 22B, FIG. 23B, FIG. 24B, FIG. 25B, FIG. 26B, FIG. 27B, FIG. 28B, FIG. 29B, FIG. 30B, FIG. 31B, FIG. 32B, and FIG. 33B are cross-sectional views taken along the dashed-dotted lines A1-A2 in FIG. 19A, FIG. 20A, FIG. 21A, FIG. 22A, FIG. 23A, FIG. 24A, FIG. 25A, FIG. 26A, FIG. 27A, FIG. 28A, FIG. 29A, FIG. 30A, FIG. 31A, FIG. 32A, and FIG. 33A, respectively. FIG. 19C, FIG. 20C, FIG. 21C, FIG. 22C, FIG. 23C, FIG. 24C, FIG. 25C, FIG. 26C, FIG. 27C, FIG. 28C, FIG. 29C, FIG. 30C, FIG. 31C, FIG. 32C, and FIG. 33C are cross-sectional views taken along the dashed-dotted lines B1-B2 in FIG. 19A, FIG. 20A, FIG. 21A, FIG. 22A, FIG. 23A, FIG. 24A, FIG. 25A, FIG. 26A, FIG. 27A, FIG. 28A, FIG. 29A, FIG. 30A, FIG. 31A, FIG. 32A, and FIG. 33A, respectively.

### Fabrication Method Example 1

An example of a method for fabricating the memory device illustrated in FIGS. 1A to 1C, FIGS. 2A and 2B, and FIGS. 3A to 3C will be described below with reference to FIGS. 19A to 19C to FIGS. 26A to 26C.

First, as illustrated in FIGS. 19A to 19C, the insulating layer 87 is formed over a substrate (not illustrated). Then, the insulating layer 61 is formed over the insulating layer 87, and the opening portion reaching the insulating layer 87 is formed in the insulating layer 61. After that, the conductive layer 53 is formed to fill the opening portion.

Next, as illustrated in FIGS. 19A to 19C, a conductive film 54f to be the conductive layer 54 is formed over the conductive layer 53 and the insulating layer 61. The conductive film 54f can be formed by a sputtering method, a CVD method, an ALD method, or the like, and is preferably formed by a sputtering method, a CVD method, or the like with a high deposition rate, in which case the memory device can be fabricated with improved productivity.

Subsequently, as illustrated in FIGS. 19A to 19C, a resist mask 91a is formed over the conductive film 54f. The resist mask 91a is formed in a band shape. FIGS. 19A to 19C illustrate an example in which the resist mask 91a is formed to extend in the X direction.

Then, as illustrated in FIGS. 20A to 20C, the conductive film 54f in a region where the resist mask 91a is not formed is removed by etching treatment, for example. Thus, the conductive film 54f is processed into a band shape. A dry etching method or a wet etching method can be used for the etching treatment, and a dry etching method is preferably used because it facilitates microfabrication. After the conductive film 54f is processed into a band shape, the resist mask 91a is removed.

Following that, as illustrated in FIGS. 20A to 20C, a resist mask 91b is formed over the conductive film 54f, the conductive layer 53, and the insulating layer 61. The resist mask 91b is formed in a band shape to intersect, e.g., perpendicularly or substantially perpendicularly, with the conductive film 54f in a plan view. FIGS. 20A to 20C illustrate an example in which the resist mask 91b is formed to extend in the Y direction.

Next, as illustrated in FIGS. 21A to 21C, the conductive film 54f in a region where the resist mask 91b is not formed is removed by etching treatment, for example. Thus, the conductive film 54f is processed into an island shape, so that the island-shaped conductive layer 54 is formed. A dry etching method is preferably used for the etching treatment as in the processing of the conductive film 54f using the resist mask 91a. After the conductive layer 54 is formed, the resist mask 91b is removed.

As described above, in the method for fabricating the memory device of one embodiment of the present invention, the conductive film 54f is processed into a band shape, the resist mask 91b is formed, and then the island-shaped conductive layer 54 is formed. This enables the area occupied by the resist mask to be larger than that in the case where the conductive layer 54 is formed in the following manner: the conductive film 54f is formed, a resist mask is formed in an island shape, and then the conductive film 54f in a region where the resist mask is not formed is processed. For example, even in the case where the minute conductive layer 54 is formed, the area occupied by the resist mask can be increased. Thus, the minute conductive layer 54 can be easily formed. Note that the conductive layer 54 may be formed in the following manner: the conductive film 54f is formed, a resist mask is formed in an island shape, and then the conductive film 54f in a region where the resist mask is not formed is processed. In that case, the conductive layer 54 can be formed through, after the formation of the conductive film 54f, formation of a resist mask, processing of the conductive film 54f, and removal of the resist mask each performed only once. Thus, the number of fabrication steps of the memory device can be reduced.

Next, as illustrated in FIGS. 22A to 22C, the insulating layer 52 is formed over the conductive layer 54, the conductive layer 53, and the insulating layer 61. The insulating layer 52 is formed to cover the top and side surfaces of the conductive layer 54. The insulating layer 52 is preferably formed by an ALD method, for example, to cover the conductive layer 54 with good coverage.

Subsequently, as illustrated in FIGS. 22A to 22C, the conductive layer 55 is formed over the insulating layer 52. The conductive layer 55 is formed such that its thickness is larger than the thickness of the conductive layer 55 illustrated in FIGS. 3A and 3B and the like, for example, larger than the thickness (the length in the Z direction) of the conductive layer 54. When the conductive layer 55 is formed such that its thickness is larger than the thickness (the length in the Z direction) of the conductive layer 54, the level of the top surface of the conductive layer 55 from the reference surface is higher than that of the top surface of the conductive layer 54 from the reference surface even in a region not overlapping with the top surface of the conductive layer 54.

The conductive layer 55 is preferably formed by a method with a high deposition rate, e.g., a method with a higher deposition rate than an ALD method. Thus, the memory device can be fabricated with improved productivity. For example, the conductive layer 55 can be formed by a sputtering method or a CVD method.

Next, as illustrated in FIGS. 22A to 22C, planarization treatment is performed on the top surface of the conductive layer 55. A CMP method can be used for the planarization treatment, for example. Performing the planarization treatment can prevent the conductive layer 55 from remaining on the top surface of the insulating layer 52 that overlaps with the conductive layer 54 after processing of the conductive layer 55 in a later step.

Then, as illustrated in FIGS. 23A to 23C, the conductive layer 55 is processed by anisotropic etching treatment, whereby the level of the top surface of the conductive layer 55 is made lower than that of the top surface of the conductive layer 54. Specifically, the level of the top surface of the conductive layer 55 from the reference surface is made lower than that of the top surface of the conductive layer 54 from the reference surface. Accordingly, part of the side surface of the insulating layer 52 and the top surface of the insulating layer 52 that overlaps with the conductive layer 54 are exposed. The conductive layer 55 is preferably processed by a dry etching method, for example. When the planarization treatment is performed on the top surface of the conductive layer 55 and then the anisotropic etching treatment is performed on the conductive layer 55 as described above, the conductive layer 55 can be prevented from remaining on the top surface of the insulating layer 52 that overlaps with the conductive layer 54.

The conductive layer 55 is processed to remove a region overlapping with the conductive layer 54, whereby the opening portion 63 is formed in the conductive layer 55. The opening portion 63 is formed to cover part of the side surface of the insulating layer 52.

In the case where the conductive layer 55 illustrated in FIG. 16A is formed, the insulating layer 52 illustrated in FIGS. 22A to 22C is formed, and then the conductive layer 55_1 is formed to have a larger thickness than the conductive layer 55_1 illustrated in FIG. 16A, e.g., to have a larger thickness than the conductive layer 54. When the conductive layer 55_1 is formed to have a larger thickness than the conductive layer 54, the level of the top surface of the conductive layer 55_1 from the reference surface is higher than that of the top surface of the conductive layer 54 from the reference surface even in a region not overlapping with the top surface of the conductive layer 54. Next, planarization treatment is performed by a CMP method or the like on the top surface of the conductive layer 55_1. Then, anisotropic etching is performed on the conductive layer 55_1. After that, the conductive layer 55_2 is formed by a method similar to that for the conductive layer 55_1. That is, the conductive layer 55_2 is formed, planarized, and subjected to anisotropic etching. In the above manner, the conductive layer 55 illustrated in FIG. 16A can be formed.

Subsequently, as illustrated in FIGS. 24A to 24C, the semiconductor layer 51 is formed over the insulating layer 52 to include a region in contact with the top surface of the conductive layer 55. The semiconductor layer 51 is formed to cover the top surface and part of the side surface of the conductive layer 54 with the insulating layer 52 therebetween.

The semiconductor layer 51 can be formed by any of a variety of methods such as an ALD method and a sputtering method. In the case where the semiconductor layer 51 has a stacked-layer structure as illustrated in FIG. 18, for example, the layers can be formed by different methods.

The semiconductor layer 51 can be formed by an ALD method, for example. With the use of an ALD method in which deposition is performed at an atomic level, generation of a crystal nucleus in a film can be inhibited as compared with the case of using a sputtering method in which particles are made to collide with the formation surface. Thus, unintentional polycrystallization of the semiconductor layer 51 can be inhibited.

The semiconductor layer 51 can be formed by an ALD method using a precursor and an oxidizer, for example. In the case where a film containing indium is formed as the semiconductor layer 51, a precursor containing indium can be used. In the case where a film containing indium and the first element is formed as the semiconductor layer 51, a precursor containing indium and a precursor containing the first element can be used. In the case of using a precursor containing indium, a thermal ALD method is preferably used as an ALD method. A plasma-enhanced ALD (PEALD) method using plasma can also be used.

As the precursor containing indium, it is possible to use trimethylindium, triethylindium, ethyldimethylindium, tris(1-methylethyl)indium, tris(2,2,6,6-tetramethyl-3,5-heptanedionato)indium, cyclopentadienylindium, indium(III) acetylacetonate, (3-(dimethylamino)propyl)dimethylindium, (diethylphosphino)dimethylindium, chlorodimethylindium, bromodimethylindium, dimethyl(2-propanolato)indium, or the like.

As the precursor containing indium, an inorganic precursor not containing hydrocarbon may be used. As the inorganic precursor containing indium, it is possible to use a halogen-based indium compound such as trifluoroindium (indium(III) fluoride), indium trichloride (indium(III) chloride), indium tribromide (indium(III) bromide), or indium triiodide (indium(III) iodide). The decomposition temperature of indium trichloride is approximately higher than or equal to 500° C. and lower than or equal to 700°C. Thus, with the use of indium trichloride, film formation can be performed by an ALD method while a substrate is being heated at approximately higher than or equal to 400° C. and lower than or equal to 600°C., e.g., at 500° C.

In the case where titanium is used as the first element, for example, titanium tetrachloride, tetrakis(dimethylamido)titanium, or tetraisopropyl titanate can be used as a precursor containing the first element.

In the case where tungsten is used as the first element, (ethylcyclopentadienyl)dicarbonylnitrosyl tungsten, (methylcyclopentadienyl)dicarbonylnitrosyl tungsten, bis(tert-butylimido)bis(dimethylamido)tungsten, bis(tert-butylimido)bis(tert-butyramido)tungsten, or hexacarbonyl tungsten can be used as the precursor containing the first element.

In the case where molybdenum is used as the first element, (ethylcyclopentadienyl)dicarbonylnitrosyl molybdenum, (methylcyclopentadienyl)dicarbonylnitrosyl molybdenum, bis(tert-butylimido)bis(dimethylamido)molybdenum, hexacarbonyl molybdenum, or molybdenum dichloride oxide can be used as the precursor containing the first element.

In the case where tin is used as the first element, tin tetrachloride, tin tetraethyl, tin tetramethyl, or tin tetrakis(dimethylamide) can be used as the precursor containing the first element, for example.

In the case where gallium is used as the first element, triethylgallium, trimethylgallium, gallium trichloride, tris(dimethylamido)gallium(III), gallium(III) acetylacetonate, tris(2,2,6,6-tetramethyl-3,5-heptanedionato)gallium, dimethylchlorogallium, or diethylchlorogallium can be used as the precursor containing the first element, for example.

In the case where aluminum is used as the first element, aluminum trichloride, trimethylaluminum, triethylaluminum, triisobutylaluminum, dimethylaluminum hydride, tris(dimethylamino)aluminum, or tris(diethylamino)aluminum can be used as the precursor containing the first element, for example.

In the case where yttrium is used as the first element, tris(methylcyclopentadienyl)yttrium(III) (Y(MeCp)₃), tris(isopropylcyclopentadienyl)yttrium(III) (Y(iPrCp)₃), tris[N,N-bis(trimethylsilyl)amide]yttrium(III) (Y(tmsa)₃), or the like can be used as the precursor containing the first element, for example.

In the case where scandium is used as the first element, tris(cyclopentadienyl)scandium, bis(ethylcyclopentadienyl)(N,N′-bis(dimethylamino)acetoamidinate)scandium, bis(ethylcyclopentadienyl)(di-tert-butyl-triazenide)scandium, bis-methylcyclopentadienyl-scandium chloride, triscyclopentadienyl scandium, or the like can be used as the precursor containing the first element, for example.

In the formation of the semiconductor layer 51, it is preferable to use a precursor with a low impurity concentration, i.e., a high-purity precursor. For example, the use of a precursor having a purity higher than or equal to 3N (99.9%), preferably higher than or equal to 4N (99.99%), further preferably higher than or equal to 5N (99.999%), still further preferably higher than or equal to 6N (99.9999%) can sufficiently reduce impurities in the semiconductor layer 51.

As the oxidizer, ozone (O₃), oxygen (O₂), water (H₂O), nitrogen dioxide (NO₂), dinitrogen monoxide (N₂O), hydrogen peroxide (H₂O₂), or the like can be used, and two or more of them may be used, for example.

In the case where a single crystal or a polycrystal having a large particle size is formed, an oxidizer containing hydrogen is preferably used in order to inhibit formation of a crystal nucleus at the initial stage of the film formation. For example, H₂O or H₂O₂ is preferably used. A film with few crystal nuclei is formed and then crystal growth is caused by heat applied during the film formation or heat treatment after the film formation, so that a single crystal film or a polycrystal film having a large particle size can be formed. Meanwhile, in the case where the hydrogen concentration and the nitrogen concentration in the film are reduced, O₂ or O₃ is preferably used as the oxidizer, and O₃ is further preferably used.

As an example of a method for controlling the composition of a film to be formed, adjustment of the flow rate ratio, flowing time, flowing order, or the like of the source gases is given. By adjusting such conditions, a film whose composition is continuously changed can be formed. A film having a concentration gradient can also be formed. Furthermore, two or more films having different compositions can be formed successively.

The substrate heating temperature at the time of introducing the precursor into a reaction chamber is preferably a temperature corresponding to the decomposition temperature of the precursor. In the case of a thermal ALD method in which triethylindium is used as the precursor containing indium, the substrate heating temperature can be higher than or equal to 100° C. and lower than or equal to 350° C., preferably higher than or equal to 150° C. and lower than or equal to 300° C., for example.

The semiconductor layer 51 can be formed by a sputtering method, for example. In the case where a film containing indium is formed, a sputtering target containing indium can be used. For example, in the case where an indium oxide film is formed, an indium oxide sputtering target can be used. In the case where an oxide film containing indium and the first element is formed, a sputtering target of an oxide containing indium and the first element can be used.

In the case where an oxide film containing indium and the first element is formed, a sputtering target of indium oxide containing the first element can be prepared, for example. The addition amount of first element in the sputtering target can be set such that the proportion of the number of atoms of the first element to the total number of atoms of indium and the first element in the oxide film to be formed is a desired value, for example.

The semiconductor layer 51 can also be formed by a co-sputtering method. For example, indium oxide is prepared as a first sputtering target, and an oxide containing the first element is prepared as a second sputtering target. The first sputtering target and the second sputtering target are sputtered at the same time, whereby an oxide film containing indium and the first element can be formed. When the first sputtering target is sputtered, an indium oxide film can be formed. With the use of a co-sputtering method, two or more films with different compositions can be formed successively.

In the case where the semiconductor layer 51 is formed by a sputtering method, a sputtering gas preferably contains hydrogen (H₂). When the semiconductor layer 51 is formed by a sputtering method or hydrogen is introduced at the initial stage of the formation of the semiconductor layer 51 by a sputtering method, the semiconductor layer 51 with low crystallinity can be formed. In addition, generation of a crystal nucleus can be inhibited or disappearance of a crystal nucleus can be promoted at the time of forming the semiconductor layer 51. As the sputtering gas, a single gas of a noble gas (typically argon), a single gas of oxygen, a mixed gas of a noble gas and oxygen, or the like can be used.

In the case where the semiconductor layer 51 is formed by a sputtering method, the substrate temperature at the time of forming the semiconductor layer 51 is preferably higher than or equal to room temperature (25° C.) and lower than or equal to 250° C., further preferably higher than or equal to room temperature and lower than or equal to 200° C., still further preferably higher than or equal to room temperature and lower than or equal to 140° C. For example, the substrate temperature is preferably set higher than or equal to room temperature and lower than or equal to 140° C., in which case the productivity increases and generation of a crystal nucleus can be inhibited. The semiconductor layer 51 can also be formed in the state where the substrate temperature is set at room temperature or the substrate is not heated.

In the case where the semiconductor layer 51 has a stacked-layer structure of two or more layers as illustrated in FIG. 18, for example, the layers may be formed by different film formation methods. For example, the semiconductor layer 51_1 can be formed by a sputtering method, the semiconductor layer 51_2 can be formed by an ALD method, and the semiconductor layer 51_3 can be formed by a sputtering method. With the use of a sputtering method, a dense film can be formed. When the semiconductor layer 51_1 and the semiconductor layer 51_3 are dense films, formation of oxygen vacancies and V_{O}H in the vicinity of the interface between the semiconductor layer 51_1 and the insulating layer 52 and in the vicinity of the interface between the semiconductor layer 51_3 and the insulating layer 62 can be inhibited. Thus, the transistor 11 can have a high on-state current.

For another example, the semiconductor layer 51_1 can be formed by an ALD method, the semiconductor layer 51_2 can be formed by a sputtering method, and the semiconductor layer 51_3 can be formed by an ALD method. When the semiconductor layer 51_1 is formed by an ALD method, formation of a mixed layer at the interface between the base and the semiconductor layer 51 can be inhibited, so that the crystallinity of the semiconductor layer 51_2 formed over the semiconductor layer 51_1 can be further increased.

After the semiconductor layer 51 is formed, heat treatment is preferably performed. Even when the semiconductor layer 51 is insufficiently crystallized at the time of the formation, the heat treatment can increase the crystallinity of the semiconductor layer 51.

The heat treatment is performed in a nitrogen gas atmosphere, an inert gas atmosphere, or an atmosphere containing an oxidizing gas at 10 ppm (0.001%) or more, 1% or more, or 10% or more. In the case where the heat treatment is performed in a mixed atmosphere of a nitrogen gas and an oxygen gas, for example, the proportion of the oxygen gas is preferably approximately 20%. The heat treatment may be performed under reduced pressure. Alternatively, the heat treatment can be performed in the following manner: heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above heat treatment is preferably less than or equal to 1 ppb (1×10⁻³ ppm), further preferably less than or equal to 0.1 ppb (1×10⁻⁴ ppm), still further preferably less than or equal to 0.05 ppb (5×10⁻⁵ ppm). The heat treatment using a highly purified gas can prevent entry of moisture or the like into the semiconductor layer 51 as much as possible.

A heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. The heat treatment can also be performed by laser light irradiation. As the laser light, for example, infrared laser light, visible laser light, or ultraviolet laser light can be used.

Here, heat treatment performed under reduced pressure is referred to as first treatment, and heat treatment performed in an atmosphere containing an oxidizing gas is referred to as second treatment. The temperature for the first treatment is preferably higher than or equal to 200° C. and lower than or equal to 500° C., further preferably higher than or equal to 350° C. and lower than or equal to 450° C. The temperature for the first treatment can be typically 400° C. The temperature for the second treatment is preferably higher than or equal to 300° C. and lower than or equal to 700° C., further preferably higher than or equal to 450° C. and lower than or equal to 650° C. The temperature for the second treatment can be typically 450° C. As the second treatment, for example, treatment can be performed at 450° C. for one hour at a flow rate ratio of a nitrogen gas to an oxygen gas of 4:1.

In the case where the semiconductor layer 51 is formed by an ALD method, the first treatment and the second treatment are preferably performed in this order as the heat treatment. The first treatment can reduce the amount of impurities such as carbon, water, and hydrogen in the semiconductor layer 51, and the second treatment can compensate for oxygen released from the semiconductor layer 51 by the first treatment. In addition, the amount of impurities such as water and hydrogen in the semiconductor layer 51 can be reduced by the first treatment and the second treatment. Thus, the reliability of the transistor can be improved.

In the case where the semiconductor layer 51 is formed by a sputtering method, the second treatment is preferably performed as the heat treatment. The second treatment can promote crystal growth and increase the size of a crystal grain in the semiconductor layer 51. In addition, the second treatment can reduce the amount of hydrogen contained in the semiconductor layer 51. In particular, when the insulating layer 52 is formed using an insulating material having a function of capturing and fixing hydrogen, the amount of hydrogen contained in the semiconductor layer 51 can be further reduced and crystal growth can be promoted. The use of a sputtering target with a low carbon concentration can eliminate the need for the first treatment.

In addition to or instead of the heat treatment, microwave plasma treatment can be performed.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

By performing microwave plasma treatment in an oxygen-containing atmosphere, the impurity concentration in the semiconductor layer 51 is reduced in some cases. Specific examples of impurities include hydrogen and carbon.

The microwave plasma treatment is preferably performed under reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

In the microwave plasma treatment, substrate heating is preferably performed. The substrate heating temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C.

The microwave plasma treatment can be performed using an oxygen gas and an argon gas, for example. The oxygen flow rate ratio (O₂/(O₂+Ar)) in the microwave plasma treatment is, for example, preferably higher than 0% and lower than or equal to 10%, further preferably higher than or equal to 0.5% and lower than or equal to 5%, still further preferably higher than or equal to 0.5% and lower than or equal to 3%, and is typically preferably 1%.

The microwave plasma treatment in an oxygen-containing atmosphere can convert an oxygen gas into plasma by using a high-frequency wave such as a microwave or a radio frequency (RF), and apply, to the semiconductor layer 51, oxygen radicals generated by conversion of the oxygen gas into plasma. By the effects of plasma, a microwave, oxygen radicals, and the like, V_{O}H in the semiconductor layer 51 can be divided into an oxygen vacancy and hydrogen, and hydrogen which is an impurity can be removed from the semiconductor layer 51. In this manner, V_{O}H contained in the semiconductor layer 51 can be reduced. At this time, carbon bonded to oxygen, hydrogen, or the like can also be removed in some cases. Performing the microwave plasma treatment in such a manner can reduce impurities such as carbon and hydrogen. Supplying the oxygen radicals to oxygen vacancies formed in the semiconductor layer 51 can further reduce oxygen vacancies in the semiconductor layer 51.

Next, as illustrated in FIGS. 24A to 24C, part of the semiconductor layer 51 and part of the conductive layer 55 are removed, so that the semiconductor layer 51 and the conductive layer 55 are each processed into a band shape. For example, a resist mask is formed over the semiconductor layer 51, and the semiconductor layer 51 and the conductive layer 55 in a region where the resist mask is not formed are removed by etching treatment. That is, the conductive layer 55 and the semiconductor layer 51 are processed using the same resist mask. When the conductive layer 55 and the semiconductor layer 51 are processed using the same resist mask in this manner, the number of masks required for fabricating the memory device can be smaller than that in the case where the conductive layer 55 and the semiconductor layer 51 are processed using different resist masks. After the conductive layer 55 is processed, the resist mask is removed. In the above manner, the semiconductor layer 51 is formed over the insulating layer 52 to include the region in contact with the top surface of the conductive layer 55.

Following that, as illustrated in FIGS. 25A to 25C, the insulating layer 62 is formed to include a region in contact with the top surface of the semiconductor layer 51, a region in contact with the side surface of the semiconductor layer 51, and a region in contact with the side surface of the conductive layer 55. The insulating layer 62 can be formed by a sputtering method, a CVD method, an ALD method, or the like, and is preferably formed by a sputtering method, a CVD method, or the like with a higher deposition rate than an ALD method, for example, in which case the memory device can be fabricated with improved productivity. When the insulating layer 62 is formed in an oxygen-containing atmosphere, the insulating layer 62 can include a region containing excess oxygen.

Heat treatment is preferably performed after the formation of the insulating layer 62. Thus, impurities such as water and hydrogen in the insulating layer 62 can diffuse outwardly. This can reduce the concentration of impurities such as water and hydrogen in the insulating layer 62. In addition, oxygen can be supplied from the insulating layer 62 to the semiconductor layer 51. It is particularly preferable that the insulating layer 62 include the insulating layer 62c as illustrated in FIGS. 13A and 13B, in which case outward diffusion of excess oxygen contained in the insulating layer 62b can be inhibited and oxygen can be efficiently supplied to the semiconductor layer 51. The heat treatment can be performed at higher than or equal to 100° C. and lower than or equal to 700° C., for example.

Subsequently, as illustrated in FIGS. 25A to 25C, planarization treatment is preferably performed on the top surface of the insulating layer 62. In the case where the insulating layer 62 has a stacked-layer structure as illustrated in FIGS. 13A and 13B, for example, the planarization treatment is preferably performed on at least one layer. A CMP method can be used for the planarization treatment, for example. Performing the planarization treatment on the top surface of the insulating layer 62 can planarize the formation surface of a layer formed over the insulating layer 62 in a later step and can inhibit disconnection of the layer. Note that the planarization treatment is not necessarily performed.

In this specification and the like, disconnection refers to a phenomenon in which a layer, a film, or an electrode is split because of the shape of the formation surface (e.g., a level difference).

Then, as illustrated in FIGS. 25A to 25C, the opening portion 64 that overlaps with the conductive layer 54 and reaches the top surface of the semiconductor layer 51 is formed in the insulating layer 62. For example, a resist mask is formed in a region other than a region to be the opening portion 64, and the insulating layer 62 in a region where the resist mask is not formed is removed by etching treatment. The etching treatment can be performed by a dry etching method or a wet etching method, and is preferably performed by a dry etching method because it facilitates microfabrication. The resist mask is removed after the etching treatment. FIG. 25A illustrates an example in which the shape of the opening portion 64 in a plan view is a circle. When the shape of the opening portion 64 in a plan view is a circle, the processing accuracy at the time of forming the opening portion 64 can be increased. This can reduce the size of the opening portion 64.

Next, as illustrated in FIGS. 26A to 26C, the conductive layer 56 is formed to include a region in contact with the top surface of the semiconductor layer 51 in the opening portion 64. For example, the conductive layer 56 can be formed in the following manner: a conductive film to be the conductive layer 56 is formed to cover the opening portion 64, and then the conductive film is processed. The conductive film to be the conductive layer 56 is preferably formed by an ALD method, for example, to cover the opening portion 64 with good coverage.

After the conductive film to be the conductive layer 56 is formed, a sacrificial layer is formed over the conductive film, for example. Then, planarization treatment such as CMP treatment is performed on the sacrificial layer and the conductive film until the top surface of the insulating layer 62 is exposed. After that, the sacrificial layer in the opening portion 64 is removed. In this manner, the conductive layer 56 illustrated in FIGS. 26A to 26C can be formed.

Alternatively, after the conductive film to be the conductive layer 56 is formed, a resist is applied onto the conductive film, for example. Then, anisotropic etching treatment is performed on the resist to remove the resist on the outside of the opening portion 64. In this manner, a mask is formed in the opening portion 64. Subsequently, etching treatment is performed on the conductive film to be the conductive layer 56, whereby the conductive layer 56 can be formed. After that, the mask is removed. In the case where the conductive layer 56 is formed by this method, the upper end portion of the conductive layer 56 is sometimes positioned below the top surface of the insulating layer 62.

Alternatively, after the conductive film to be the conductive layer 56 is formed, the conductive film is processed by a photolithography method, whereby the conductive layer 56 can be formed. In that case, the side end portion of the conductive layer 56 is sometimes positioned above the insulating layer 62. That is, the conductive layer 56 is sometimes formed to include a region positioned outside the opening portion 64.

Through the above steps, the transistor 11 can be formed.

Next, as illustrated in FIGS. 26A to 26C, the insulating layer 57 is formed to cover the conductive layer 56. The insulating layer 57 is formed along the side surface of the conductive layer 56, the top surface of the depression of the conductive layer 56, and the top surface of the insulating layer 62. The insulating layer 57 is preferably formed by an ALD method, for example, to cover the conductive layer 56 with good coverage.

Then, as illustrated in FIGS. 26A to 26C, the conductive layer 58 is formed over the insulating layer 57. The conductive layer 58 is formed to include a region facing the side surface of the conductive layer 56 with the insulating layer 57 therebetween in the opening portion 64. The conductive layer 58 can be formed to fill the opening portion 64. By the formation of the conductive layer 58, the capacitor 13 is formed.

In the above manner, the memory cell 10 including the transistor 11 and the capacitor 13 is formed.

In the method for fabricating the memory device of one embodiment of the present invention, the conductive layer 56 can be formed not only as the other of the source electrode and the drain electrode of the transistor 11 but also as one of the pair of electrodes of the capacitor 13. This enables the number of fabrication steps of the memory device to be smaller than that in the case where different conductive layers are formed as these electrodes. Thus, the memory device can be fabricated with improved productivity.

In the method for fabricating the memory device of one embodiment of the present invention, another insulating layer, e.g., an interlayer insulating layer, is absent between the insulating layer 52 and the insulating layer 62 in a region not overlapping with the conductive layer 55. This enables the number of fabrication steps of the memory device to be smaller than that in the case where an interlayer insulating layer other than the insulating layer 62 is formed over the insulating layer 52, an opening portion is formed in the interlayer insulating layer, and then the conductive layer 55 is formed to fill the opening portion, for example. Thus, the memory device can be fabricated with improved productivity.

### Fabrication Method Example 2

An example of a method for fabricating the memory device illustrated in FIGS. 9A to 9D and FIGS. 10A and 10B will be described below with reference to FIGS. 27A to 27C to FIGS. 31A to 31C. Note that the description of the portions already described above in [Fabrication method example 1] is omitted and only different portions are described in detail.

First, as illustrated in FIGS. 27A to 27C, the insulating layer 87, the insulating layer 61, and the conductive layer 53 are formed over a substrate (not illustrated). Then, the layer 93 is formed over the conductive layer 53 and the insulating layer 61. The layer 93 is removed in a later step. Thus, the layer 93 is also referred to as a sacrificial layer.

Since the layer 93 is removed in a later step, the layer 93 is formed using a material with an etching rate different from the etching rates of the materials for the conductive layer 53 and the insulating layer 61. Specifically, the layer 93 is formed using a material having high etching selectivity with respect to the conductive layer 53 and the insulating layer 61. As described above, the layer 93 can be formed using any of the insulating materials described later in [Insulating layer], for example, silicon oxide, silicon nitride, silicon oxynitride, aluminum oxide, aluminum nitride, or aluminum oxynitride. A spin on carbon (SOC) film or a spin on glass (SOG) film may be used as the layer 93. The layer 93 may be formed using any of the conductive materials described later in [Conductive layer] or any of the semiconductor materials described later in [Semiconductor layer].

Next, as illustrated in FIGS. 27A to 27C, the opening portion 94 reaching the top surface of the conductive layer 53 is formed in the layer 93. The opening portion 94 is preferably formed such that the angle θ is greater than or equal to 90°, further preferably greater than or equal to 100°, still further preferably greater than or equal to 110°. Note that the opening portion 94 may be formed such that the angle θ is less than 90°. For example, the opening portion 94 may be formed such that the angle θ is greater than or equal to 80° and less than 90°, greater than or equal to 85° and less than 90°, or greater than or equal to 87° and less than 90°.

The angle θ can be an angle between the side surface of the layer 93 in the opening portion 94 and the bottom portion of the opening portion 94 (the top surface of the conductive layer 53 in the example illustrated in FIGS. 27A to 27C). Note that FIG. 27A illustrates an example in which the shape of the opening portion 94 in a plan view is a circle. When the shape of the opening portion 94 in a plan view is a circle, the processing accuracy at the time of forming the opening portion 94 can be increased. This can reduce the size of the opening portion 94.

The opening portion 94 can be formed in the following manner: a resist mask is formed in a region other than a region to be the opening portion 94, and the layer 93 in a region where the resist mask is not formed is removed by etching treatment. The etching treatment is preferably performed by a dry etching method, as in the formation of the opening portion 64 in the insulating layer 62. The resist mask is removed after the formation of the opening portion 94.

Subsequently, as illustrated in FIGS. 28A to 28C, the conductive layer 54 is formed to fill the opening portion 94. For example, the conductive layer 54 can be formed in the following manner: a conductive film to be the conductive layer 54 is formed to fill the opening portion 94, and then planarization treatment such as CMP treatment is performed on the conductive film until the top surface of the layer 93 is exposed. Here, an angle between the side surface of the conductive layer 54 and the top surface of the conductive layer 53 corresponds to the angle θ.

Next, as illustrated in FIGS. 29A to 29C, the layer 93 is removed. The layer 93 can be removed by an etching method, specifically a wet etching method. Note that the layer 93 may be removed by a dry etching method.

FIGS. 29A to 29C illustrate an example in which the layer 93 is entirely removed. Note that the layer 93 is not necessarily entirely removed, and part of the layer 93 may be left. In that case, the memory device illustrated in FIGS. 11A and 11B can be fabricated. In the case where part of the layer 93 is left, the layer 93 preferably has a stacked-layer structure of two or more layers. At this time, one or some of the layers included in the layer 93 are removed. For example, in the case where the layer 93 has a two-layer structure of a first layer and a second layer over the first layer, the second layer is removed and the first layer is left. In that case, the first layer and the second layer are formed using materials having high etching selectivity therebetween, in which case the first layer can be inhibited from being removed at the time of removing the second layer, for example.

Even when the angle θ is made larger, the conductive layer 54 is less likely to fall down in the case where part of the layer 93 is left than in the case where the layer 93 is entirely removed. On the other hand, the layer 93 can be formed and removed more easily in the case where the layer 93 is entirely removed than in the case where part of the layer 93 is left.

Subsequently, as illustrated in FIGS. 29A to 29C, the insulating layer 52 is formed over the conductive layer 54, the conductive layer 53, and the insulating layer 61. The insulating layer 52 is preferably formed by a film formation method that offers good coverage, such as an ALD method, to cover the conductive layer 54 with good coverage even when the angle θ is greater than 90°, for example.

Next, as illustrated in FIGS. 29A to 29C, the conductive layer 55 is formed over the insulating layer 52. The conductive layer 55 is formed such that its thickness is larger than the thickness of the conductive layer 55 illustrated in FIGS. 9C and 9D and the like, for example, larger than the thickness (the length in the Z direction) of the conductive layer 54. When the conductive layer 55 is formed such that its thickness is larger than the thickness (the length in the Z direction) of the conductive layer 54 as described above, the level of the top surface of the conductive layer 55 from the reference surface is higher than that of the top surface of the conductive layer 54 from the reference surface even in a region not overlapping with the top surface of the conductive layer 54.

The conductive layer 55 is preferably formed by a method that offers lower coverage than the method used for forming the insulating layer 52. Thus, the conductive layer 55 can be inhibited from being in contact with the side surface of the insulating layer 52. For example, in the case where the angle θ is greater than 90°, preferably greater than or equal to 100°, further preferably greater than or equal to 110°, the conductive layer 55 can be inhibited from being in contact with the side surface of the insulating layer 52. The conductive layer 55 is preferably formed by a sputtering method or a CVD method, for example. Note that the conductive layer 55 may be disconnected because of the conductive layer 54.

Next, as illustrated in FIGS. 29A to 29C, planarization treatment is performed by a CMP method or the like on the top surface of the conductive layer 55. Performing the planarization treatment can prevent the conductive layer 55 from remaining on the top surface of the insulating layer 52 that overlaps with the conductive layer 54 after processing of the conductive layer 55 in a later step, as described above.

Next, as illustrated in FIGS. 30A to 30C, the conductive layer 55 is processed by anisotropic etching treatment. In the case where the conductive layer 55 is formed to be in contact with the side surface of the insulating layer 52 in the step illustrated in FIGS. 29A to 29C, the anisotropic etching treatment cannot completely remove the conductive layer 55 in a region in contact with the insulating layer 52 and a region in its vicinity in some cases. In view of this, the angle θ is made greater than 90° and the conductive layer 55 is formed by a method that offers low coverage, so that the residue of the conductive layer 55 can be prevented from being attached to the side surface of the insulating layer 52 after the anisotropic etching treatment. In particular, when the angle θ is greater than 110°, the residue of the conductive layer 55 can be easily prevented from being attached to the side surface of the insulating layer 52. Accordingly, the fabrication yield of the memory device can be increased. In addition, a change in the electrical characteristics of the transistor 11 due to the residue of the conductive layer 55 can be inhibited. Thus, the memory device having high reliability can be fabricated.

In the case where the conductive layer 55 illustrated in FIG. 16B is formed, the conductive layer 55_1 is formed to have the same thickness as that of the conductive layer 55_1 illustrated in FIG. 16B after the formation of the insulating layer 52 illustrated in FIGS. 29A to 29C. When the angle θ is greater than 90° at this time, the conductive layer 55_1 can be inhibited from being in contact with the side surface of the insulating layer 52.

Next, the conductive layer 55_2 is formed over the conductive layer 55_1 to have a larger thickness than the conductive layer 55_2 illustrated in FIG. 16B, e.g., to have a larger thickness than the conductive layer 54. When the conductive layer 55_2 is formed to have a larger thickness than the conductive layer 54, the level of the top surface of the conductive layer 55_2 from the reference surface is higher than that of the top surface of the conductive layer 54 from the reference surface also in a region not overlapping with the top surface of the conductive layer 54. Following that, planarization treatment is performed by a CMP method or the like on the top surface of the conductive layer 55_2. Then, the conductive layer 55_2 is processed by anisotropic etching treatment. By the anisotropic etching treatment on the conductive layer 55_2, the top surface of the conductive layer 55_1 is exposed over the conductive layer 54. After that, the conductive layer 55_1 over the conductive layer 54 is removed by etching treatment. The etching treatment is performed under the condition where the etching selectivity with respect to the conductive layer 55_2 is high, so that the conductive layer 55_2 can be inhibited from being removed at the time of removing the conductive layer 55_1, for example. The etching treatment is also referred to as treatment for removing the conductive layer 55_1 with the use of the conductive layer 55_2 as a hard mask.

When the angle θ is greater than 90° as described above, the conductive layer 55_1 can be inhibited from being in contact with the side surface of the insulating layer 52. Thus, even when the conductive layer 55_2 is formed without processing of the conductive layer 55_1 by etching treatment or the like after the formation of the conductive layer 55_1, the conductive layer 55 illustrated in FIG. 16B can be formed.

Next, as illustrated in FIGS. 31A to 31C, the semiconductor layer 51 and the insulating layer 62 are formed. The opening portion 64 is formed in the insulating layer 62. The semiconductor layer 51 is preferably formed by a film formation method that offers good coverage, such as an ALD method, to cover the side surface of the insulating layer 52 and the top surface of the insulating layer 52 that overlaps with the conductive layer 54 with good coverage even when the angle θ is greater than 90°, for example. FIGS. 31A to 31C illustrate an example in which the semiconductor layer 51 is formed also between the side surface of the conductive layer 54 and the side surface of the conductive layer 55 in the opening portion 63. In that case, the semiconductor layer 51 can include a region in contact with the side surface of the conductive layer 55 in the opening portion 63. In the case where the semiconductor layer 51 is formed by a film formation method that offers good coverage, such as an ALD method, the semiconductor layer 51 can also cover the side surface of the conductive layer 55 in the opening portion 63 with good coverage.

At least part of the insulating layer 62 is preferably formed by an ALD method. Hence, the insulating layer 62 can cover the conductive layer 54 with good coverage even when the angle θ is greater than 90°, for example. Thus, the fabrication yield of the memory device can be increased. In addition, the memory device having high reliability can be fabricated. It is preferable that part of the insulating layer 62 be formed by an ALD method, for example, and then the remaining part thereof be formed by a sputtering method or a CVD method, in which case the insulating layer 62 can be formed to cover the conductive layer 54 with good coverage and the productivity of the memory device can be higher than that in the case where the insulating layer 62 is formed entirely by an ALD method. In the case where the insulating layer 62 illustrated in FIGS. 13A and 13B is formed, for example, it is preferable that the insulating layer 62a be formed by an ALD method and the insulating layer 62b be formed by a sputtering method or a CVD method. Note that the insulating layer 62c may be formed by any of a sputtering method, a CVD method, and an ALD method.

After that, the conductive layer 56, the insulating layer 57, and the conductive layer 58 are formed through the step illustrated in FIGS. 26A to 26C. The conductive layer 56, the insulating layer 57, and the conductive layer 58 are each formed to include a region positioned in the opening portion 64.

Through the above steps, the memory device illustrated in FIGS. 9A to 9D and FIGS. 10A and 10B can be fabricated.

### Fabrication Method Example 3

An example of a method for fabricating the memory device illustrated in FIGS. 14A and 14B will be described below with reference to FIGS. 32A to 32C and FIGS. 33A to 33C. Note that the description of the portions already described above in [Fabrication method example 1] is omitted and only different portions are described in detail.

First, the steps illustrated in FIGS. 19A to 19C, FIGS. 20A to 20C, FIGS. 21A to 21C, FIGS. 22A to 22C, and FIGS. 23A to 23C are performed. Then, as illustrated in FIGS. 32A to 32C, the conductive layer 55 is processed into a band shape before the semiconductor layer 51 is formed. For example, a resist mask is formed over the conductive layer 55 and the insulating layer 52, and the conductive layer 55 in a region where the resist mask is not formed is removed by etching treatment. The resist mask is removed after the conductive layer 55 is processed.

Next, as illustrated in FIGS. 33A to 33C, the semiconductor layer 51 is formed and then part of the semiconductor layer 51 is removed. Specifically, part of a region of the semiconductor layer 51 that overlaps with neither the conductive layer 54 nor the conductive layer 55 is removed. For example, a resist mask is formed over the semiconductor layer 51, and the semiconductor layer 51 in a region where the resist mask is not formed is removed by etching treatment. The resist mask is removed after the semiconductor layer 51 is processed. In this manner, the semiconductor layer 51 can be formed to cover the side surface of the conductive layer 55. Specifically, the semiconductor layer 51 can be formed to include a region in contact with the side surface of the conductive layer 55.

Subsequently, the steps illustrated in FIGS. 25A to 25C and FIGS. 26A to 26C are performed. Through the above steps, the memory device illustrated in FIGS. 14A and 14B can be fabricated.

### Materials for Memory Device

Materials that can be used for the memory device of this embodiment will be described below. Note that the layers included in the memory device of this embodiment may each have a single-layer structure or a stacked-layer structure.

### Semiconductor Layer

As described above, an indium oxide film can be used for the semiconductor layer (e.g., the semiconductor layer 51) included in the memory device, for example. In that case, the semiconductor layer preferably has crystallinity. For example, the semiconductor layer preferably includes a crystal grain. Examples of a film including a crystal grain include a single crystal film, a polycrystal film, and an amorphous film including a crystal grain. A polycrystal film is regarded as being formed of two or more crystal grains, whereas a single crystal film is regarded as being formed of one crystal grain. A crystal grain boundary (also referred to as a grain boundary) is observed in a polycrystal film, whereas a crystal grain boundary is not observed in a single crystal film.

Unlike in a polycrystal film, a crystal grain boundary is not observed in a channel formation region in a single crystal film. Impurities that block the carrier flow (typically, an insulating impurity, an insulating oxide, or the like) are likely to be segregated at a crystal grain boundary. Thus, in the case where a crystal grain boundary exists in a channel formation region, a variation in transistor characteristics at the crystal grain boundary is large. Meanwhile, since a crystal grain boundary is not observed in a channel formation region in a single crystal film of one embodiment of the present invention, a variation in transistor characteristics due to a crystal grain boundary can be inhibited. The use of a single crystal film for a semiconductor layer can inhibit carrier scattering or the like at a crystal grain boundary. Thus, a transistor with high field-effect mobility and a transistor with high reliability can be provided.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. Furthermore, a semiconductor layer where at least one crystal orientation faces the same direction in a channel formation region can be referred to as a single crystal film. In the above cases, a crystal grain size can be larger than each of the channel length and the channel width of a transistor. In the case where the crystal grain size of a semiconductor layer is larger than each of the channel length and the channel width of a transistor, the semiconductor layer may be regarded as a single crystal film.

The semiconductor layer may be a polycrystal film or an amorphous film with crystal grains. In that case, it is preferable that a crystal grain boundary not be observed or the number of grain boundary components be small in the channel formation region. For example, when one crystal grain is positioned in a channel formation region, a structure in which a crystal grain boundary is not observed in the channel formation region can be obtained. Such a structure can also produce an effect similar to that of the structure in which the indium oxide film is a single crystal film.

The crystallinity of the semiconductor layer can be analyzed with X-ray diffractometry (XRD), transmission electron microscopy (TEM), or electron diffraction (ED), for example. Alternatively, these methods may be combined to be employed for analysis.

A crystal grain can be observed in a high-resolution TEM image, for example. In addition, a crystal grain boundary can sometimes be observed in a high-resolution TEM image, for example. That is, a crystal grain and a crystal grain boundary of a film having crystallinity can sometimes be observed in a high-resolution TEM image. The total magnification at the time of obtaining a TEM image is preferably greater than or equal to 2000000 times, further preferably greater than or equal to 4000000 times.

Note that the crystal structure of the semiconductor layer is not limited to a single crystal structure. For example, the semiconductor layer may have a c-axis aligned crystalline (CAAC) structure, a polycrystalline structure, a nanocrystalline (nc) structure, an amorphous-like (a-like) structure, or an amorphous structure.

A metal oxide other than indium oxide may be used for the semiconductor layer. In that case, gallium oxide or zinc oxide can be used for the semiconductor layer, for example. In the case where a metal oxide other than indium oxide is used for the semiconductor layer, the metal oxide preferably contains one or more kinds selected from indium, an element M, and zinc. Note that the element M is one or more kinds selected from aluminum, gallium, silicon, yttrium, tin, copper, vanadium, chromium, manganese, beryllium, boron, titanium, iron, nickel, germanium, zirconium, molybdenum, lanthanum, cerium, neodymium, hafnium, tantalum, tungsten, magnesium, calcium, strontium, barium, cobalt, and antimony. In particular, the element M is preferably one or more kinds selected from gallium, tungsten, aluminum, yttrium, and tin. For example, indium gallium oxide (In—Ga oxide, also referred to as IGO), indium zinc oxide (In—Zn oxide), or indium tungsten oxide (In—W oxide, also referred to as IWO) can be used as the metal oxide used for the semiconductor layer.

As the metal oxide used for the semiconductor layer, indium gallium zinc oxide (In—Ga—Zn oxide, also referred to as IGZO) can be used. An oxide containing indium, tin, and zinc (In—Sn—Zn oxide, also referred to as ITZO (registered trademark)) can also be used. An oxide containing indium, gallium, tin, and zinc (In—Ga—Sn—Zn oxide) can also be used. An oxide containing indium, aluminum, and zinc (In—Al—Zn oxide, also referred to as IAZO) can also be used. An oxide containing indium, aluminum, gallium, and zinc (In—Al—Ga—Zn oxide, also referred to as IAGZO) can also be used.

A semiconductor material other than a metal oxide may be used for the semiconductor layer. Examples of the semiconductor material other than a metal oxide include a single-element semiconductor and a compound semiconductor.

Examples of the single-element semiconductor that can be used as the semiconductor material include silicon and germanium. Examples of silicon that can be used as the semiconductor material include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure. Other examples of the compound semiconductor include an organic semiconductor and a nitride semiconductor. In addition, the oxide semiconductor mentioned above is also one kind of the compound semiconductor. These semiconductor materials may contain an impurity as a dopant.

### Insulating Layer

An inorganic insulating film is preferably used as each of the insulating layers (e.g., the insulating layers 52, 57, 61, 62, 65, 83, 87, 315, 320, 322, 324, 326, and 350) included in the memory device. Examples of the inorganic insulating film include an oxide insulating film, a nitride insulating film, and an oxynitride insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and an oxide film containing aluminum and hafnium. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. An organic insulating film may be used as each of the insulating layers included in the memory device.

With scaling down and high integration of a transistor, for example, a problem such as generation of leakage current may arise because of a thin gate insulating layer. When a high-dielectric-constant (high-k) material is used for the gate insulating layer, the voltage at the time of operation of the transistor can be reduced while the physical thickness is maintained. Furthermore, the equivalent oxide thickness (EOT) of the gate insulating layer can be reduced. By contrast, when a low-dielectric-constant material is used for the insulating layer functioning as an interlayer insulating layer, the parasitic capacitance generated between wirings can be reduced. Thus, a material is preferably selected in accordance with the function of an insulating layer. Note that a low-dielectric-constant material is a material with high dielectric strength.

Examples of the low-dielectric-constant material include aluminum oxide, gallium oxide, hafnium oxide, tantalum oxide, zirconium oxide, an oxide containing hafnium and zirconium, an oxide containing aluminum and hafnium, an oxynitride containing aluminum and hafnium, an oxide containing silicon and hafnium, an oxynitride containing silicon and hafnium, and a nitride containing silicon and hafnium.

Examples of the low-dielectric-constant material include inorganic insulating materials such as silicon oxide and silicon oxynitride, and resins such as polyester, polyolefin, polyamide (e.g., nylon and aramid), polyimide, polycarbonate, and an acrylic resin. Other examples of the inorganic insulating material with a low dielectric constant include silicon oxide containing fluorine, silicon oxide containing carbon, and silicon oxide containing carbon and nitrogen. Another example is porous silicon oxide. Note that these silicon oxides can contain nitrogen.

A material that can have ferroelectricity may be used for each of the insulating layers included in the memory device. As the material that can have ferroelectricity, an oxide containing one or both of hafnium and zirconium is preferably used. Examples of the oxide include metal oxides such as hafnium oxide, zirconium oxide, and hafnium zirconium oxide. As the material that can have ferroelectricity, a material in which an element J1 (the element J1 here is one or more selected from one of hafnium and zirconium, silicon, aluminum, gadolinium, yttrium, lanthanum, strontium, and the like) is added to a metal oxide containing the other of hafnium and zirconium may also be used.

Addition of a Group 3 element in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

Examples of the material that can have ferroelectricity also include a metal nitride containing nitrogen and at least one of an element M1 and an element M2. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Examples of the material that can have ferroelectricity also include the above metal nitride to which an element M3 is added. Note that the element M3 is one or more of magnesium, calcium, strontium, zinc, cadmium, and the like.

Examples of the material that can have ferroelectricity also include perovskite-type oxynitrides such as SrTaO₂N and BaTaO₂N, and GaFeO₃ with a κ-alumina-type structure. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Although the metal oxides and the metal nitrides are described above as examples, one embodiment of the present invention is not limited thereto. For example, a material in which nitrogen is added to any of the above metal oxides, a material in which oxygen is added to any of the above metal nitrides, or the like may be used.

As the material that can have ferroelectricity, a mixture or a compound each containing a plurality of materials selected from the above-listed materials can be used, for example. Incidentally, since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

In this specification and the like, the material that can have ferroelectricity processed into a layered shape is referred to as a ferroelectric layer, a metal oxide layer, or a metal nitride film in some cases. Furthermore, a device including such a ferroelectric layer, a metal oxide layer, or a metal nitride film is sometimes referred to as a ferroelectric device in this specification and the like.

The ferroelectric layer preferably includes a crystal having an orthorhombic crystal structure, in which case ferroelectricity is exhibited. A crystal included in the ferroelectric layer may have one or more of crystal structures selected from tetragonal, orthorhombic, monoclinic, and hexagonal crystal structures. Alternatively, the ferroelectric layer may have an amorphous structure. In that case, the ferroelectric layer may have a composite structure including an amorphous structure and a crystal structure.

A metal oxide containing one or both of hafnium and zirconium is also an insulating material having a function of capturing or fixing hydrogen. Thus, when a metal oxide containing one or both of hafnium and zirconium is used for at least part of a gate insulating layer, hydrogen contained in an oxide semiconductor layer can be captured or fixed, so that the hydrogen concentration in the oxide semiconductor layer can be reduced. Furthermore, a transistor including the gate insulating layer can function as a ferroelectric field-effect transistor (FeFET).

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, germanium oxide, yttrium oxide, zirconium oxide, lanthanum oxide, neodymium oxide, hafnium oxide, or tantalum oxide, a nitride such as aluminum nitride or silicon nitride, or an oxynitride such as silicon oxynitride can be used.

Specific examples of the material for the insulating layer having a function of inhibiting passage of oxygen and impurities such as water and hydrogen include metal oxides such as aluminum oxide, magnesium oxide, germanium oxide, yttrium oxide, zirconium oxide, lanthanum oxide, neodymium oxide, hafnium oxide, tantalum oxide, and an oxide containing aluminum and hafnium. Other examples include nitrides such as aluminum nitride, aluminum titanium nitride, and silicon nitride. Other examples include an oxynitride such as silicon oxynitride. Examples of the material for the insulating layer having a function of inhibiting passage of oxygen include gallium oxide.

An insulating layer that is in contact with an oxide semiconductor layer or provided in the vicinity of the oxide semiconductor layer, such as a gate insulating layer, preferably includes a region containing excess oxygen. For example, when an insulating layer including a region containing excess oxygen is in contact with an oxide semiconductor layer or positioned in the vicinity of the oxide semiconductor layer, oxygen vacancies in the oxide semiconductor layer can be reduced.

The insulating layer that is in contact with the oxide semiconductor layer or provided in the vicinity of the oxide semiconductor layer is preferably formed using an insulating material having a barrier property against hydrogen. When the insulating layer has a barrier property against hydrogen, diffusion of hydrogen into the oxide semiconductor layer can be inhibited. The insulating layer having a barrier property against hydrogen can be rephrased as an insulating layer having a function of inhibiting diffusion of hydrogen.

Examples of an insulating material having a function of capturing or fixing hydrogen include metal oxides such as an oxide containing hafnium, an oxide containing magnesium, an oxide containing aluminum, an oxide containing aluminum and hafnium, and an oxide containing hafnium and silicon. Furthermore, these metal oxides may further contain zirconium, and an example of such a metal oxide is an oxide containing hafnium and zirconium.

The insulating layer having a function of capturing or fixing hydrogen preferably has an amorphous structure. In a metal oxide having an amorphous structure, some oxygen atoms have a dangling bond, which allows the metal oxide to have a high property of capturing or fixing hydrogen. Thus, when the insulating layer has an amorphous structure, the function of capturing or fixing hydrogen can be enhanced.

When the insulating layer has an amorphous structure, formation of a crystal grain boundary can be inhibited. Inhibiting formation of a crystal grain boundary can increase the planarity of the insulating layer. This enables the insulating layer to have uniform thickness distribution and the number of extremely thin portions to be reduced, so that the withstand voltage of the insulating layer can be increased. In addition, the thickness distribution of the film provided over the insulating layer can be uniform. Furthermore, inhibiting formation of a crystal grain boundary in the insulating layer can reduce leakage current due to the defect states in the crystal grain boundary. Thus, the insulating layer can function as an insulating film with a low leakage current.

A function of capturing or fixing a target substance can also be referred to as a property that does not easily allow diffusion of a target substance. Thus, a function of capturing or fixing a target substance can be rephrased as a barrier property.

Examples of the insulating material having a barrier property against hydrogen include magnesium oxide, hafnium oxide, zirconium oxide, an oxide containing aluminum and hafnium, an oxide containing hafnium and zirconium, silicon nitride, and silicon oxynitride.

### Conductive Layer

For each of the conductive layers (the conductive layers 45, 46, 53, 54, 55, 56, 58, 71, 73, 75, 77, 316, 328, 330, and the like) included in the memory device, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, palladium, iridium, strontium, lanthanum, and the like; an alloy containing any of the above metal elements as its component; an alloy containing a combination of the above metal elements; or the like. As an alloy containing any of the above metal elements as its component, a nitride of the alloy or an oxide of the alloy may be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a conductive material maintaining its conductivity even after absorbing oxygen. Examples of the conductive material containing oxygen include indium oxide containing tungsten oxide, indium oxide containing titanium oxide, ITO, indium tin oxide containing titanium oxide, ITSO, In—Zn oxide, and indium zinc oxide containing tungsten oxide. In this specification and the like, a conductive film formed using the conductive material containing oxygen may be referred to as an oxide conductive film.

A plurality of conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

### Substrate

As a substrate (e.g., the substrate 311) where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include any of the semiconductor substrates including an insulator region, e.g., an SOI substrate. Examples of the conductor substrate include a graphite substrate, a metal substrate, an alloy substrate, and a conductive resin substrate. Other examples include a substrate containing a nitride of a metal and a substrate containing an oxide of a metal. An insulator substrate provided with a conductor or a semiconductor, a semiconductor substrate provided with a conductor or an insulator, a conductor substrate provided with a semiconductor or an insulator, or the like is also given as an example. Alternatively, these substrates provided with elements may be used. Examples of the element provided for the substrate include a capacitor, a resistor, a switching element, a light-emitting element, and a memory element.

The above is the description of materials that can be used for the memory device of this embodiment.

This embodiment can be combined with any of the other embodiments as appropriate. In this specification, in the case where a plurality of structure examples are shown in one embodiment, the structure examples can be combined as appropriate.

### Embodiment 2

In this embodiment, an indium oxide film that can be used for the semiconductor layer of the transistor included in the memory device of one embodiment of the present invention will be described.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

The dependence of the Hall mobility on the carrier concentration of indium oxide, silicon, and IGZO will be described.

IGZO has a tendency in which the Hall mobility is higher as the carrier concentration is higher. By contrast, single crystal indium oxide has a tendency in which the Hall mobility is higher as the carrier concentration is lower. This tendency is similar to that of silicon; as the concentration of a dopant (impurity) in a material is lower, impurity scattering is inhibited more and thus the Hall mobility is higher. That is, single crystal indium oxide having higher purity and being more intrinsic has higher Hall mobility. Consequently, the physical properties of single crystal indium oxide are different from those of IGZO and similar to those of silicon. Note that the tendency of non-single-crystal (e.g., polycrystal) indium oxide is sometimes different from that of single crystal indium oxide.

A carrier concentration range suitable for a channel formation region of a transistor is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270cm²/(V·s).

Indium oxide can include an element that reduces the carrier concentration. Examples of the element that reduces the carrier concentration include magnesium, calcium, zinc, cadmium, and copper. When indium is replaced with any of these elements, the carrier concentration can be reduced. Other examples include nitrogen, phosphorus, arsenic, and antimony. When oxygen is replaced with any of these elements, the carrier concentration can be reduced.

By contrast, an increase in carrier concentration can reduce electrical resistance. A carrier concentration range suitable for a source region and a drain region of a transistor, a resistor, or a transparent conductive film is, for example, a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

Indium oxide can include an element that increases the carrier concentration. For example, the same element as a source electrode and a drain electrode of a transistor is preferably included. Examples of the element that increases the carrier concentration include titanium, zirconium, hafnium, tantalum, tungsten, molybdenum, tin, silicon, and boron. It is particularly preferable that an oxide of the element have conductivity or semiconductor properties.

Since indium oxide is an oxide whose valence electron can be controlled in this manner, a region with a low carrier concentration and a region with a high carrier concentration of indium oxide can be used as a channel formation region and source and drain regions, respectively, of a transistor. Thus, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually. With the use of this technical idea, a transistor that has high mobility, has a low off-state current, can be normally off, and has high reliability can be achieved.

An indium oxide film preferably has crystallinity. In particular, the indium oxide film is preferably a polycrystal film, further preferably a single crystal film. A single crystal film does not have a crystal grain boundary (also referred to as a grain boundary). The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal film, the channel formation region is positioned in a single crystal region included in the polycrystal film and thus the transistor can be regarded as a transistor including a single crystal film.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be regarded as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A crystal grain, a crystal grain boundary, a crystal axis, a crystal orientation, or the like in a channel formation region can be confirmed in observation of a cross section including a semiconductor layer, a source electrode, and a drain electrode.

Impurities in the indium oxide film can function as a carrier scattering source and thus can cause a reduction in field-effect mobility and inhibit crystal growth. Examples of the impurities for the indium oxide film include boron and silicon. The concentrations of the impurities in the indium oxide film in the channel formation region are preferably as low as possible. For example, the concentrations of the impurity elements are each lower than or equal to 0.1%, preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film may contain an element that can form a trivalent cation like indium as long as the cubic crystal structure (bixbyite structure) is retained. Examples of the element include Group 13 elements such as gallium and aluminum and Group 3 elements in the periodic table. Since these elements exist mainly as trivalent cations in oxides, the carrier concentration of indium oxide can be kept low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. For example, oxygen diffusing in an indium oxide film is transmitted through the indium oxide film and released as an oxygen molecule. When reacting with hydrogen contained in the film, oxygen is released as a water molecule in some cases. In the case where the film includes oxygen vacancies, the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

Hydrogen diffuses in the indium oxide film. Hydrogen diffusing into the indium oxide film from the outside is transmitted through the indium oxide film and is released as a hydrogen molecule. When reacting with oxygen contained in the film, hydrogen is released as a water molecule.

Indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon, a transistor containing indium oxide can have higher field-effect mobility and lower off-state current than a Si transistor.

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In that case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO.

This embodiment can be combined with any of the other embodiments as appropriate. In this specification, in the case where a plurality of structure examples are shown in one embodiment, the structure examples can be combined as appropriate.

### Embodiment 3

In this embodiment, a memory device 900 of one embodiment of the present invention will be described.

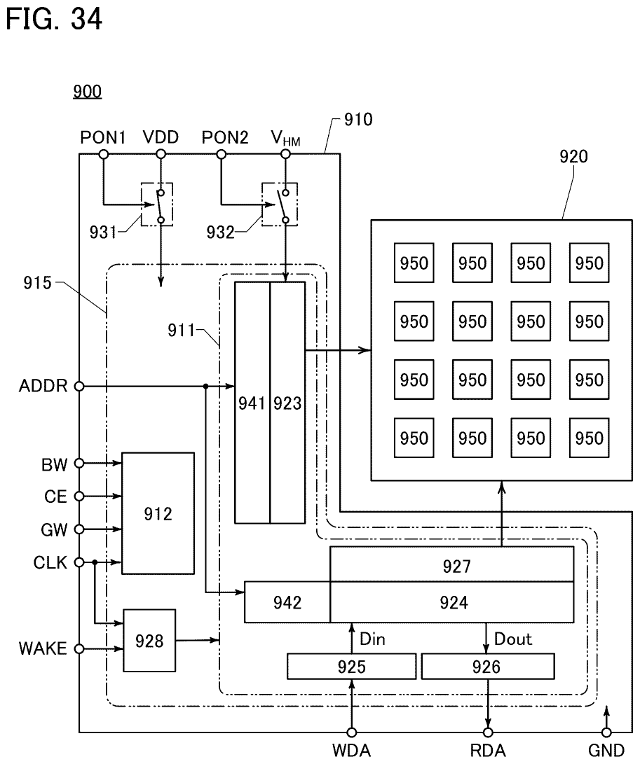

FIG. 34 is a block diagram illustrating a structure example of the memory device 900. The memory device 900 illustrated in FIG. 34 includes a driver circuit 910 and a memory array 920. The memory array 920 includes at least one memory cell 950. FIG. 34 illustrates an example in which the memory array 920 includes a plurality of memory cells 950 arranged in a matrix.

The memory cell 10 described in Embodiment 1 can be used as the memory cell 950, for example.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the memory device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the memory device 900. For example, the control circuit 912 performs logical operation on the signals CE, GW, and BW to determine the operating mode (e.g., write operation or read operation) of the memory device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when a potential H is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The word line driver circuit described in Embodiment 1 corresponds to the row driver 923, for example. The bit line driver circuit described in Embodiment 1 corresponds to the column driver 924 and the sense amplifier 927, for example. The transistor 300 illustrated in FIG. 8 can be, for example, a transistor included in the sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the memory device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the memory device 900, a high power supply potential is V_{DD} and a low power supply potential is a ground potential (GND). In addition, V_{HM} is a high power supply potential used for setting a word line at a high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 34 but can be more than one. In that case, a power switch can be provided for each power domain.

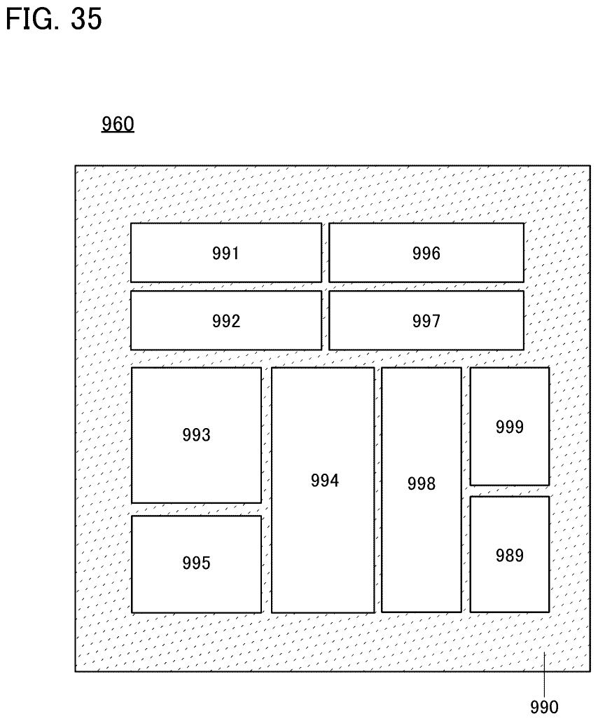

FIG. 35 is a block diagram of an arithmetic device 960. The arithmetic device 960 illustrated in FIG. 35 can be used as a CPU, for example. The arithmetic device 960 can also be used as a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 35 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in that case, the driver circuit 910 is preferably included in part of the cache interface 989.

It is also possible that the cache 999 is not provided and only the memory array 920 is used as a cache.

The arithmetic device 960 illustrated in FIG. 35 is just an example with a simplified structure, and the actual arithmetic device 960 has a variety of structures depending on the application. For example, what is called a multicore structure is preferably employed in which a plurality of cores each including the arithmetic device 960 in FIG. 35 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more cores, preferably 32 or more cores, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above-described circuits.

In the arithmetic device 960 illustrated in FIG. 35, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply potential is supplied to the memory cell in the register 996. When data retention by the capacitor is selected, the data is rewritten into the capacitor, and supply of the power supply potential to the memory cell in the register 996 can be stopped.

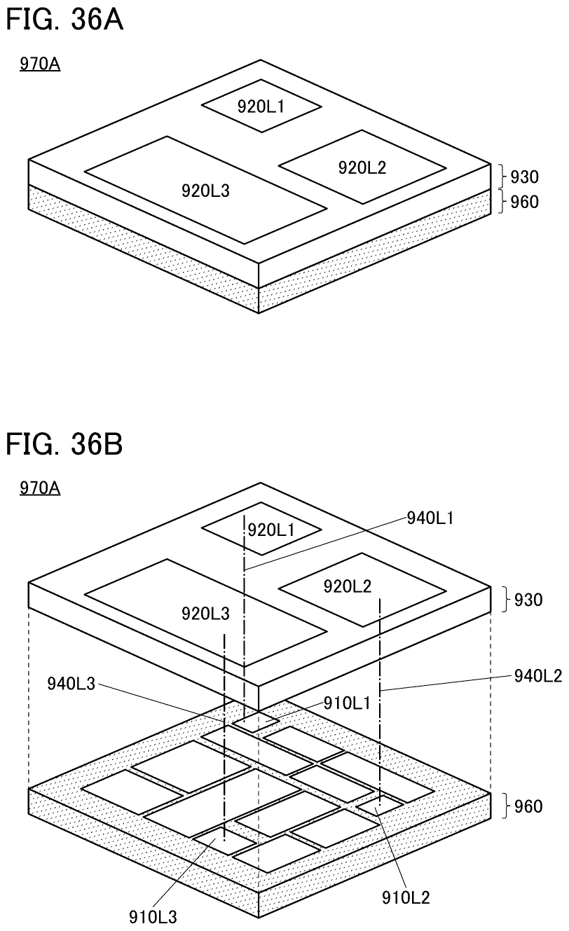

The memory array 920 and the arithmetic device 960 can be provided to overlap with each other. FIGS. 36A and 36B are perspective views of a memory device 970A. The memory device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the memory device 970A, the arithmetic device 960 and the layer 930 are separately illustrated in FIG. 36B.

Stacking the arithmetic device 960 and the layer 930 provided with the memory arrays can shorten the connection distance therebetween. Accordingly, the communication speed therebetween can be increased. Moreover, the short connection distance leads to lower power consumption.

As a method for stacking the arithmetic device 960 and the layer 930 provided with the memory arrays, either of the following methods may be employed: a method in which the layer 930 provided with the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu—Cu bonding). The former method does not require consideration of misalignment in bonding; thus, not only the chip size but also the fabrication cost can be reduced.

Here, it is possible that the arithmetic device 960 does not include the cache 999 and the memory arrays 920L1, 920L2, and 920L3 provided in the layer 930 are each used as a cache. In that case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

In the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 36B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although three memory arrays function as caches here, the number of memory arrays functioning as caches may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the memory device 900 function as RAM in accordance with a signal supplied from the arithmetic device 960.

In the memory device 900, some of the memory cells 950 can function as the cache and the other memory cells 950 can function as the main memory. That is, the memory device 900 can have both the function of the cache and the function of the main memory. The memory device 900 of one embodiment of the present invention can function as a universal memory, for example.

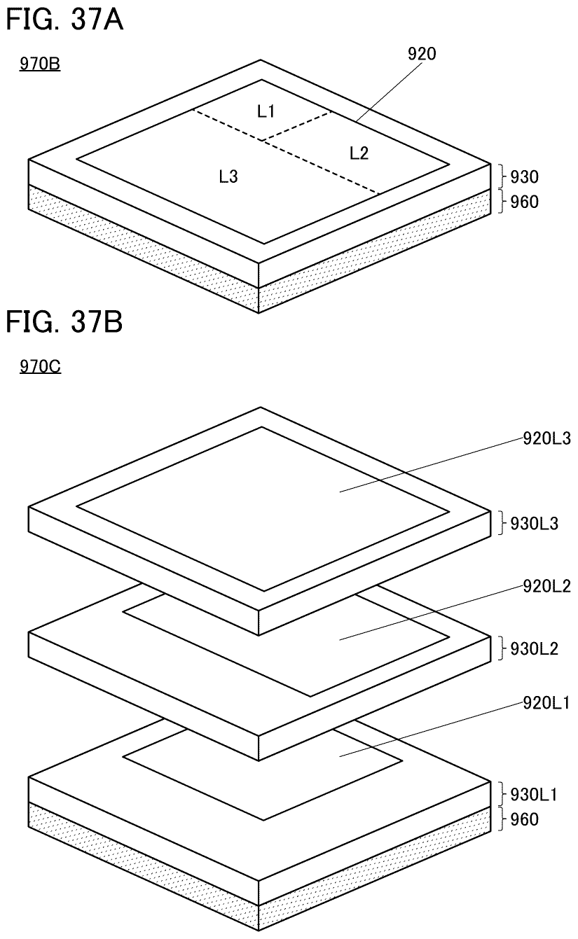

The layer 930 including one memory array 920 may be provided to overlap with the arithmetic device 960. FIG. 37A is a perspective view of a memory device 970B.

In the memory device 970B, one memory array 920 can be divided into a plurality of areas having different functions. FIG. 37A illustrates an example in which a region L1, a region L2, and a region L3 are used as the L1 cache, the L2 cache, and the L3 cache, respectively.

In the memory device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 37B is a perspective view of a memory device 970C.

In the memory device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate. In this specification, in the case where a plurality of structure examples are shown in one embodiment, the structure examples can be combined as appropriate.

### Embodiment 4

In this embodiment, application examples of the memory device of one embodiment of the present invention will be described.

The memory device of one embodiment of the present invention can be used for an electronic component, a large computer, space equipment, a data center (also referred to as DC), and a variety of electronic devices, for example. With the use of the memory device of one embodiment of the present invention, an electronic component, a large computer, space equipment, a data center, and a variety of electronic devices can have lower power consumption and higher performance.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### Electronic Component

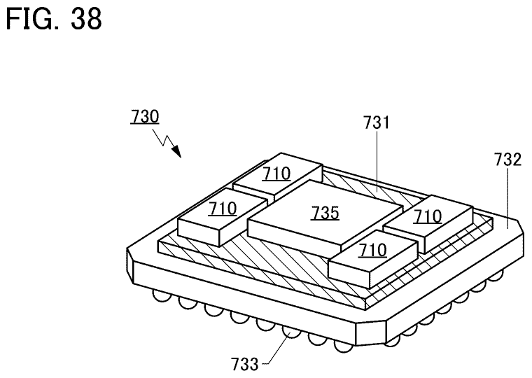

FIG. 38 is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of memory devices 710 are provided over the interposer 731.

The electronic component 730 using the memory devices 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of connecting a plurality of integrated circuits with different terminal pitches. The plurality of wirings are provided in a single layer or multiple layers. In addition, the interposer 731 has a function of connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to connect an integrated circuit and the package substrate 732 in some cases. In the case of using a silicon interposer, a through silicon via (TSV) can also be used as the through electrode.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high flatness; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are connected with use of a silicon interposer, a TSV, and the like, a space for a width or the like of the terminal pitches is needed. Accordingly, in the case where the size of the electronic component 730 is reduced, the width of the terminal pitches becomes an issue, which sometimes makes it difficult to provide a large number of wirings for obtaining a wide memory bandwidth. For this reason, the above-described monolithic stacked-layer structure using OS transistors is suitable. A composite structure combining memory arrays stacked using a TSV and monolithically stacked memory arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the memory devices 710 and the semiconductor device 735 are preferably equal to each other.

To mount the electronic component 730 on another substrate, an electrode 733 may be provided on a bottom portion of the package substrate 732. FIG. 38 illustrates an example in which the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

The memory device 710 may be called a die. In this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

### Large Computer

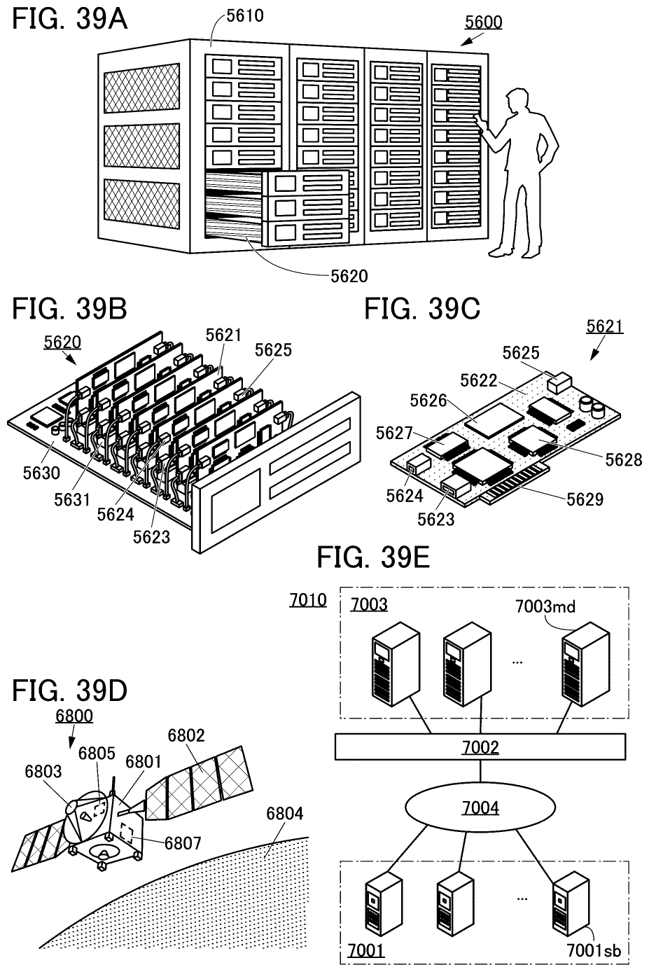

FIG. 39A is a perspective view of a large computer 5600. In the large computer 5600 illustrated in FIG. 39A, a plurality of rack mount computers 5620 are stored in a rack 5610. Note that the large computer 5600 may be referred to as a supercomputer.

The computer 5620 can have a structure illustrated in a perspective view in FIG. 39B, for example. In FIG. 39B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 39C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a memory device 5628, and a connection terminal 5629. FIG. 39C also illustrates semiconductor devices other than the semiconductor device 5626, the semiconductor device 5627, and the memory device 5628, and the following description of the semiconductor device 5626, the semiconductor device 5627, and the memory device 5628 can be referred to for the semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 730 can be used, for example.

The memory device 5628 includes a plurality of terminals, and when the terminals are reflow-soldered, for example, to wirings of the board 5622, the memory device 5628 and the board 5622 can be connected to each other.

The large computer 5600 can also function as a parallel computer. When the large computer 5600 is used as a parallel computer, large-scale computation necessary for artificial intelligence learning and inference can be performed, for example.

### Space Equipment

The memory device of one embodiment of the present invention can be suitably used as space equipment.

The memory device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude of 100 km or higher, and outer space described in this specification can include one or more of thermosphere, mesosphere, and stratosphere.

FIG. 39D illustrates an artificial satellite 6800 as an example of space equipment. The artificial satellite 6800 includes a body 6801, a solar panel 6802, an antenna 6803, a secondary battery 6805, and a control device 6807. In FIG. 39D, a planet 6804 in outer space is illustrated as an example.

Although not illustrated in FIG. 39D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The memory device of one embodiment of the present invention can be suitably used for space equipment such as a spacecraft, a space capsule, or a space probe, for example.

As described above, the OS transistor has advantageous effects over the Si transistor, such as a wide memory bandwidth and high radiation resistance.

### Data Center

The memory device of one embodiment of the present invention can be suitably used for, for example, a storage system in a data center or the like. Long-term management of data, such as guarantee of data immutability, is required for the data center. In the case where data is managed for a long term, it is necessary to increase the scale of data center facility for installation of storages and servers for storing an enormous amount of data, stable electric power for data retention, cooling equipment for data retention, or the like.

With the use of the memory device of one embodiment of the present invention for a storage system in a data center, electric power required for data retention can be reduced and a memory device for retaining data can be downsized. Accordingly, downsizing of the storage system and the power supply for data retention, downscaling of the cooling equipment, and the like can be achieved. Thus, a space of the data center can be reduced.

Since the memory device of one embodiment of the present invention has low power consumption, heat generation from a circuit can be reduced. Accordingly, adverse effects of the heat generation on the circuit itself, a peripheral circuit, and a module can be reduced. Furthermore, the use of the memory device of one embodiment of the present invention can achieve a data center that operates stably even in a high-temperature environment. Thus, the reliability of the data center can be increased.

FIG. 39E illustrates a storage system that can be used in a data center. A storage system 7010 illustrated in FIG. 39E includes a plurality of servers 7001sb as a host 7001. The storage system 7010 includes a plurality of memory devices 7003md as a storage 7003. In the illustrated example, the host 7001 and the storage 7003 are connected to each other via a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but the time is considerably longer than the time required for a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downscaling is possible by stacking memory arrays.

This embodiment can be combined with any of the other embodiments as appropriate. In this specification, in the case where a plurality of structure examples are shown in one embodiment, the structure examples can be combined as appropriate. This application is based on Japanese Patent Application Serial No. 2024-212251 filed with Japan Patent Office on Dec. 5, 2024, the entire contents of which are hereby incorporated by reference.

What is claimed is:

1. A memory device comprising:
a transistor;
a capacitor;
a first insulating layer; and
a second insulating layer,
wherein the transistor comprises a first conductive layer, a second conductive layer, a third conductive layer, a third insulating layer, and a semiconductor layer,
wherein the capacitor comprises the third conductive layer, a fourth conductive layer, and a fourth insulating layer,
wherein the first conductive layer is positioned over the first insulating layer,
wherein the third insulating layer is over the first insulating layer to cover a top surface and a side surface of the first conductive layer,
wherein the second conductive layer is positioned over the third insulating layer,
wherein a level of a top surface of the second conductive layer is lower than a level of the top surface of the first conductive layer,
wherein the semiconductor layer comprises a region in contact with the top surface of the second conductive layer, a region in contact with a side surface of the third insulating layer, and a region in contact with a top surface of the third insulating layer that overlaps with the first conductive layer,
wherein the second insulating layer comprises a region positioned over the semiconductor layer and a region in contact with a side surface of the semiconductor layer,
wherein a level of a bottom surface of the second insulating layer is lower than the level of the top surface of the second conductive layer,
wherein the second insulating layer comprises a first opening portion overlapping with the first conductive layer,
wherein the third conductive layer comprises a region in contact with a top surface of the semiconductor layer in the first opening portion,
wherein the fourth insulating layer covers the third conductive layer and comprises a region positioned over the second insulating layer, and
wherein the fourth conductive layer is over the fourth insulating layer and comprises a region facing a side surface of the third conductive layer with the fourth insulating layer therebetween.

2. The memory device according to claim 1,
wherein the second conductive layer comprises a second opening portion, and
wherein the first conductive layer and the third insulating layer each comprise a region positioned in the second opening portion.

3. The memory device according to claim 1, further comprising:
a fifth conductive layer,
wherein the fifth conductive layer comprises a region in contact with a bottom surface of the first conductive layer, and
wherein an angle between the side surface of the first conductive layer and a top surface of the fifth conductive layer is greater than or equal to 90°.

4. The memory device according to claim 1, wherein the fourth insulating layer and the fourth conductive layer each comprise a region positioned in the first opening portion.

5. The memory device according to claim 1, wherein the semiconductor layer is a crystalline oxide semiconductor comprising indium and oxygen.

6. The memory device according to claim 2, further comprising:
a fifth conductive layer,
wherein the fifth conductive layer comprises a region in contact with a bottom surface of the first conductive layer, and
wherein an angle between the side surface of the first conductive layer and a top surface of the fifth conductive layer is greater than or equal to 90°.

7. The memory device according to claim 2, wherein the fourth insulating layer and the fourth conductive layer each comprise a region positioned in the first opening portion.

8. The memory device according to claim 2, wherein the semiconductor layer is a crystalline oxide semiconductor comprising indium and oxygen.

9. The memory device according to claim 3, wherein the angle is greater than 110°.

10. The memory device according to claim 3,
wherein the second conductive layer extends in a first direction in a plan view,
wherein the fifth conductive layer extends in a second direction in the plan view, and
wherein the second direction is perpendicular or substantially perpendicular to the first direction.

11. A method for fabricating a memory device, the method comprising:
forming a first conductive layer over a first insulating layer;
forming a second insulating layer to cover a top surface and a side surface of the first conductive layer;
forming a second conductive layer over the second insulating layer;
processing the second conductive layer to make a level of a top surface of the second conductive layer lower than a level of the top surface of the first conductive layer;
forming a semiconductor layer over the second insulating layer to comprise a region in contact with the top surface of the second conductive layer;
forming a third insulating layer to comprise a region in contact with a top surface of the semiconductor layer and a region in contact with a side surface of the semiconductor layer;
forming a first opening portion in the third insulating layer, the first opening portion overlapping with the first conductive layer and reaching the top surface of the semiconductor layer;
forming a third conductive layer to comprise a region in contact with the top surface of the semiconductor layer in the first opening portion;
forming a fourth insulating layer to cover the third conductive layer; and
forming a fourth conductive layer over the fourth insulating layer to comprise a region facing a side surface of the third conductive layer with the fourth insulating layer therebetween.

12. The method for fabricating a memory device, according to claim 11,
wherein the first conductive layer is formed by the steps of:
forming a conductive film;
forming a first resist mask over the conductive film;
processing the conductive film into a band shape;
removing the first resist mask;
forming a second resist mask over the conductive film and the first insulating layer; and
processing the conductive film into an island shape,
wherein the first resist mask is formed to extend in a first direction in a plan view,
wherein the second resist mask is formed to extend in a second direction in the plan view, and
wherein the second direction is perpendicular or substantially perpendicular to the first direction.

13. The method for fabricating a memory device, according to claim 11,
wherein a fifth conductive layer is formed over the first insulating layer before the first conductive layer is formed,
wherein a sacrificial layer is formed over the fifth conductive layer,
wherein a second opening portion reaching a top surface of the fifth conductive layer is formed in the sacrificial layer such that an angle between a side surface of the sacrificial layer in the second opening portion and a bottom portion of the second opening portion is greater than 90°,
wherein the first conductive layer is formed to fill the second opening portion, and
wherein the second insulating layer is formed after the sacrificial layer is removed.

14. The method for fabricating a memory device, according to claim 12,
wherein a fifth conductive layer is formed over the first insulating layer before the first conductive layer is formed,
wherein a sacrificial layer is formed over the fifth conductive layer,
wherein a second opening portion reaching a top surface of the fifth conductive layer is formed in the sacrificial layer such that an angle between a side surface of the sacrificial layer in the second opening portion and a bottom portion of the second opening portion is greater than 90°,
wherein the first conductive layer is formed to fill the second opening portion, and
wherein the second insulating layer is formed after the sacrificial layer is removed.

15. The method for fabricating a memory device, according to claim 13, wherein the second opening portion is formed such that the angle is greater than 110°.

16. The method for fabricating a memory device, according to claim 13,
wherein the second insulating layer and the semiconductor layer are formed by an ALD method, and
wherein the second conductive layer is formed by a sputtering method or a CVD method.
